(19) United States
(12) Patent Application Publication
(10) Pub. No.: US 2025/0282992 A1
(43) Pub. Date: Sep. 11, 2025

(54) LIGHT-EMITTING DEVICE INCLUDING CONDENSED CYCLIC COMPOUND AND ELECTRONIC APPARATUS INCLUDING THE LIGHT-EMITTING DEVICE

(71) Applicant: Samsung Display Co., Ltd., Yongin-si (KR)

(72) Inventors: Munki SIM, Yongin-si (KR); Taeil KIM, Yongin-si (KR); Sunyoung PAK, Yongin-si (KR); Junha PARK, Yongin-si (KR); Jangyeol BAEK, Yongin-si (KR); Chanseok OH, Yongin-si (KR); Minjung JUNG, Yongin-si (KR)

(21) Appl. No.: 19/217,750

(22) Filed: May 23, 2025

Related U.S. Application Data
(63) Continuation of application No. 17/206,544, filed on Mar. 19, 2021, now Pat. No. 12,356,854.

(30) Foreign Application Priority Data
May 25, 2020 (KR) 10-2020-0062577

(51) Int. Cl. C09K 11/06; C07F 5/02; H10K 50/11; H10K 50/15; H10K 50/844; H10K 59/12; H10K 85/60; H10K 101/10

(52) U.S. Cl. CPC C09K 11/06; C07F 5/027; H10K 85/633; H10K 85/636; H10K 85/657; H10K 85/6572; H10K 85/658; C09K 2211/1018; H10K 50/11; H10K 50/15; H10K 50/844; H10K 59/12; H10K 2101/10

(57) ABSTRACT

A light-emitting device including a condensed cyclic compound and an electronic apparatus including the light-emitting device are provided. The light-emitting device includes a first electrode, a second electrode facing the first electrode, and an interlayer between the first electrode and the second electrode, wherein the interlayer further includes a hole transport region between the first electrode and the emission layer, the hole transport region includes a compound represented by Formula 201, a compound represented by Formula 202, or any combination thereof, and the emission layer includes at least one condensed cyclic compound represented by Formula 1:

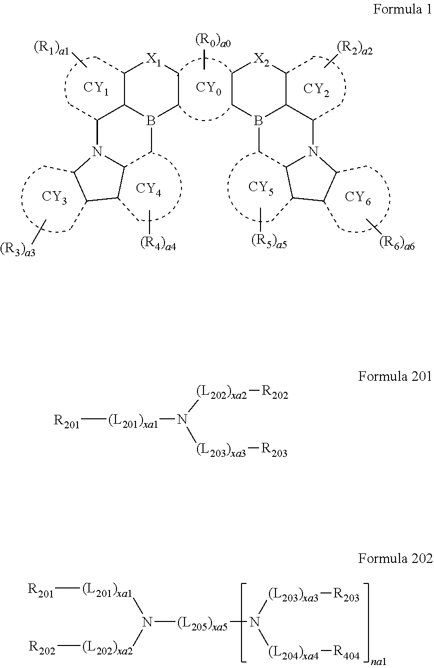

The substituents are as defined in the detailed description.

### CROSS-REFERENCE TO RELATED APPLICATION

This application is a continuation of U.S. patent application Ser. No. 17/206,544, filed on Mar. 19, 2021, which claims priority to and the benefit of Korean Patent Application No. 10-2020-0062577, filed on May 25, 2020, in the Korean Intellectual Property Office, the disclosures of each of which are incorporated herein by reference in their entireties.

### BACKGROUND

### 1. Field

One or more embodiments relate to a light-emitting device including a condensed cyclic compound, and an electronic apparatus including the light-emitting device.

### 2. Description of Related Art

Organic light-emitting devices are self-emission devices that have wide viewing angles, high contrast ratios, short response times, and/or desired (e.g., excellent) characteristics in terms of brightness, driving voltage, and/or response speed, as compared with light-emitting devices in the related art.

Organic light-emitting devices may include a first electrode located on a substrate, and a hole transport region, an emission layer, an electron transport region, and a second electrode sequentially stacked on the first electrode. Holes provided from the first electrode may move toward the emission layer through the hole transport region, and electrons provided from the second electrode may move toward the emission layer through the electron transport region. Carriers, such as holes and electrons, recombine in the emission layer to produce excitons. These excitons transition from an excited state to a ground state to thereby generate light.

### SUMMARY

Aspects according to one or more embodiments are directed toward a light-emitting device including a condensed cyclic compound having desired (e.g., excellent) light efficiency and high stability, and an electronic apparatus including the light-emitting device.

Additional aspects will be set forth in part in the description which follows and, in part, will be apparent from the description, or may be learned by practice of the presented embodiments of the disclosure.

According to one or more embodiments, a light-emitting device includes a first electrode, a second electrode facing the first electrode, and an interlayer between the first electrode and the second electrode,
wherein the interlayer further includes a hole transport region between the first electrode and the emission layer,
the hole transport region includes a compound represented by Formula 201, a compound represented by Formula 202, or any combination thereof, and
the emission layer includes at least one condensed cyclic compound represented by Formula 1:

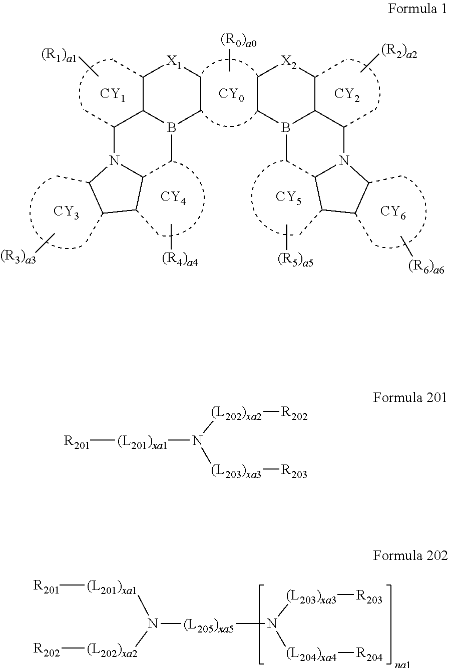

wherein, in Formula 1,
X₁ and X₂ are each independently O or S,
ring CY₀ to ring CY are each independently a C₅-C₃₀ carbocyclic group or a C₁-C₃₀ heterocyclic group, wherein at least one of ring CY₃ and ring CY₆ is not a benzene group,
R₀ to R₆ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a0 to a6 are each independently an integer selected from 0 to 20,
R₁₀ₐ is
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group that is each unsubstituted or substituted with deuterium, —F, a cyano group, a C₁-C₆₀ alkyl group, a C₁-C₆₀ alkoxy group, a phenyl group, a biphenyl group, or any combination thereof, and
wherein, in Formulae 201 and 202,
L₂₀₁ to L₂₀₄ are each independently a C₅-C₆₀ carbocyclic group unsubstituted or substituted with at least one R₁₀ₐ or a C₁-C₆₀ heterocyclic group unsubstituted or substituted with at least one R₁₀ₐ,
L₂₀s is *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 are each independently an integer selected from 0 to 5,
xa5 is an integer selected from 1 to 10,
R₂₀₁ to R₂₀₄ and Q₂₀₁ are each independently a C₅-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ are optionally linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ,
R₂₀₃ and R₂₀₄ are optionally linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ,
na1 is an integer selected from 1 to 4, and * and *′ each indicate a binding site to a neighboring atom.

According to one or more embodiments, a light-emitting device includes a first electrode, a second electrode facing the first electrode, and an interlayer between the first electrode and the second electrode,
wherein the light-emitting device further includes a second capping layer outside the second electrode and having a refractive index of equal to or greater than 1.6, and
the emission layer includes at least one condensed cyclic compound represented by Formula 1.

According to one or more embodiments, an electronic apparatus includes a thin-film transistor in addition to the light-emitting device, wherein the thin-film transistor includes a source electrode and a drain electrode, and the first electrode of the light-emitting device is electrically connected to the source electrode or the drain electrode of the thin-film transistor.

### BRIEF DESCRIPTION OF THE DRAWINGS

The above and other aspects, features, and enhancements of certain embodiments of the disclosure will be more apparent from the following description taken in conjunction with the accompanying drawings, in which:

FIG. 1 is a schematic cross-sectional view of a light-emitting device according to an embodiment;

FIG. 2 is a schematic cross-sectional view of a light-emitting apparatus according to another embodiment; and

FIG. 3 is a schematic cross-sectional view of a light-emitting apparatus according to another embodiment.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b and c” indicates only a, only b, only c, both a and b, both a and c, both b and c, all of a, b, and c, or variations thereof.

According to an embodiment of the present disclosure, a condensed cyclic compound is represented by Formula 1:

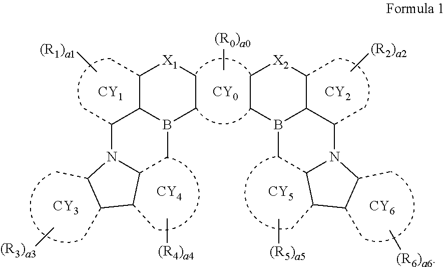

In Formula 1, X₁ and X₂ may each independently be O or S.

For example, X₁ may be O or S.

For example, X₂ may be O or S.

In Formula 1, ring CY₀ to ring CY₆ may each independently be a C₅-C₃₀ carbocyclic group or a C₁-C₃₀ heterocyclic group, wherein at least one of ring CY₃ and ring CY₆ may not be a benzene group.

In an embodiment, ring CY₀ to ring CY₆ may each independently be a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group, wherein at least one of ring CY₃ and ring CY₆ may not be a benzene group.

For example, at least one of ring CY₀ to ring CY₂ may be a benzene group.

In one or more embodiments, at least one of ring CY₃ and ring CY₆ may be a fluorene group, a carbazole group, a dibenzofuran group, or a dibenzothiophene group.

In one or more embodiments, a group represented by

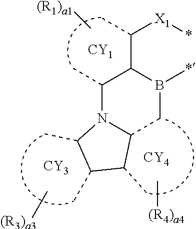

in Formula 1 may be a group represented by any of Formulae CY3-1 to CY3-3:

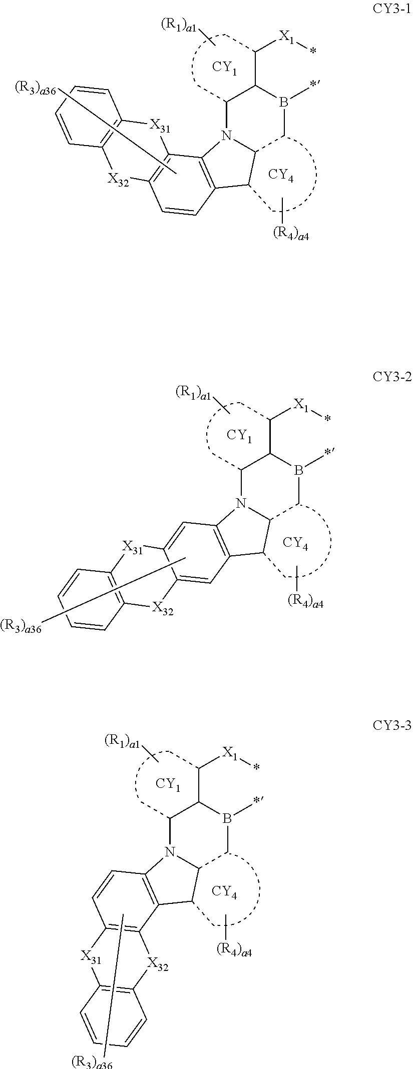

In Formulae CY3-1 to CY3-3, X₁, ring CY₁, ring CY₄, R₁, R₃, R₄, a1, and a4 may each independently be the same as respectively described in the present specification, * and *′ each indicate a condensation (e.g., connection) site to ring CY₀ in Formula 1, X₃₁ may be a single bond, O, S, Se, C(R₃₁ₐ)(R_{31b}), Si(R₃₁ₐ)(R_{31b}), or N(R₃₁ₐ), X₃₂ may be a single bond, O, S, Se, C(R₃₂ₐ)(R_{32b}), Si(R₃₂ₐ)(R_{32b}), or N(R₃₂ₐ), X₃₁ and X₃₂ may not both be single bonds at the same time, R₃₁ₐ, R_{31b}, R₃₂ₐ, and R_{32b} may each independently be the same as described in connection with R₃, and a36 may be an integer selected from 0 to 6.

For example, the group represented by

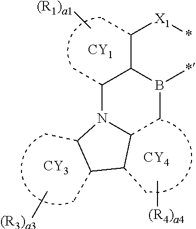

in Formula 1 may be represented by any of Formulae CY3(1) to CY3(6):

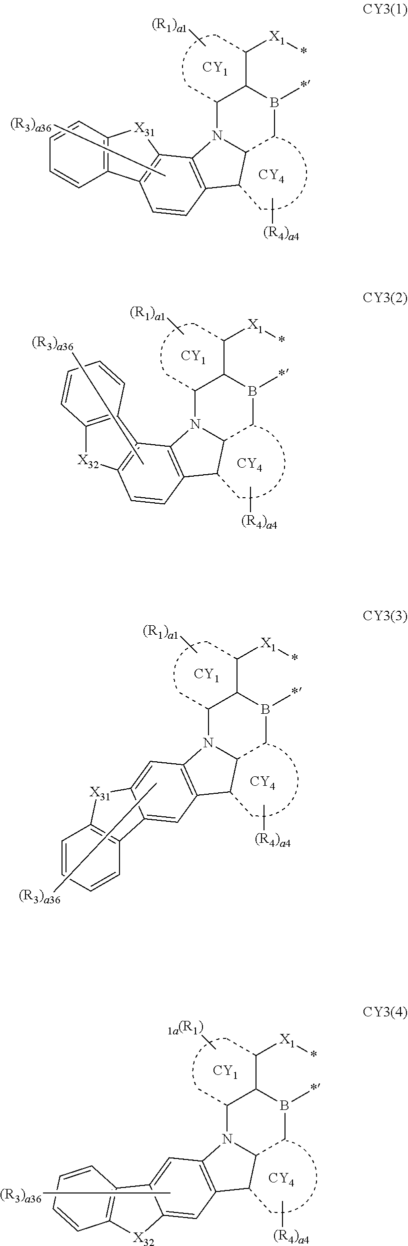

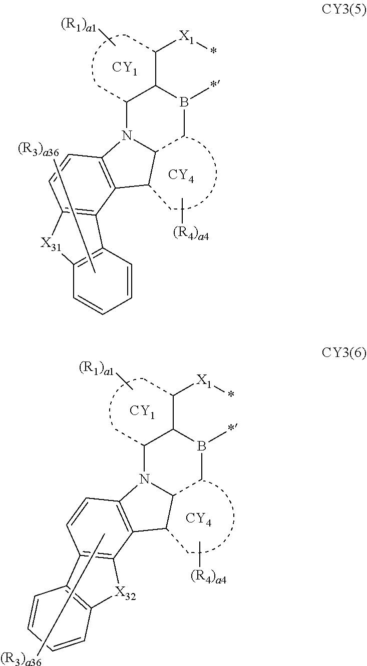

In Formulae CY3(1) to CY3(6), X₁, ring CY₁, ring CY₄, R₁, R₃, R₄, a1, and a4 may each independently be the same as respectively described in the present specification, * and *′ each indicate a condensation (e.g., connection) site to ring CY₀ in Formula 1, X₃₁ may be O, S, Se, C(R₃₁ₐ)(R_{31b}), Si(R₃₁ₐ)(R_{31b}), or N(R₃₁ₐ), X₃₂ may be O, S, Se, C(R₃₂ₐ)(R_{32b}), Si(R₃₂ₐ)(R_{32b}), or N(R₃₂ₐ), R₃₁ₐ, R_{31b}, R₃₂ₐ, and R_{32b} may each independently be the same as described in connection with R₃, and a36 may be an integer selected from 0 to 6.

In one or more embodiments, the group represented by

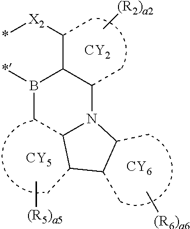

in Formula 1 may be a group represented by any of Formulae CY6-1 to CY6-4:

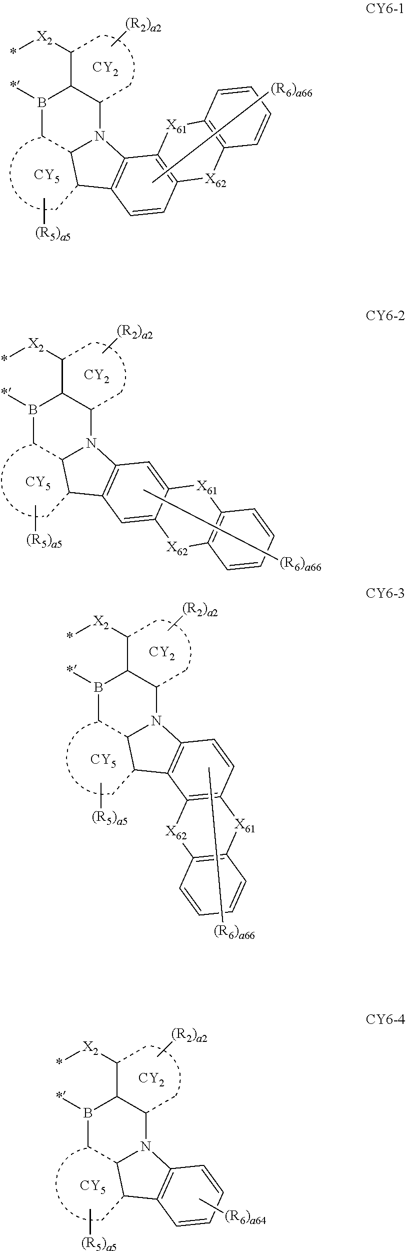

In Formulae CY6-1 to CY6-4, X₂, ring CY₂, ring CY₅, R₂, R₅, R₆, a2, and a5 may each independently be the same as respectively described in the present specification, * and *′ each indicate a condensation (e.g., connection) site to ring CY₀ in Formula 1, X₆₁ may be single bond, O, S, Se, C(R₆₁ₐ)(R_{61b}), Si(R₆₁ₐ)(R_{61b}), or N(R₆₁ₐ), X₆₂ may be a single bond, O, S, Se, C(R₆₂ₐ)(R_{62b}), Si(R₆₂ₐ)(R_{62b}), or N(R₆₂ₐ), X₆₁ and X₆₂ may not both be single bonds at the same time, R₆₁ₐ, R_{61b}, R₆₂ₐ, and R_{62b} may each independently be the same as described in connection with R₆, a64 may be an integer selected from 0 to 4, and a66 may be an integer selected from 0 to 6.

For example, the group represented by

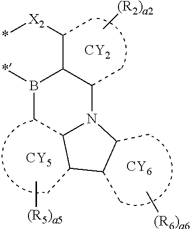

in Formula 1 may be represented by any of Formulae CY6(1) to CY6(6) and CY6-4:

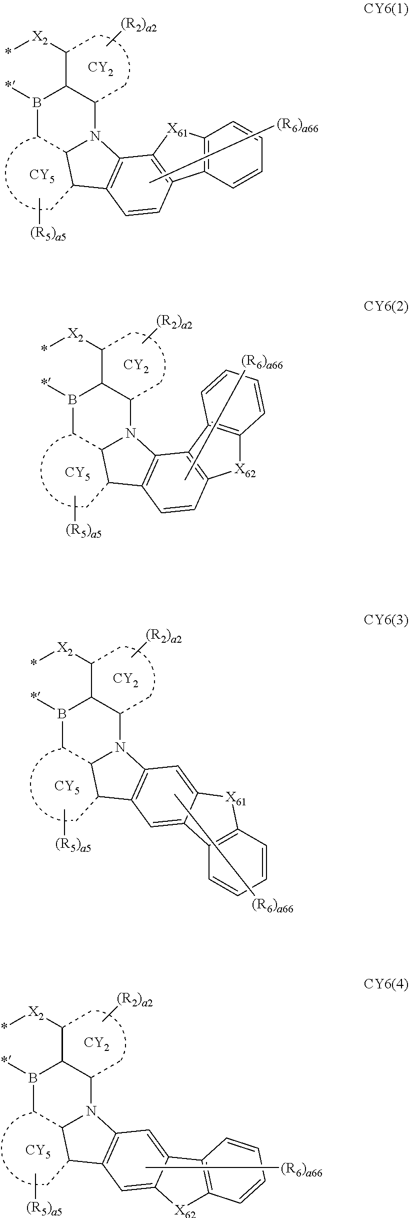

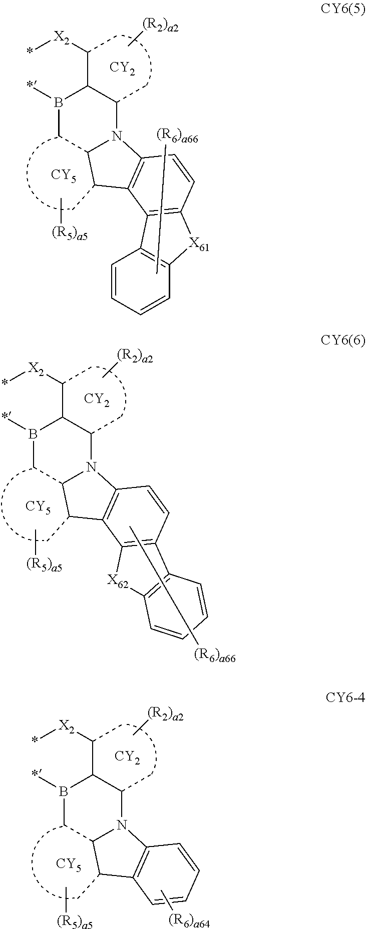

In Formulae CY6(1) to CY6(6) and CY6-4, X₂, ring CY₂, ring CY₅, R₂, R₅, R₆, a2, and a5 may each independently be the same as respectively described in the present specification, * and *′ each indicate a condensation (e.g., connection) site to ring CY₀ in Formula 1, X₆₁ may be O, S, Se, C(R₆₁ₐ)(R_{61b}), Si(R₆₁ₐ)(R_{61b}), or N(R₆₁ₐ), X₆₂ may be O, S, Se, C(R₆₂ₐ)(R_{62b}), Si(R₆₂ₐ)(R_{62b}), or N(R₆₂ₐ), R₆₁ₐ, R_{61b}, R₆₂ₐ, and R_{62b} may each independently be the same as described in connection with R₆, a64 may be an integer selected from 0 to 4, and a66 may be an integer selected from 0 to 6.

In one or more embodiments, at least one of ring CY4 and CY₅ may be a benzene group.

In Formula 1, R₀ to R₆ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂). Here, R₁₀ₐ and Q₁ to Q₃ may each independently be the same as respectively described in the present specification.

In an embodiment, R₀ to R₆ may each independently be:
hydrogen, deuterium, —F, —Cl, —Br, —I, a hydroxyl group, a cyano group, or a nitro group;
a C₁-C₂₀ alkyl group, a C₂-C₂₀ alkenyl group, a C₂-C₂₀ alkynyl group, or a C₁-C₂₀ alkoxy group, each unsubstituted or substituted with deuterium, —F, —Cl, —Br, —I, —CD₃, -CD₂H, -CDH₂, —CF₃, —CF₂H, —CFH₂, a hydroxyl group, a cyano group, a nitro group, a cyclopentyl group, a cyclohexyl group, a cycloheptyl group, a cycloctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or any combination thereof;
a cyclopentyl group, a cyclohexyl group, a cycloheptyl group, a cycloctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thienyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothienyl group, an benzoisothiazolyl group, a benzoxazolyl group, an benzoisoxazolyl group, a triazolyl group, a tetrazolyl group, an oxadiazolyl group, a triazinyl group, a dibenzofuranyl group, a dibenzothienyl group, a benzocarbazolyl group, a dibenzocarbazolyl group, an imidazopyridinyl group, or an imidazopyrimidinyl group, each unsubstituted or substituted with
deuterium, —F, —CI, —Br, —I, -CD₃, -CD₂H, -CDH₂, —CF₃, —CF₂H, —CFH₂, a hydroxyl group, a cyano group, a nitro group, a C₁-C₂₀ alkyl group, a C₂-C₂₀ alkenyl group, a C₂-C₂₀ alkynyl group, a C₁-C₂₀ alkoxy group, a cyclopentyl group, a cyclohexyl group, a cycloheptyl group, a cycloctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thienyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothienyl group, an benzoisothiazolyl group, a benzoxazolyl group, an benzoisoxazolyl group, a triazolyl group, a tetrazolyl group, an oxadiazolyl group, a triazinyl group, a dibenzofuranyl group, a dibenzothienyl group, a benzocarbazolyl group, a dibenzocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or any combination thereof; or
—B(Q₁)(Q₂), —P(Q₁)(Q₂), or —C(═O)(Q₁).

In one or more embodiments, at least one of R₀ to R₆ may be hydrogen.

In one or more embodiments, at least one of R₄ and R₅ may be hydrogen.

In Formula 1, a0 to a6 may each independently be an integer selected from 0 to 20.

In an embodiment, a0 to a6 may each independently be an integer selected from 0 to 5.

In one or more embodiments, at least one of a0 to a2 may be 0.

In Formula 1, a part of the group represented by

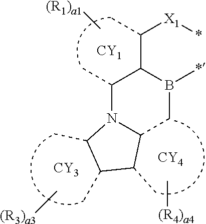

and a part (e.g., a corresponding part) of the group represented by

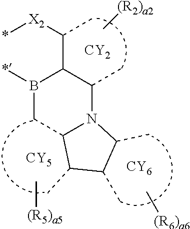

may be identical to each other. For example, ring CY₃ and ring CY₆ may be identical to each other, ring CY₄ and ring CY₅ may be identical to each other, and/or R₃ and R₆ may be identical to each other.

In an embodiment, ring CY₃ and ring CY₆ may be identical to each other.

In one or more embodiments, ring CY₃ and ring CY₆ may be identical to each other, and R₃ and R₆ may be identical to each other.

In one or more embodiments, ring CY₄ and ring CY₅ may be identical to each other.

In an embodiment, the condensed cyclic compound represented by Formula 1 may be one of Compounds 1 to 56:

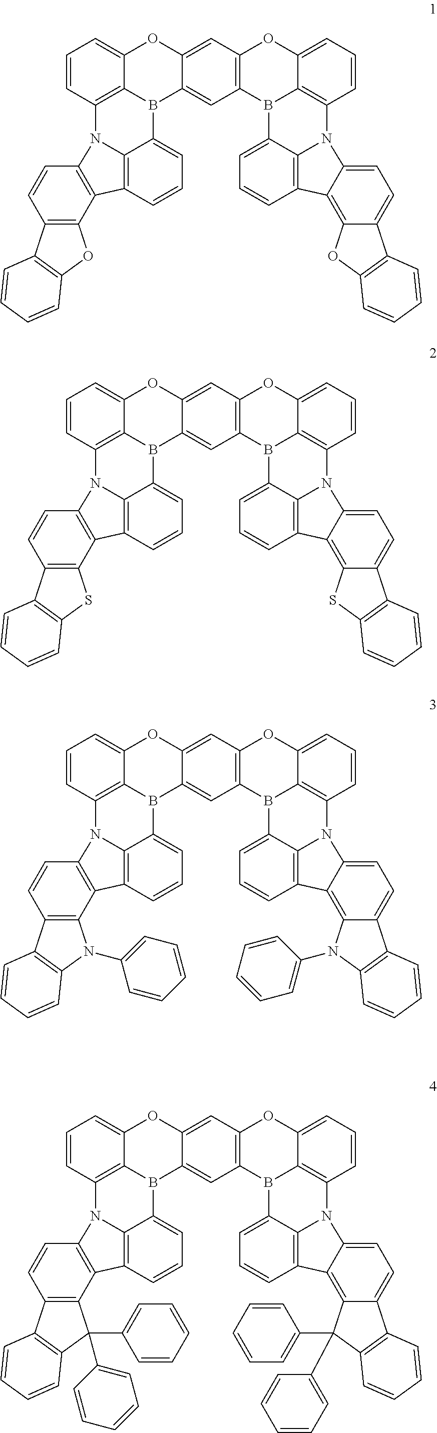 [SMILES: c1cc2c3c(c1)-n1c4ccc5c6ccccc6oc5c4c4cccc(c41)B3c1cc3c(cc1O2)Oc1cccc2c1B3c1cccc3c4c5oc6ccccc6c5ccc4n-2c13 ; c1cc2c3c(c1)-n1c4ccc5c6ccccc6sc5c4c4cccc(c41)B3c1cc3c(cc1O2)Oc1cccc2c1B3c1cccc3c4c5sc6ccccc6c5ccc4n-2c13 ; Cc1c(N2c3ccccc3B3c4cc5c(cc4Oc4cccc2c43)Oc2cccc3c2B5c2cccc4c5c(ccc6c7ccccc7n(-c7ccccc7)c65)n-3c24)ccc2c3ccccc3n(-c3ccccc3)c12 ; Cc1c(N2c3ccccc3B3c4cc5c(cc4Oc4cccc2c43)Oc2cccc3c2B5c2cccc4c5c6c(ccc5n-3c24)-c2ccccc2C6(c2ccccc2)c2ccccc2)ccc2c1C(c1ccccc1)(c1ccccc1)c1ccccc1-2]

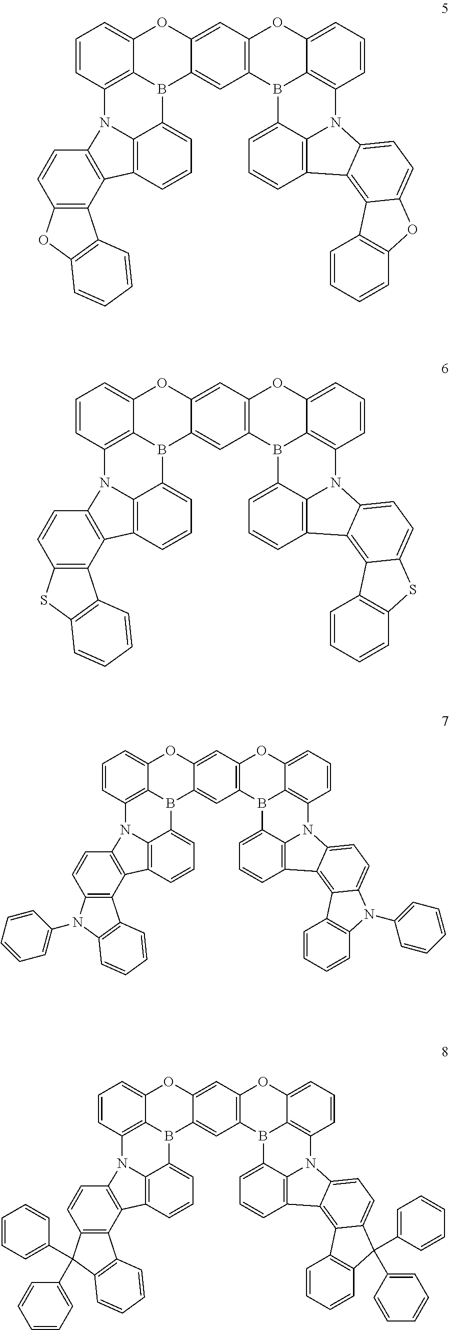 [SMILES: c1cc2c3c(c1)-n1c4ccc5oc6ccccc6c5c4c4cccc(c41)B3c1cc3c(cc1O2)Oc1cccc2c1B3c1cccc3c4c5c(ccc4n-2c13)oc1ccccc15 ; c1cc2c3c(c1)-n1c4ccc5sc6ccccc6c5c4c4cccc(c41)B3c1cc3c(cc1O2)Oc1cccc2c1B3c1cccc3c4c5c(ccc4n-2c13)sc1ccccc15 ; c1ccc(-n2c3ccccc3c3c4c5cccc6c5n(c4ccc32)-c2cccc3c2B6c2cc4c(cc2O3)Oc2cccc3c2B4c2cccc4c5c6c7ccccc7n(-c7ccccc7)c6ccc5n-3c24)cc1 ; c1ccc(C2(c3ccccc3)c3ccccc3-c3c2ccc2c3c3cccc4c3n2-c2cccc3c2B4c2cc4c(cc2O3)Oc2cccc3c2B4c2cccc4c5c6c(ccc5n-3c24)C(c2ccccc2)(c2ccccc2)c2ccccc2-6)cc1]

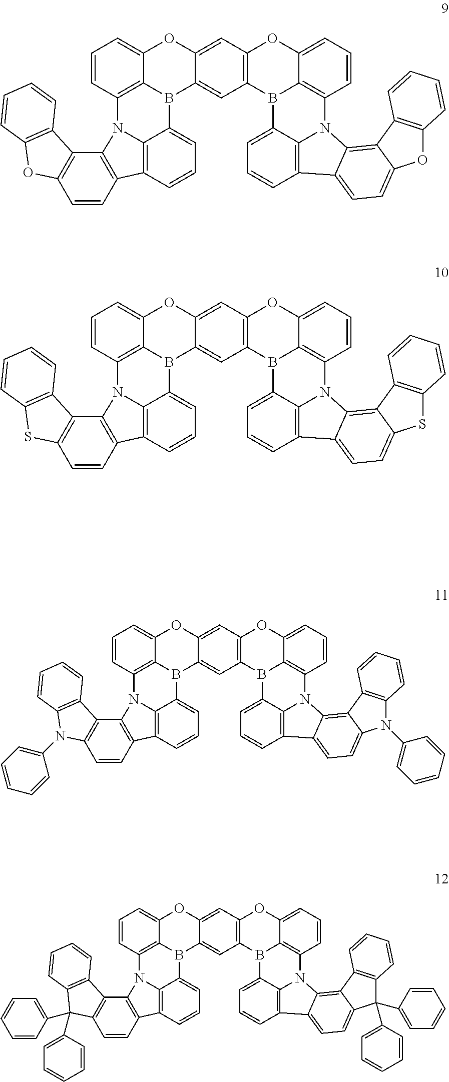 [SMILES: c1cc2c3c(c1)-n1c4c(cccc4c4ccc5oc6ccccc6c5c41)B3c1cc3c(cc1O2)Oc1cccc2c1B3c1cccc3c4ccc5oc6ccccc6c5c4n-2c13 ; c1cc2c3c(c1)-n1c4c(cccc4c4ccc5sc6ccccc6c5c41)B3c1cc3c(cc1O2)Oc1cccc2c1B3c1cccc3c4ccc5sc6ccccc6c5c4n-2c13 ; c1ccc(-n2c3ccccc3c3c2ccc2c4cccc5c4n(c23)-c2cccc3c2B5c2cc4c(cc2O3)Oc2cccc3c2B4c2cccc4c5ccc6c(c7ccccc7n6-c6ccccc6)c5n-3c24)cc1 ; c1ccc(C2(c3ccccc3)c3ccccc3-c3c2ccc2c4cccc5c4n(c32)-c2cccc3c2B5c2cc4c(cc2O3)Oc2cccc3c2B4c2cccc4c5ccc6c(c5n-3c24)-c2ccccc2C6(c2ccccc2)c2ccccc2)cc1]

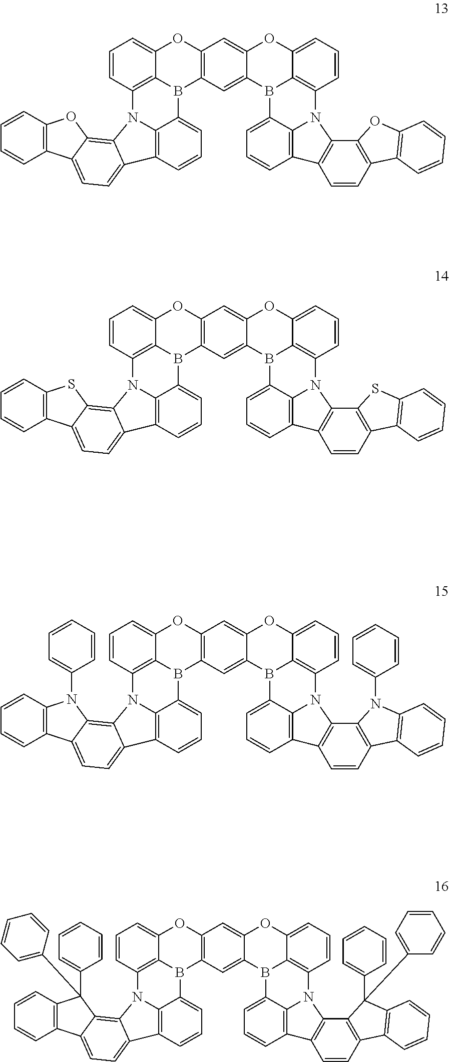 [SMILES: c1cc2c3c(c1)-n1c4c(cccc4c4ccc5c6ccccc6oc5c41)B3c1cc3c(cc1O2)Oc1cccc2c1B3c1cccc3c4ccc5c6ccccc6oc5c4n-2c13 ; c1cc2c3c(c1)-n1c4c(cccc4c4ccc5c6ccccc6sc5c41)B3c1cc3c(cc1O2)Oc1cccc2c1B3c1cccc3c4ccc5c6ccccc6sc5c4n-2c13 ; c1ccc(-n2c3ccccc3c3ccc4c5cccc6c5n(c4c32)-c2cccc3c2B6c2cc4c(cc2O3)Oc2cccc3c2B4c2cccc4c5ccc6c7ccccc7n(-c7ccccc7)c6c5n-3c24)cc1 ; c1ccc(C2(c3ccccc3)c3ccccc3-c3ccc4c5cccc6c5n(c4c32)-c2cccc3c2B6c2cc4c(cc2O3)Oc2cccc3c2B4c2cccc4c5ccc6c(c5n-3c24)C(c2ccccc2)(c2ccccc2)c2ccccc2-6)cc1]

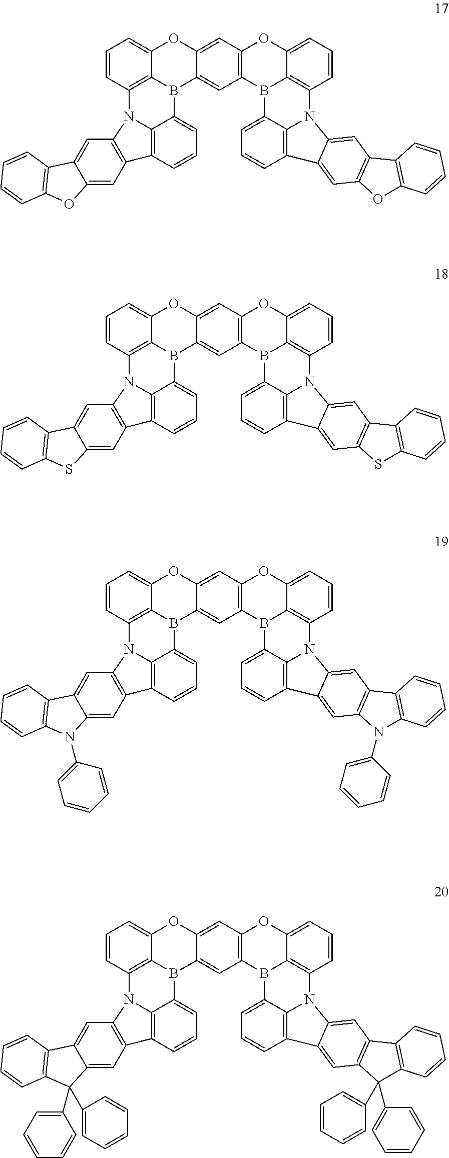 [SMILES: c1cc2c3c(c1)-n1c4cc5c(cc4c4cccc(c41)B3c1cc3c(cc1O2)Oc1cccc2c1B3c1cccc3c4cc6oc7ccccc7c6cc4n-2c13)oc1ccccc15 ; c1cc2c3c(c1)-n1c4cc5c(cc4c4cccc(c41)B3c1cc3c(cc1O2)Oc1cccc2c1B3c1cccc3c4cc6sc7ccccc7c6cc4n-2c13)sc1ccccc15 ; c1ccc(-n2c3ccccc3c3cc4c(cc32)c2cccc3c2n4-c2cccc4c2B3c2cc3c(cc2O4)Oc2cccc4c2B3c2cccc3c5cc6c(cc5n-4c23)c2ccccc2n6-c2ccccc2)cc1 ; c1ccc(C2(c3ccccc3)c3ccccc3-c3cc4c(cc32)c2cccc3c2n4-c2cccc4c2B3c2cc3c(cc2O4)Oc2cccc4c2B3c2cccc3c5cc6c(cc5n-4c23)-c2ccccc2C6(c2ccccc2)c2ccccc2)cc1]

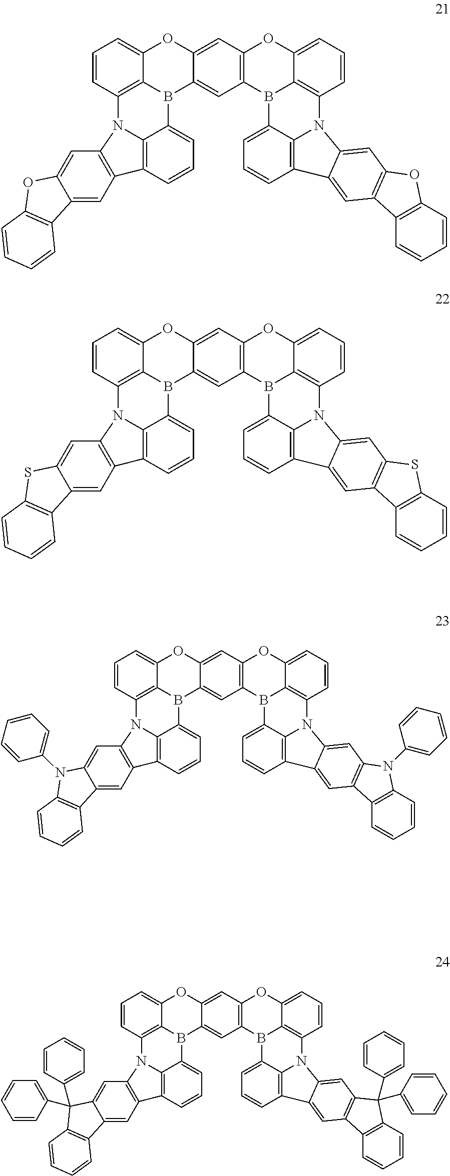 [SMILES: c1cc2c3c(c1)-n1c4cc5oc6ccccc6c5cc4c4cccc(c41)B3c1cc3c(cc1O2)Oc1cccc2c1B3c1cccc3c4cc5c(cc4n-2c13)oc1ccccc15 ; c1cc2c3c(c1)-n1c4cc5sc6ccccc6c5cc4c4cccc(c41)B3c1cc3c(cc1O2)Oc1cccc2c1B3c1cccc3c4cc5c(cc4n-2c13)sc1ccccc15 ; c1ccc(-n2c3ccccc3c3cc4c5cccc6c5n(c4cc32)-c2cccc3c2B6c2cc4c(cc2O3)Oc2cccc3c2B4c2cccc4c5cc6c7ccccc7n(-c7ccccc7)c6cc5n-3c24)cc1 ; c1ccc(C2(c3ccccc3)c3ccccc3-c3cc4c5cccc6c5n(c4cc32)-c2cccc3c2B6c2cc4c(cc2O3)Oc2cccc3c2B4c2cccc4c5cc6c(cc5n-3c24)C(c2ccccc2)(c2ccccc2)c2ccccc2-6)cc1]

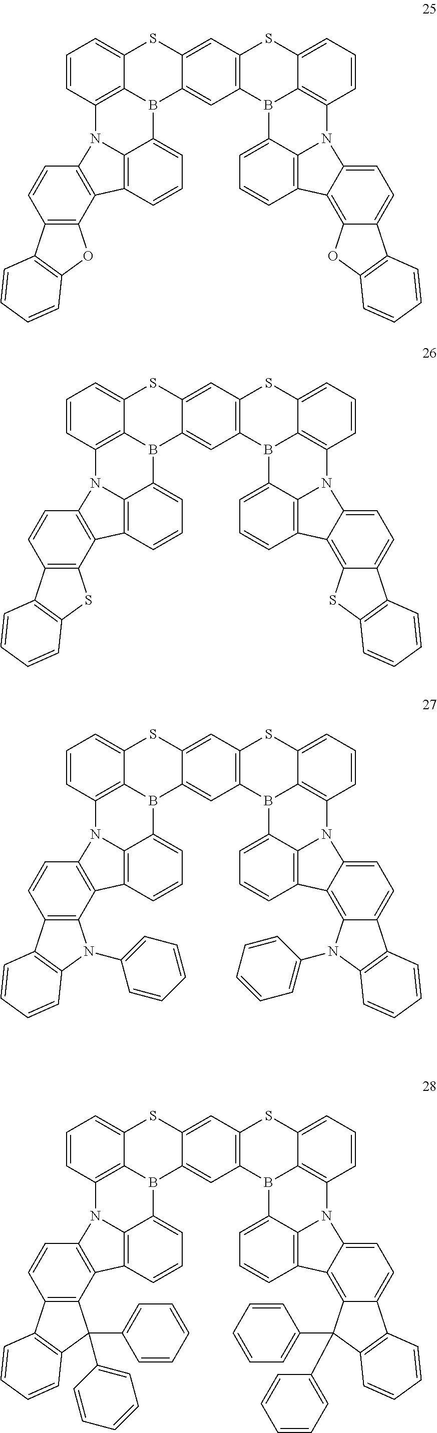 [SMILES: c1cc2c3c(c1)-n1c4ccc5c6ccccc6oc5c4c4cccc(c41)B3c1cc3c(cc1S2)Sc1cccc2c1B3c1cccc3c4c5oc6ccccc6c5ccc4n-2c13 ; c1cc2c3c(c1)-n1c4ccc5c6ccccc6sc5c4c4cccc(c41)B3c1cc3c(cc1S2)Sc1cccc2c1B3c1cccc3c4c5sc6ccccc6c5ccc4n-2c13 ; Cc1c(N2c3ccccc3B3c4cc5c(cc4Sc4cccc2c43)Sc2cccc3c2B5c2cccc4c5c(ccc6c7ccccc7n(-c7ccccc7)c65)n-3c24)ccc2c3ccccc3n(-c3ccccc3)c12 ; Cc1c(N2c3ccccc3B3c4cc5c(cc4Sc4cccc2c43)Sc2cccc3c2B5c2cccc4c5c6c(ccc5n-3c24)-c2ccccc2C6(c2ccccc2)c2ccccc2)ccc2c1C(c1ccccc1)(c1ccccc1)c1ccccc1-2]

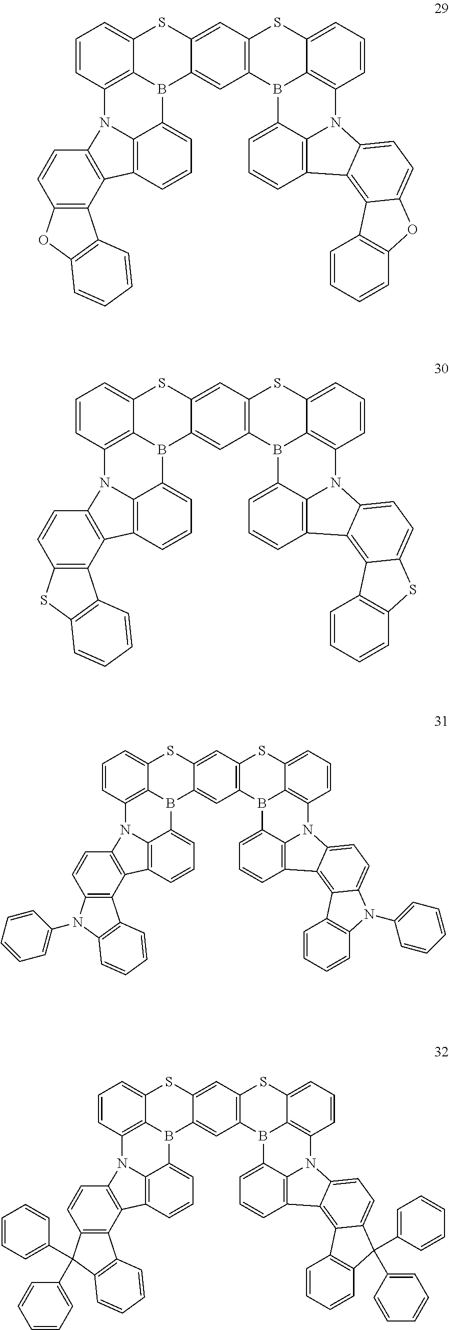 [SMILES: c1cc2c3c(c1)-n1c4ccc5oc6ccccc6c5c4c4cccc(c41)B3c1cc3c(cc1S2)Sc1cccc2c1B3c1cccc3c4c5c(ccc4n-2c13)oc1ccccc15 ; c1cc2c3c(c1)-n1c4ccc5sc6ccccc6c5c4c4cccc(c41)B3c1cc3c(cc1S2)Sc1cccc2c1B3c1cccc3c4c5c(ccc4n-2c13)sc1ccccc15 ; c1ccc(-n2c3ccccc3c3c4c5cccc6c5n(c4ccc32)-c2cccc3c2B6c2cc4c(cc2S3)Sc2cccc3c2B4c2cccc4c5c6c7ccccc7n(-c7ccccc7)c6ccc5n-3c24)cc1 ; c1ccc(C2(c3ccccc3)c3ccccc3-c3c2ccc2c3c3cccc4c3n2-c2cccc3c2B4c2cc4c(cc2S3)Sc2cccc3c2B4c2cccc4c5c6c(ccc5n-3c24)C(c2ccccc2)(c2ccccc2)c2ccccc2-6)cc1]

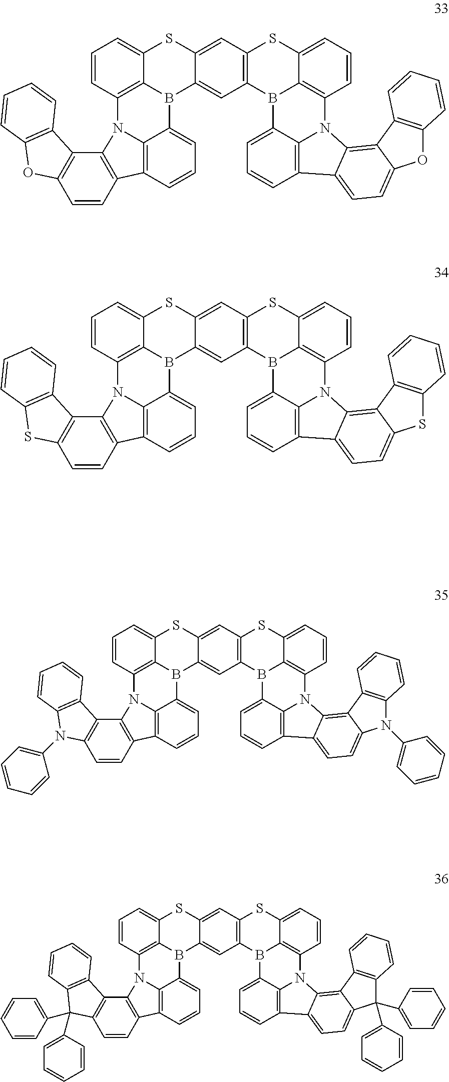 [SMILES: c1cc2c3c(c1)-n1c4c(cccc4c4ccc5oc6ccccc6c5c41)B3c1cc3c(cc1S2)Sc1cccc2c1B3c1cccc3c4ccc5oc6ccccc6c5c4n-2c13 ; c1cc2c3c(c1)-n1c4c(cccc4c4ccc5sc6ccccc6c5c41)B3c1cc3c(cc1S2)Sc1cccc2c1B3c1cccc3c4ccc5sc6ccccc6c5c4n-2c13 ; c1ccc(-n2c3ccccc3c3c2ccc2c4cccc5c4n(c23)-c2cccc3c2B5c2cc4c(cc2S3)Sc2cccc3c2B4c2cccc4c5ccc6c(c7ccccc7n6-c6ccccc6)c5n-3c24)cc1 ; c1ccc(C2(c3ccccc3)c3ccccc3-c3c2ccc2c4cccc5c4n(c32)-c2cccc3c2B5c2cc4c(cc2S3)Sc2cccc3c2B4c2cccc4c5ccc6c(c5n-3c24)-c2ccccc2C6(c2ccccc2)c2ccccc2)cc1]

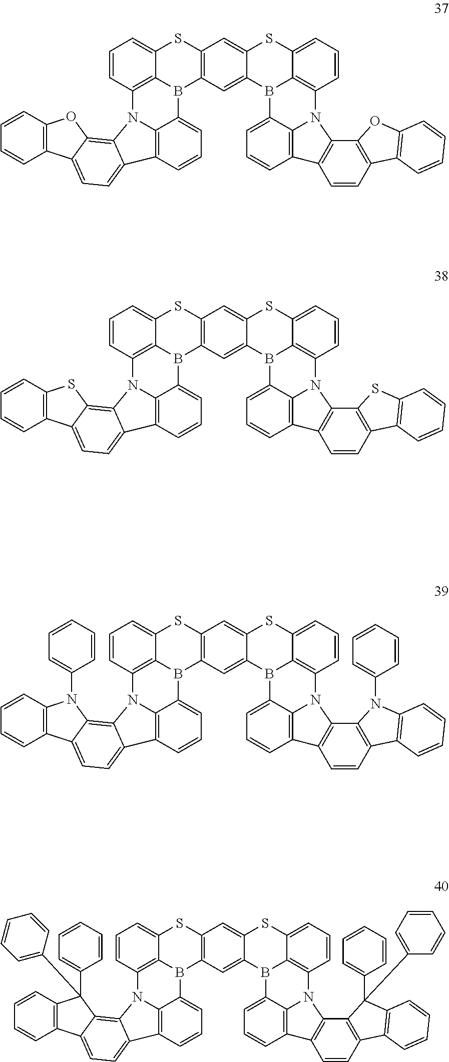 [SMILES: c1cc2c3c(c1)-n1c4c(cccc4c4ccc5c6ccccc6oc5c41)B3c1cc3c(cc1S2)Sc1cccc2c1B3c1cccc3c4ccc5c6ccccc6oc5c4n-2c13 ; c1cc2c3c(c1)-n1c4c(cccc4c4ccc5c6ccccc6sc5c41)B3c1cc3c(cc1S2)Sc1cccc2c1B3c1cccc3c4ccc5c6ccccc6sc5c4n-2c13 ; c1ccc(-n2c3ccccc3c3ccc4c5cccc6c5n(c4c32)-c2cccc3c2B6c2cc4c(cc2S3)Sc2cccc3c2B4c2cccc4c5ccc6c7ccccc7n(-c7ccccc7)c6c5n-3c24)cc1 ; c1ccc(C2(c3ccccc3)c3ccccc3-c3ccc4c5cccc6c5n(c4c32)-c2cccc3c2B6c2cc4c(cc2S3)Sc2cccc3c2B4c2cccc4c5ccc6c(c5n-3c24)C(c2ccccc2)(c2ccccc2)c2ccccc2-6)cc1]

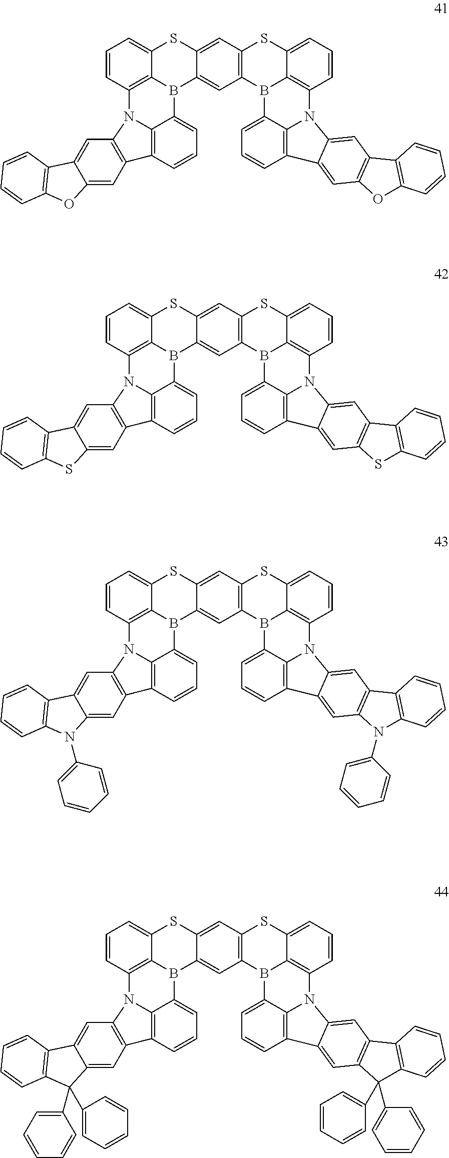 [SMILES: c1cc2c3c(c1)-n1c4cc5c(cc4c4cccc(c41)B3c1cc3c(cc1S2)Sc1cccc2c1B3c1cccc3c4cc6oc7ccccc7c6cc4n-2c13)oc1ccccc15 ; c1cc2c3c(c1)-n1c4cc5c(cc4c4cccc(c41)B3c1cc3c(cc1S2)Sc1cccc2c1B3c1cccc3c4cc6sc7ccccc7c6cc4n-2c13)sc1ccccc15 ; c1ccc(-n2c3ccccc3c3cc4c(cc32)c2cccc3c2n4-c2cccc4c2B3c2cc3c(cc2S4)Sc2cccc4c2B3c2cccc3c5cc6c(cc5n-4c23)c2ccccc2n6-c2ccccc2)cc1 ; c1ccc(C2(c3ccccc3)c3ccccc3-c3cc4c(cc32)c2cccc3c2n4-c2cccc4c2B3c2cc3c(cc2S4)Sc2cccc4c2B3c2cccc3c5cc6c(cc5n-4c23)-c2ccccc2C6(c2ccccc2)c2ccccc2)cc1]

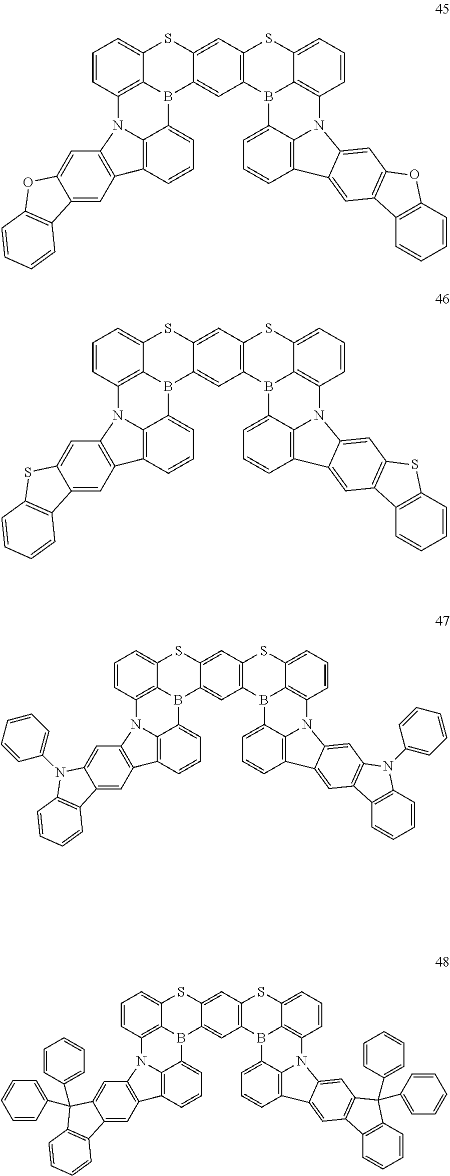 [SMILES: c1cc2c3c(c1)-n1c4cc5oc6ccccc6c5cc4c4cccc(c41)B3c1cc3c(cc1S2)Sc1cccc2c1B3c1cccc3c4cc5c(cc4n-2c13)oc1ccccc15 ; c1cc2c3c(c1)-n1c4cc5sc6ccccc6c5cc4c4cccc(c41)B3c1cc3c(cc1S2)Sc1cccc2c1B3c1cccc3c4cc5c(cc4n-2c13)sc1ccccc15 ; c1ccc(-n2c3ccccc3c3cc4c5cccc6c5n(c4cc32)-c2cccc3c2B6c2cc4c(cc2S3)Sc2cccc3c2B4c2cccc4c5cc6c7ccccc7n(-c7ccccc7)c6cc5n-3c24)cc1 ; c1ccc(C2(c3ccccc3)c3ccccc3-c3cc4c5cccc6c5n(c4cc32)-c2cccc3c2B6c2cc4c(cc2S3)Sc2cccc3c2B4c2cccc4c5cc6c(cc5n-3c24)C(c2ccccc2)(c2ccccc2)c2ccccc2-6)cc1]

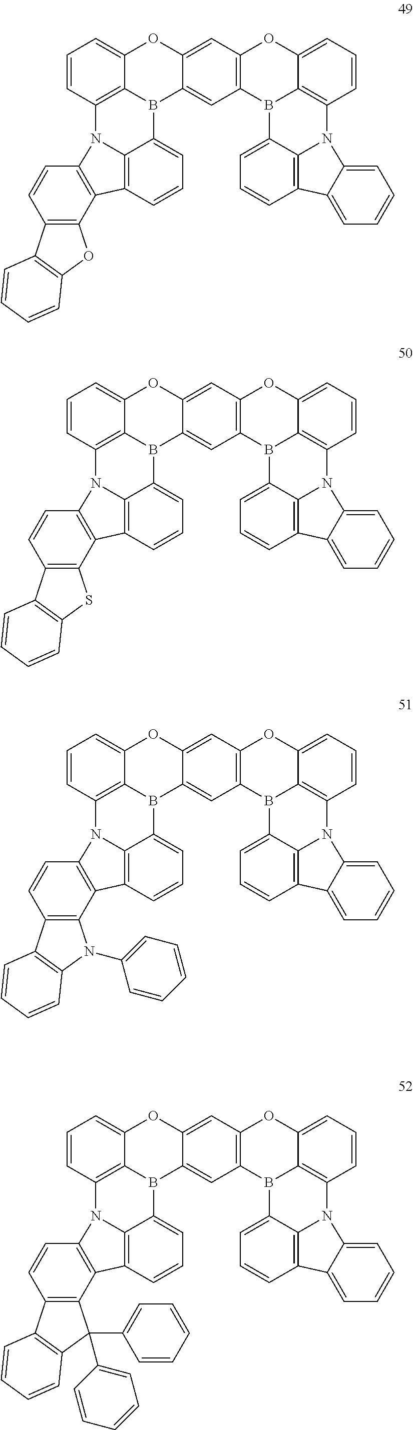 [SMILES: c1cc2c3c(c1)-n1c4ccccc4c4cccc(c41)B3c1cc3c(cc1O2)Oc1cccc2c1B3c1cccc3c4c5oc6ccccc6c5ccc4n-2c13 ; c1cc2c3c(c1)-n1c4ccccc4c4cccc(c41)B3c1cc3c(cc1O2)Oc1cccc2c1B3c1cccc3c4c5sc6ccccc6c5ccc4n-2c13 ; Cc1ccccc1N1c2ccccc2B2c3cc4c(cc3Oc3cccc1c32)Oc1cccc2c1B4c1cccc3c4c(ccc5c6ccccc6n(-c6ccccc6)c54)n-2c13 ; Cc1ccccc1N1c2ccccc2B2c3cc4c(cc3Oc3cccc1c32)Oc1cccc2c1B4c1cccc3c4c5c(ccc4n-2c13)-c1ccccc1C5(c1ccccc1)c1ccccc1]

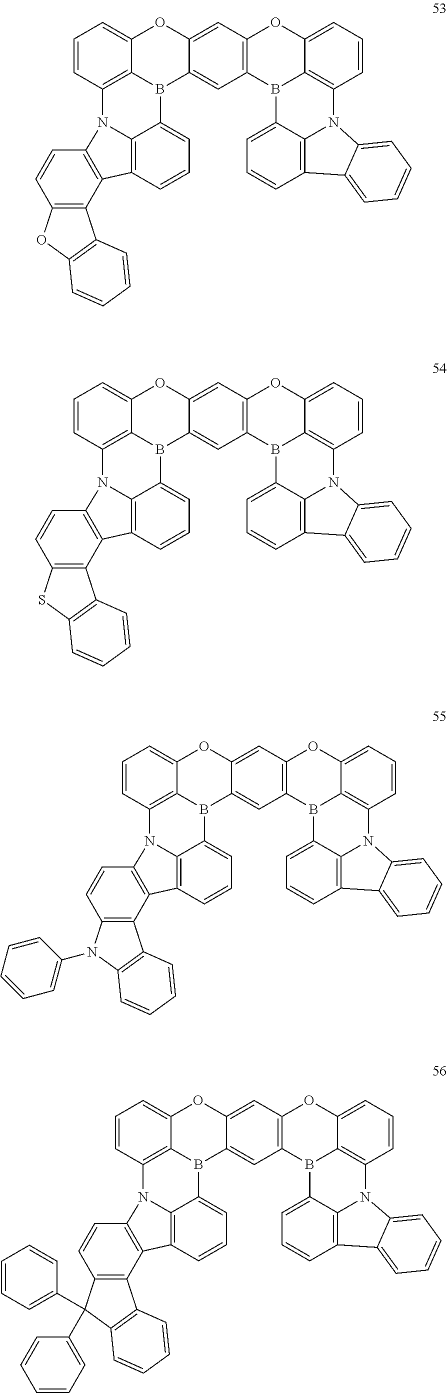 [SMILES: c1cc2c3c(c1)-n1c4ccccc4c4cccc(c41)B3c1cc3c(cc1O2)Oc1cccc2c1B3c1cccc3c4c5c(ccc4n-2c13)oc1ccccc15 ; c1cc2c3c(c1)-n1c4ccccc4c4cccc(c41)B3c1cc3c(cc1O2)Oc1cccc2c1B3c1cccc3c4c5c(ccc4n-2c13)sc1ccccc15 ; c1ccc(-n2c3ccccc3c3c4c5cccc6c5n(c4ccc32)-c2cccc3c2B6c2cc4c(cc2O3)Oc2cccc3c2B4c2cccc4c5ccccc5n-3c24)cc1 ; c1ccc(C2(c3ccccc3)c3ccccc3-c3c2ccc2c3c3cccc4c3n2-c2cccc3c2B4c2cc4c(cc2O3)Oc2cccc3c2B4c2cccc4c5ccccc5n-3c24)cc1]

The condensed cyclic compound represented by Formula 1 may have a wide plate-like structure.

In the condensed cyclic group, i) because at least one of ring CY₃ and ring CY₆ is not a benzene group, the condensed cyclic group may have a wide plate-like structure due to the condensed ring, and thus the periphery of the boron atom may become strong. Accordingly, the trigonal planar structure of the boron atom may be maintained (thereby reducing or preventing deterioration in which the structure changes into a tetrahedral structure when reacting with other nucleophiles) with structural rigidity. In addition, multiple resonance may be activated, the f-value may be increased, and ΔE_{ST} may be reduced, thereby improving light extraction efficiency. In addition, in the condensed cyclic compound, ii) because the N atom is included in the pentagonal ring structure, the single bond portion may be reduced in the condensed structure, thereby increasing the stability of the material and obtaining an effect of lengthening the absorption band by reducing the stokes shift. Therefore, the condensed cyclic compound may be utilized as a high-efficiency delayed fluorescence light emitting material, and in this regard, an electronic device, for example, an organic light-emitting device, including the condensed cyclic compound may have a low driving voltage, desired (e.g., excellent) light efficiency, and a long lifespan.

Synthesis methods of the condensed cyclic compound represented by Formula 1 may be recognizable by one of ordinary skill in the art by referring to Examples provided below.

At least one condensed cyclic compound represented by Formula 1 may be utilized in a light-emitting device (for example, an organic light-emitting device).

According to another embodiment of the present disclosure, a light-emitting device includes: a first electrode; a second electrode facing the first electrode; and an interlayer between the first electrode and the second electrode and including an emission layer, wherein the interlayer further includes a hole transport region located between the first electrode and the emission layer, the hole transport region includes a compound represented by Formula 201, a compound represented by Formula 202, or any combination thereof, and the emission layer includes at least one condensed cyclic compound represented by Formula 1:

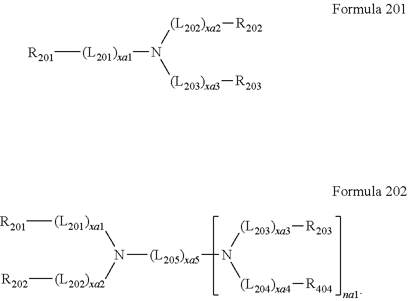

In Formulae 201 and 202,
L₂₀₁ to L₂₀₄ may each independently be a C₅-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer selected from 0 to 5,
xa5 may be an integer selected from 1 to 10,
R₂₀₁ to R₂₀₄ and Q₂₀₁ may each independently be a C₅-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ,
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer selected from 1 to 4.

In one or more embodiments,
the first electrode of the light-emitting device may be an anode,
the second electrode of the light-emitting device may be a cathode,
the interlayer may further include an electron transport region located between the emission layer and the second electrode,
the hole transport region may include a hole injection layer, a hole transport layer, an emission auxiliary layer, an electron blocking layer, or any combination thereof, and
the electron transport region may include a buffer layer, a hole blocking layer, an electron transport layer, an electron injection layer, or any combination thereof.

In one or more embodiments, the interlayer (e.g., the emission layer) of the light-emitting device may include a dopant and a host, and the host or the dopant may include the condensed cyclic compound. That is, the condensed cyclic compound may serve as the host or the dopant.

The emission layer may emit red light, green light, blue light, and/or white light. For example, the emission layer may emit blue light or turquoise light. The blue or the turquoise light may have, for example, a maximum luminescence wavelength in a range of about 400 nm to about 500 nm.

The emission layer may have a lowest excitation triplet energy level of, for example, equal to or greater than 2.4 eV and equal to or less than 3.1 eV.

The condensed cyclic compound included in the emission layer may serve as a delayed fluorescence dopant to emit delayed fluorescence from the emission layer.

In one or more embodiments, the light-emitting device may include:
a first capping layer located outside the first electrode (e.g., on the side opposite to the second electrode);
a second capping layer located outside the second electrode (e.g., on the side opposite to the first electrode); or
the first capping layer and the second capping layer.

According to another embodiment of the present disclosure, a light-emitting device includes: a first electrode, a second electrode facing the first electrode, and an interlayer located between the first electrode and the second electrode and including an emission layer,
wherein the light-emitting device may further include a second capping layer located outside the second electrode and having a refractive index of equal to or greater than 1.6, and
the emission layer includes at least one condensed cyclic compound represented by Formula 1.

In an embodiment, an encapsulation portion (e.g., an encapsulation layer) may be located on the second capping layer. The encapsulation portion may be located on the light-emitting device to protect the light-emitting device from moisture and/or oxygen.

In an embodiment, the encapsulation portion may include:
an inorganic film including silicon nitride (SiNₓ), silicon oxide (SiOₓ), indium tin oxide, indium zinc oxide, or any combination thereof;
an organic film including polyethylene tetephthalate, polyethylene naphthalate, polycarbonate, polyimide, polyethylene sulfonate, polyoxymethylene, polyarylate, hexamethyldisiloxane, acryl-based resin, epoxy-based resin, or any combination thereof; or
a combination of the inorganic film and the organic film.

According to another embodiment of the present disclosure, an electronic apparatus includes the light-emitting device. The electronic apparatus may further include a thin-film transistor.

For example, the electronic apparatus may further include a thin-film transistor including a source electrode and a drain electrode, and the first electrode of the light-emitting device may be electrically connected to the source electrode or the drain electrode.

In an embodiment, the electronic apparatus may further include a color filter, a color conversion layer, a touchscreen layer, a polarization layer, or any combination thereof. For example, the electronic apparatus may be a flat electronic apparatus, but embodiments of the present disclosure are not limited thereto.

A more detailed description of the electronic apparatus may be the same as described above.

In the present specification, the expression the “(interlayer) includes a condensed cyclic compound” may be construed as referring to the “(interlayer) may include one condensed cyclic compound of Formula 1 or two different condensed cyclic compounds of Formula 1”.

For example, the interlayer may include, as the condensed cyclic compound, only Compound 1. In an embodiment, Compound 1 may be included in the emission layer of the light-emitting device. In one or more embodiments, the interlayer may include, as the condensed cyclic compound, Compound 1 and Compound 2. In this regard, Compound 1 and Compound 2 may exist in an identical layer (for example, Compound 1 and Compound 2 may both exist in an emission layer), or different layers (for example, Compound 1 may exist in an emission layer and Compound 2 may exist in an electron transport region).

The term “interlayer” as used herein refers to a single layer and/or all of a plurality of layers located between the first electrode and the second electrode of the light-emitting device.

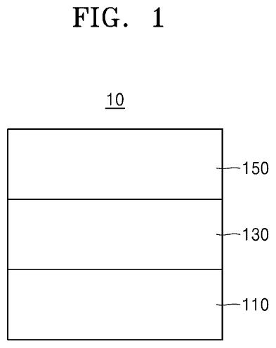

### [Description of FIG. 1]

FIG. 1 is a schematic cross-sectional view of a light-emitting device 10 according to an embodiment. The light-emitting device 10 includes a first electrode 110, an interlayer 130, and a second electrode 150.

Hereinafter, the structure of the light-emitting device 10 according to an embodiment and a method of manufacturing the light-emitting device 10 will be described in connection with FIG. 1.

### [First Electrode 110]

In FIG. 1, a substrate may be additionally located under the first electrode 110 or above the second electrode 150. The substrate may be a glass substrate or a plastic substrate. The substrate may be a flexible substrate. In one or more embodiments, the substrate may include plastics with suitable (e.g., excellent) heat resistance and durability, such as polyimide, polyethylene terephthalate (PET), polycarbonate, polyethylene naphthalate, polyarylate (PAR), polyetherimide, or a combination thereof.

The first electrode 110 may be formed by, for example, depositing or sputtering a material for forming the first electrode 110 on the substrate. When the first electrode 110 is an anode, a high work function material that can suitably (e.g., easily) inject holes may be utilized as the material for forming the first electrode 110.

The first electrode 110 may be a reflective electrode, a semi-transmissive electrode, or a transmissive electrode. When the first electrode 110 is a transmissive electrode, the material for forming the first electrode 110 may include indium tin oxide (ITO), indium zinc oxide (IZO), tin oxide (SnO₂), zinc oxide (ZnO), or any combinations thereof. In one or more embodiments, when the first electrode 110 is a semi-transmissive electrode or a reflective electrode, magnesium (Mg), silver (Ag), aluminum (Al), aluminum-lithium (Al—Li), calcium (Ca), magnesium-indium (Mg—In), magnesium-silver (Mg—Ag), or any combinations thereof may be utilized as the material for forming the first electrode 110.

The first electrode 110 may have a single-layered structure consisting of a single layer or a multi-layered structure including a plurality of layers. In an embodiment, the first electrode 110 may have a three-layered structure of ITO/Ag/ITO.

### [Interlayer 130]

The interlayer 130 is located on the first electrode 110. The interlayer 130 includes an emission layer.

The interlayer 130 may further include a hole transport region located between the first electrode 110 and the emission layer, and an electron transport region located between the emission layer and the second electrode 150.

The interlayer 130 may further include metal-containing compounds (such as organometallic compounds), inorganic materials (such as quantum dots), and/or the like, in addition to various suitable organic materials.

In one or more embodiments, the interlayer 130 may include, i) two or more emitting units sequentially stacked between the first electrode 110 and the second electrode 150, and ii) a charge generation layer located between two adjacent emitting units from among the two or more emitting units. When the interlayer 130 includes the two or more emitting units and the charge generation layer as described above, the light-emitting device 10 may be a tandem light-emitting device.

### [Hole Transport Region in Interlayer 130]

The hole transport region may have: i) a single-layered structure (e.g., consisting of a single layer) including (e.g. consisting of) a single material, ii) a single-layered structure (e.g., consisting of a single layer) including (e.g., consisting of) a plurality of different materials, or iii) a multi-layered structure including a plurality of layers including different materials.

The hole transport region may include a hole injection layer, a hole transport layer, an emission auxiliary layer, an electron blocking layer, or any combination thereof.

For example, the hole transport region may have a multi-layered structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein, in each structure, constituting layers are stacked sequentially on the first electrode 110 in the respective stated order.

The hole transport region may include the compound represented by Formula 201, the compound represented by Formula 202, or any combination thereof, as described above:

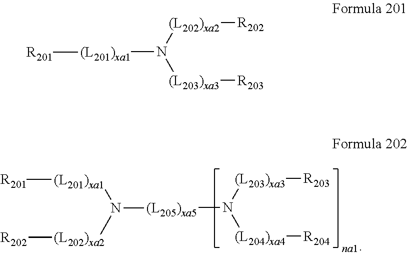

In Formulae 201 and 202,
L₂₀₁ to L₂₀₄ may each independently be a C₅-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer selected from 0 to 5,
xa5 may be an integer selected from 1 to 10,
R₂₀₁ to R₂₀₄ and Q₂₀₁ may each independently be a C₅-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ (for example, a carbazole group and/or the like) (for example, refer to the following compound HT16),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer selected from 1 to 4.

For example, Formulae 201 and 202 may each include at least one of the groups represented by Formulae CY201 to CY217:

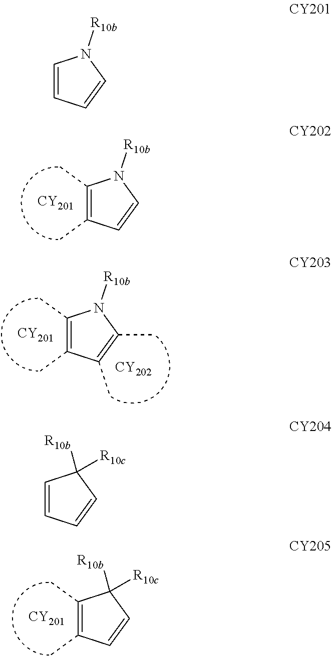

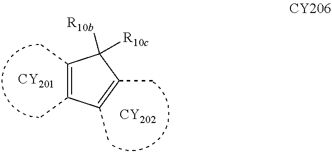

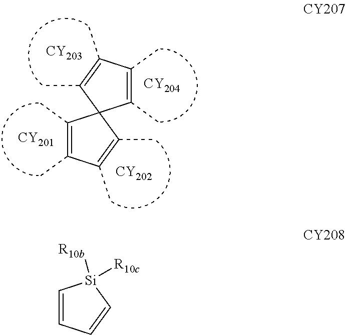

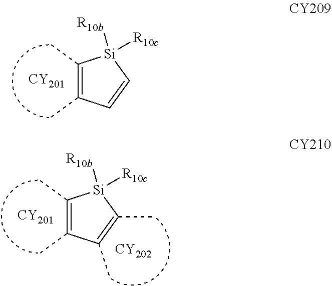

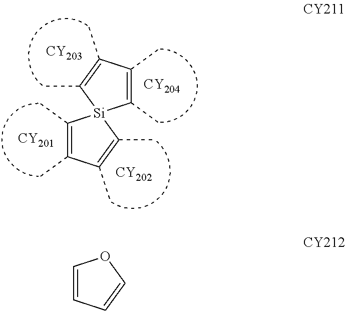

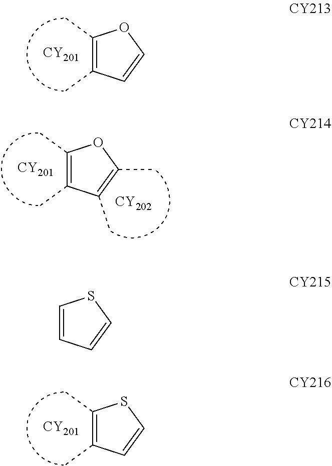

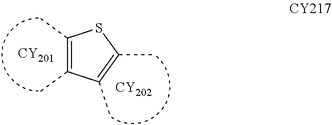

In Formulae CY201 to CY217, R_{10b} and R_{10c} may each independently be the same as described in connection with R₁₀ₐ, ring CY201 to ring CY204 may each independently be a C₃-C₂₀ carbocyclic group or a C₁-C₂₀ heterocyclic group, and at least one hydrogen in Formula CY201 to CY217 may be unsubstituted or substituted with at least one R₁₀ₐ.

In an embodiment, ring CY201 to ring CY204 in Formulae CY201 to CY217 may each independently be a benzene group, a naphthalene group, a phenanthrene group, or an anthracene group.

In one or more embodiments, Formulae 201 and 202 may each include at least one of the groups represented by Formulae CY201 to CY203.

In one or more embodiments, Formula 201 may include at least one of the groups represented by Formulae CY201 to CY203 and at least one of the groups represented by Formulae CY204 to CY217.

In one or more embodiments, in Formula 201, xa1 may be 1, R₂₀₁ may be a group represented by any of Formulae CY201 to CY203, xa2 may be 0, and R₂₀₂ may be a group represented by any of Formulae CY204 to CY207.

In one or more embodiments, each of Formulae 201 and 202 may not include any of the groups represented by Formulae CY201 to CY203.

In one or more embodiments, each of Formulae 201 and 202 may not include any of the groups represented by Formulae CY201 to CY203, and may include at least one of the groups represented by Formulae CY204 to CY217.

In one or more embodiments, each of Formulae 201 and 202 may not include any of the groups represented by Formulae CY201 to CY217.

For example, the hole transport region may include one of Compounds HT1 to HT44, m-MTDATA, TDATA, 2-TNATA, NPB(NPD), β-NPB, TPD, Spiro-TPD, Spiro-NPB, methylated-NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), 9-(4-(tert-butyl)phenyl)-3,6-bis(triphenylsilyl)-9H-carbazole (CzSi), or any combination thereof:

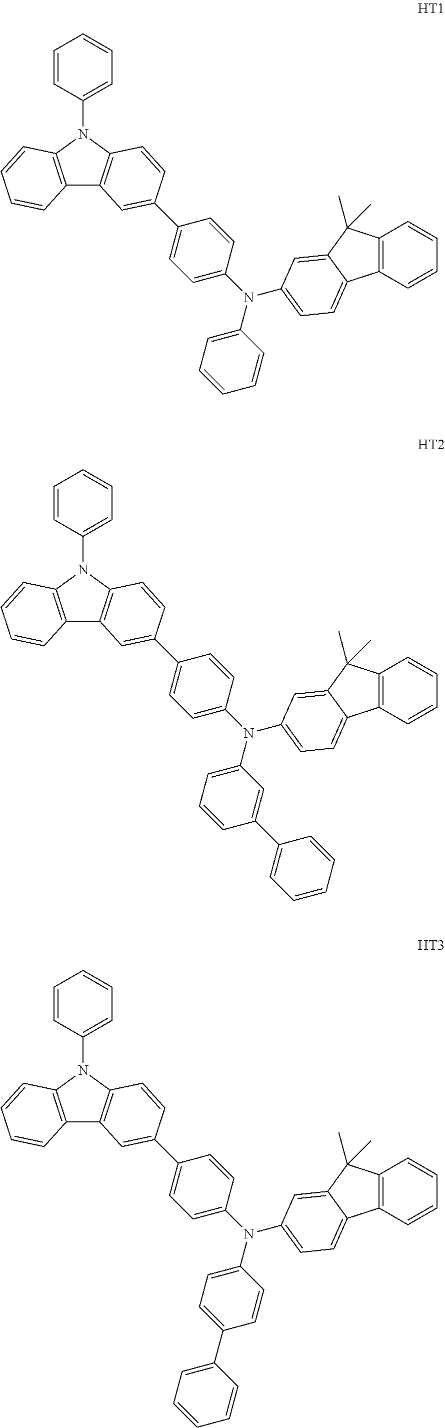 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

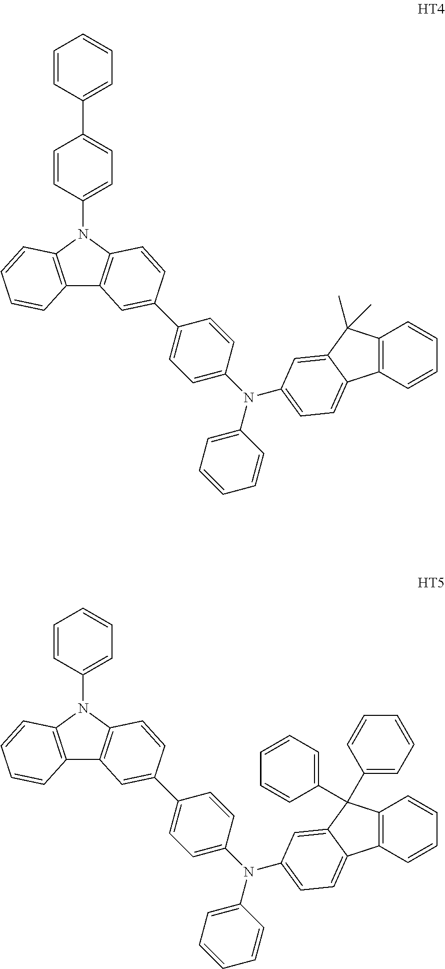 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1]

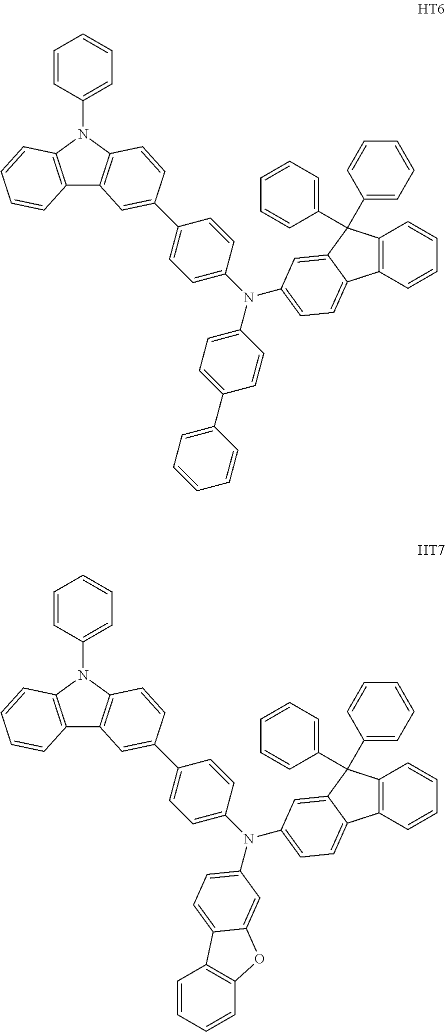 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1]

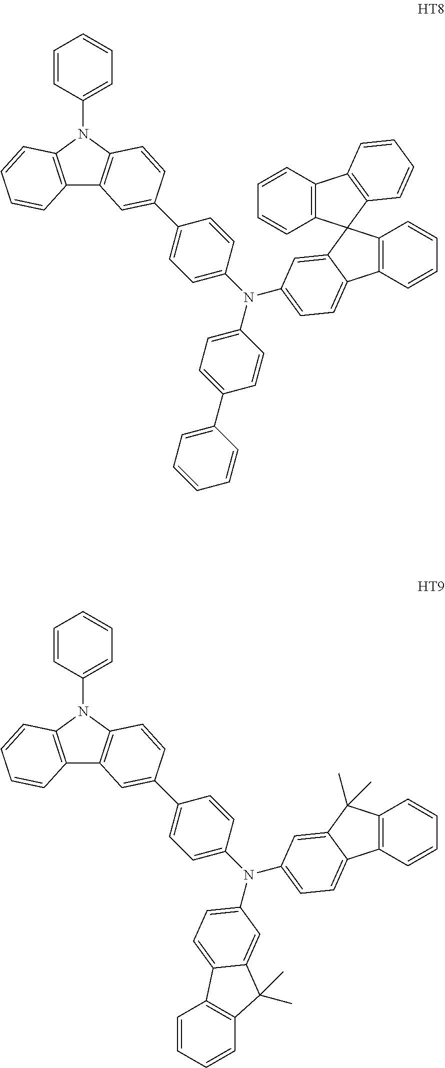 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

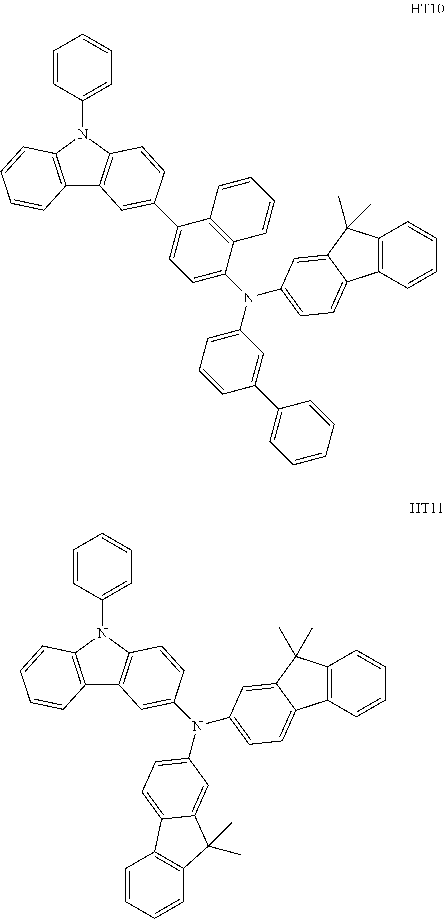 [SMILES: CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

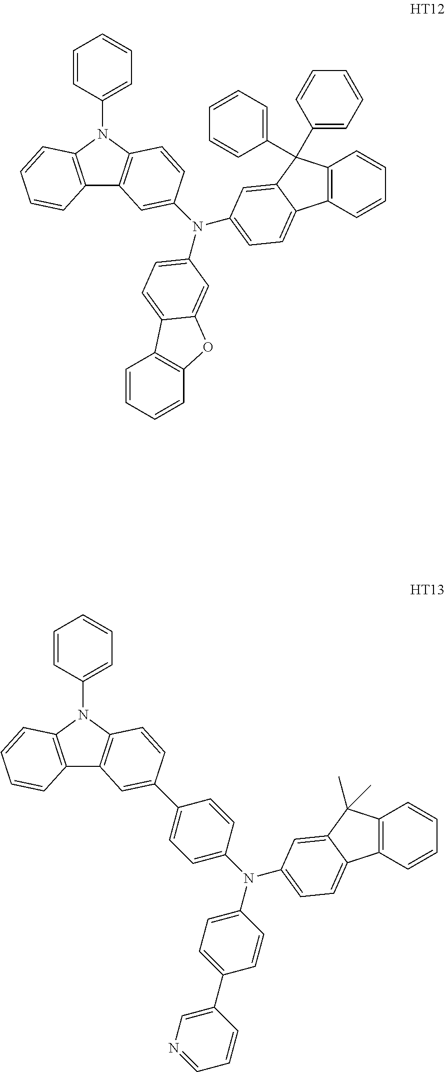 [SMILES: c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1 ; CC1(C)c2ccccc2-c2ccc(N(c3ccc(-c4cccnc4)cc3)c3ccc(-c4ccc5c(c4)c4ccccc4n5-c4ccccc4)cc3)cc21]

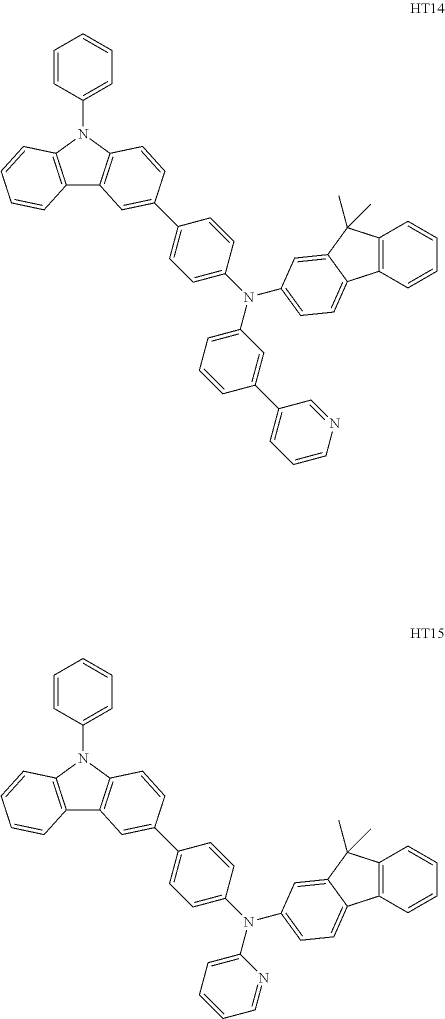 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

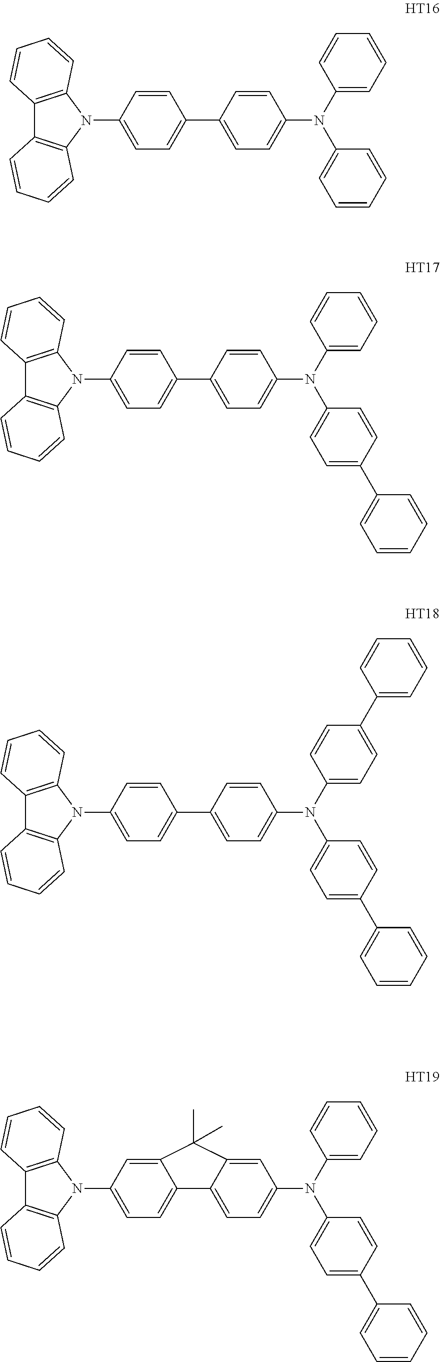 [SMILES: c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21]

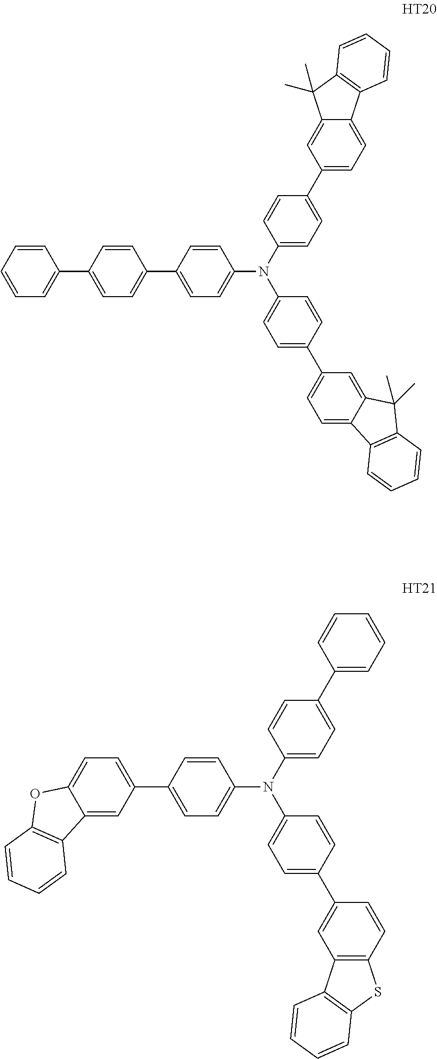 [SMILES: CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1]

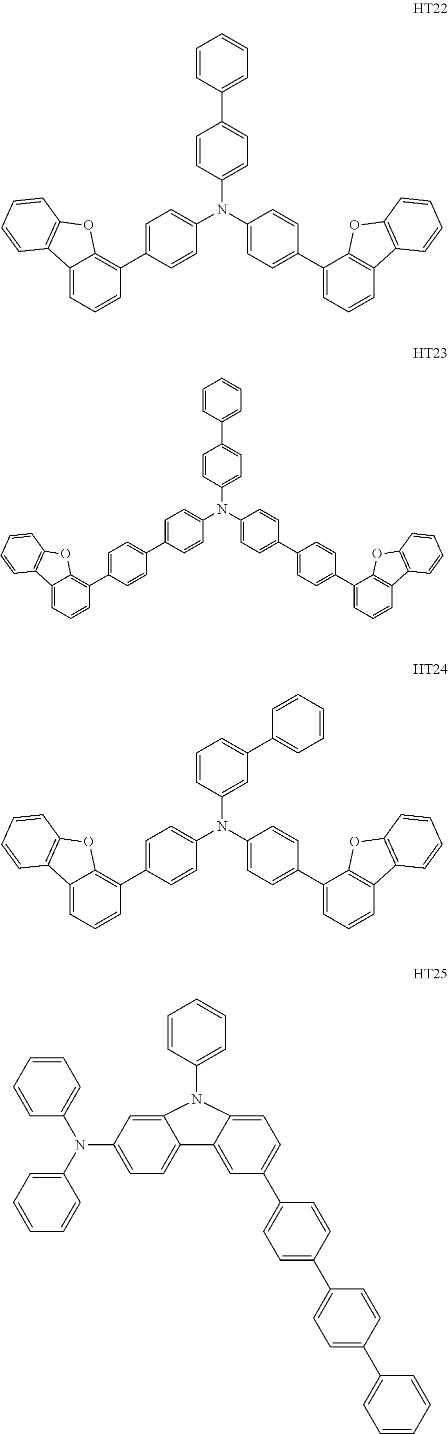 [SMILES: c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1]

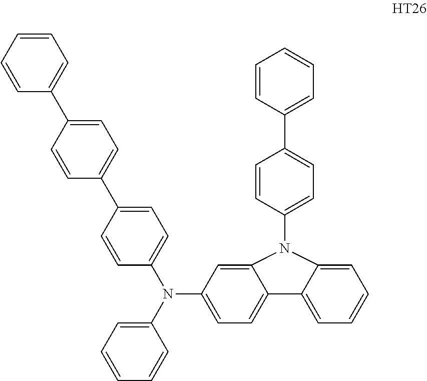 [SMILES: c1ccc(-c2ccc(-c3ccc(N(c4ccccc4)c4ccc5c6ccccc6n(-c6ccc(-c7ccccc7)cc6)c5c4)cc3)cc2)cc1]

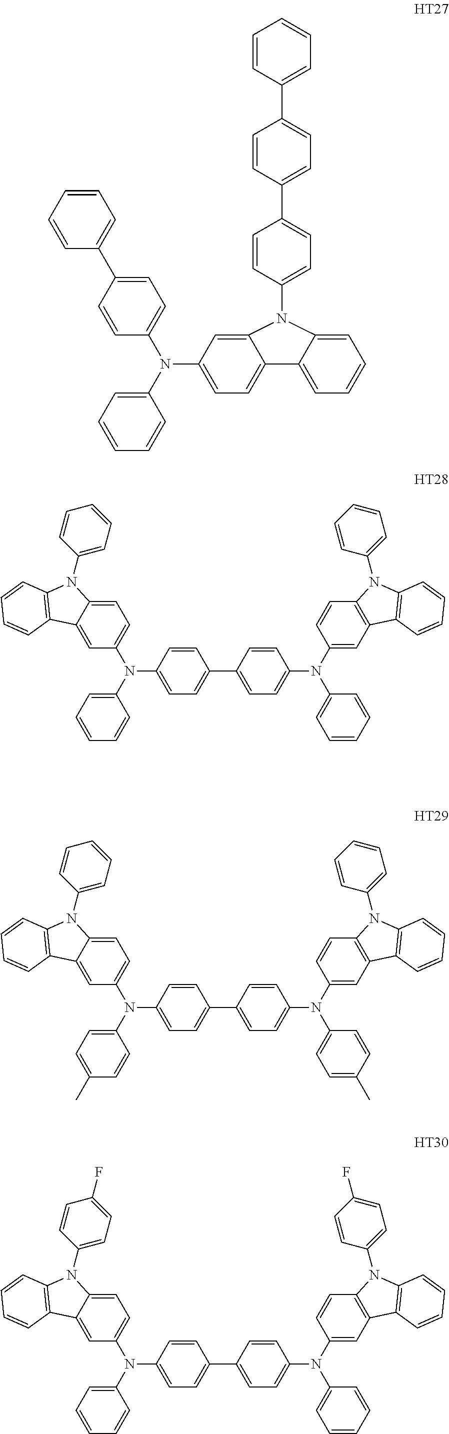 [SMILES: c1ccc(-c2ccc(-c3ccc(-n4c5ccccc5c5ccc(N(c6ccccc6)c6ccc(-c7ccccc7)cc6)cc54)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

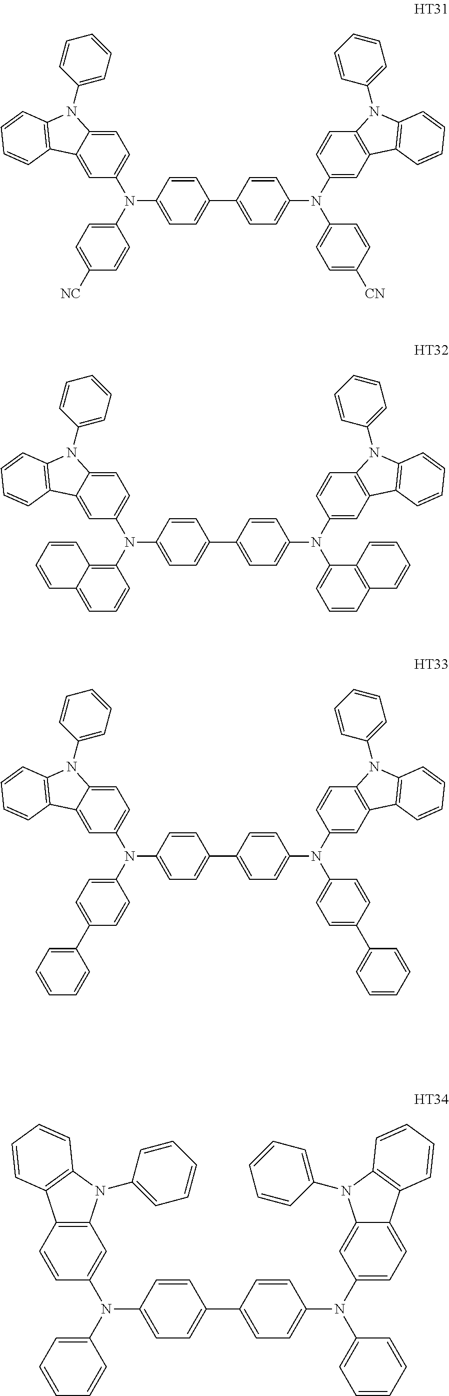 [SMILES: N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(N(c2ccc(-c3ccc(N(c4ccccc4)c4ccc5c6ccccc6n(-c6ccccc6)c5c4)cc3)cc2)c2ccc3c4ccccc4n(-c4ccccc4)c3c2)cc1]

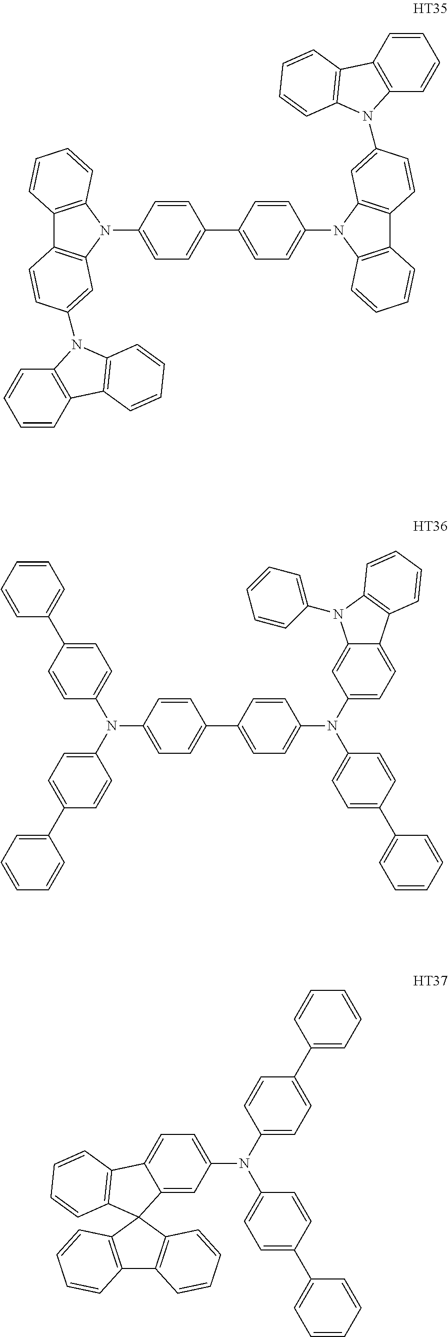 [SMILES: c1ccc2c(c1)c1ccccc1n2-c1ccc2c3ccccc3n(-c3ccc(-c4ccc(-n5c6ccccc6c6ccc(-n7c8ccccc8c8ccccc87)cc65)cc4)cc3)c2c1 ; c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1 ; c1ccc(-c2ccc(N(c3ccc(-c4ccccc4)cc3)c3ccc4c(c3)C3(c5ccccc5-c5ccccc53)c3ccccc3-4)cc2)cc1]

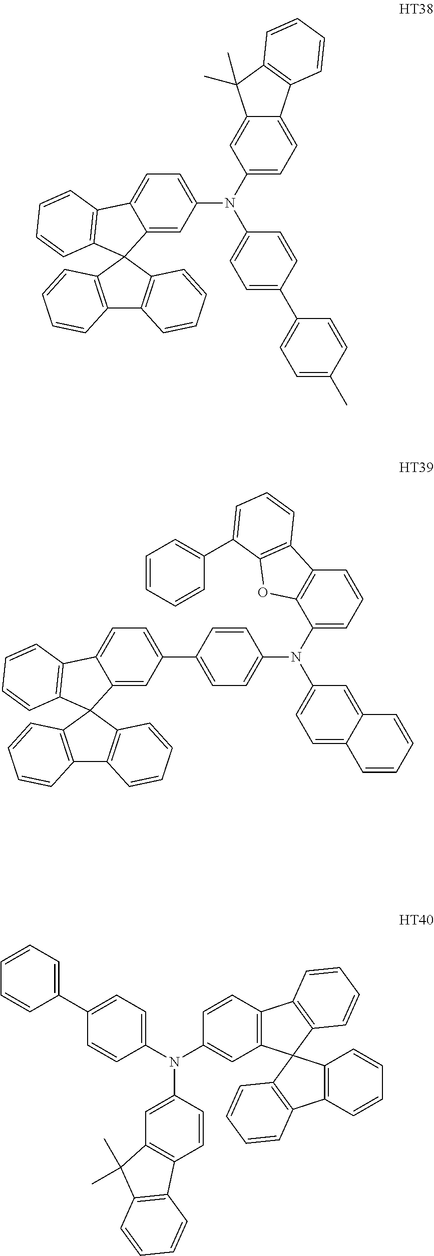 [SMILES: Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1 ; CC1(C)c2ccccc2-c2ccc(N(c3ccc(-c4ccccc4)cc3)c3ccc4c(c3)C3(c5ccccc5-c5ccccc53)c3ccccc3-4)cc21]

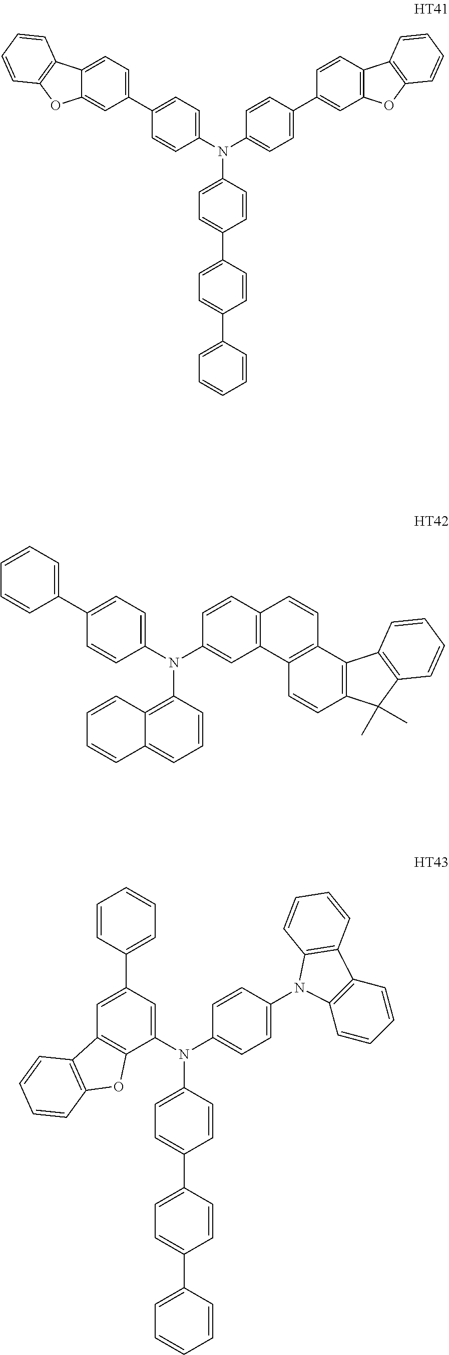 [SMILES: c1ccc(-c2ccc(-c3ccc(N(c4ccc(-c5ccc6c(c5)oc5ccccc56)cc4)c4ccc(-c5ccc6c(c5)oc5ccccc56)cc4)cc3)cc2)cc1 ; CC1(C)c2ccccc2-c2c1ccc1c2ccc2ccc(N(c3ccc(-c4ccccc4)cc3)c3cccc4ccccc34)cc21 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

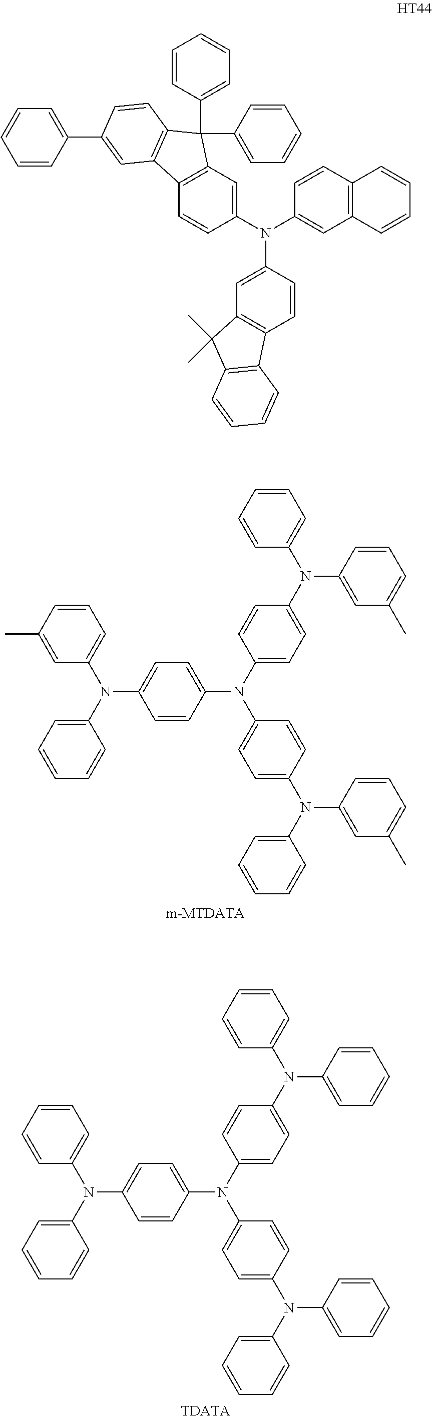

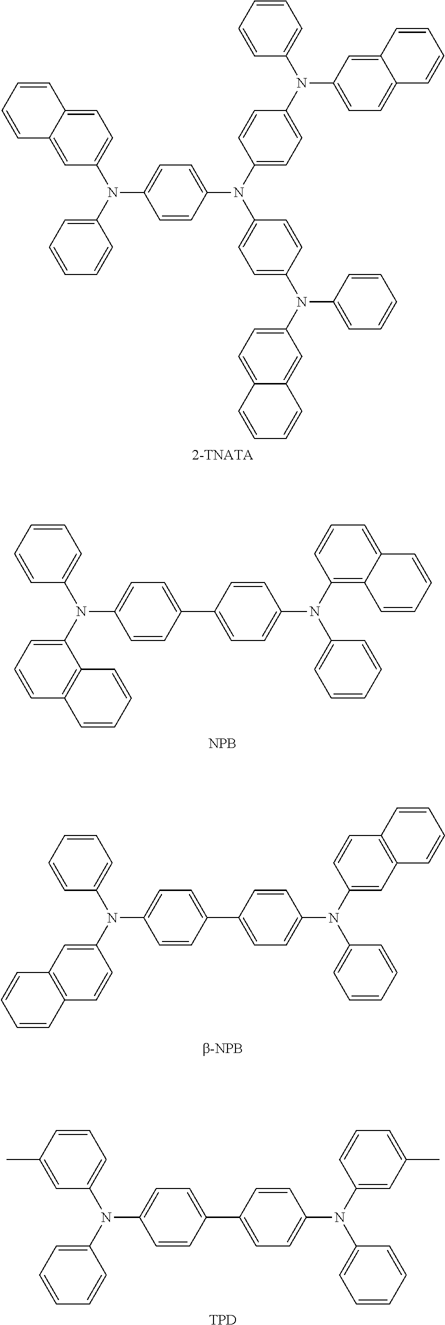

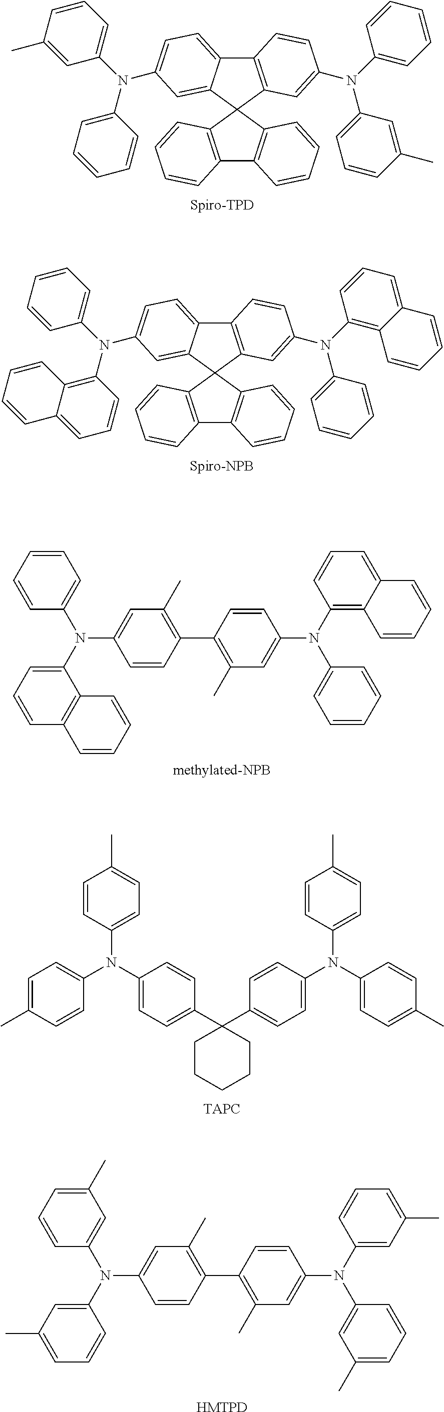

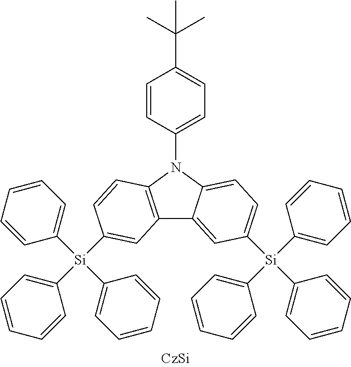 [SMILES: CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1]

A thickness of the hole transport region may be in a range of about 50 Å to about 10,000 Å, for example, about 100 Å to about 4,000 Å. When the hole transport region includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within these ranges, satisfactory hole transporting characteristics may be obtained without a substantial increase in driving voltage.

The emission auxiliary layer may increase light-emission efficiency by compensating for an optical resonance distance according to the wavelength of light emitted by the emission layer, and the electron blocking layer may block the flow of electrons from an electron transport region. The emission auxiliary layer and the electron blocking layer may include the materials as described above.

### [P-Dopant]

The hole transport region may further include, in addition to these materials, a charge-generation material for the improvement of conductive properties. The charge-generation material may be uniformly or non-uniformly dispersed in the hole transport region (for example, in the form of a single layer consisting of a charge generation material).

The charge-generation material may be, for example, a p-dopant.

In an embodiment, the p-dopant may have a lowest unoccupied molecular orbital (LUMO) energy level of equal to or less than −3.5 eV.

In an embodiment, the p-dopant may include a quinone derivative, a cyano group-containing compound, a compound containing Elements EL1 and EL2 (to be described in more detail below), or any combination thereof.

Non-limiting examples of the quinone derivative are TCNQ and F4-TCNQ.

Non-limiting examples of the cyano group-containing compound are HAT-CN and a compound represented by Formula 221:

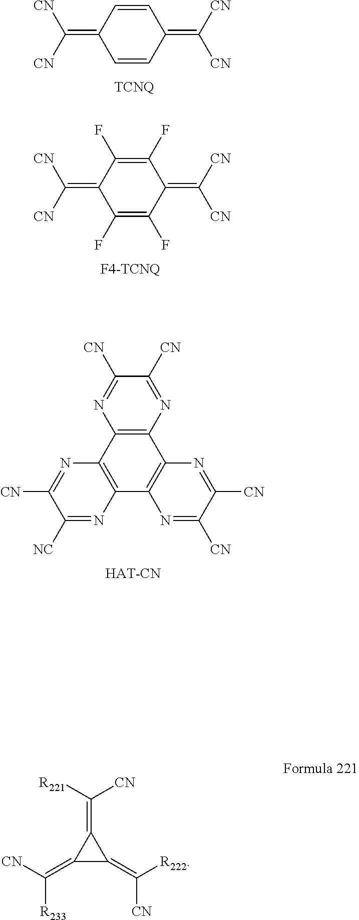

In Formula 221,
R₂₂₁ to R₂₂₃ may each independently be a C₅-C₆₀ carbocyclic group unsubstituted or substituted with at least one R₁₀ₐ or a C₁-C₆₀ heterocyclic group unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

Regarding the compound containing Elements EL1 and EL2, Element EL1 may be a metal, a metalloid, or a combination thereof, and Element EL2 may be a non-metal, a metalloid, or a combination thereof.

Non-limiting examples of the metal are: an alkali metal (for example, lithium (Li), sodium (Na), potassium (K), rubidium (Rb), cesium (Cs), and/or the like); alkaline earth metal (for example, beryllium (Be), magnesium (Mg), calcium (Ca), strontium (Sr), barium (Ba), and/or the like); transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); post-transition metals (for example, zinc (Zn), indium (In), tin (Sn), and/or the like); and lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like).

Non-limiting examples of the metalloid are silicon (Si), antimony (Sb), and tellurium (Te).

Non-limiting examples of the non-metal are oxygen (O) and halogen (for example, F, Cl, Br, I, etc.).

For example, the compound containing Elements EL1 and EL2 may be a metal oxide, a metal halide (for example, metal fluoride, metal chloride, metal bromide, and/or metal iodide), a metalloid halide (for example, metalloid fluoride, metalloid chloride, metalloid bromide, and/or metalloid iodide), a metal telluride, or any combination thereof.

Non-limiting examples of the metal oxide are tungsten oxide (for example, WO, W₂O₃, WO₂, WO₃, and/or W₂O₅), vanadium oxide (for example, VO, V₂O₃, VO₂, and/or V₂O₅), molybdenum oxide (for example, MoO, Mo₂O₃, MoO₂, MoO₃, and/or Mo₂O₅), and rhenium oxide (for example, ReO₃).

Non-limiting examples of the metal halide are alkali metal halide, alkaline earth metal halide, transition metal halide, post-transition metal halide, and lanthanide metal halide.

Non-limiting examples of the alkali metal halide are LiF, NaF, KF, RbF, CsF, LiCl, NaCl, KCl, RbCl, CsCl, LiBr, NaBr, KBr, RbBr, CsBr, LiI, NaI, KI, RbI, and CsI.

Non-limiting examples of the alkaline earth metal halide are BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, Sr₁₂, and BaI₂.

Non-limiting examples of the transition metal halide are titanium halide (for example, TiF₄, TiCl₄, TiBr₄, and/or TiI₄), zirconium halide (for example, ZrF₄, ZrCl₄, ZrBr₄, and/or ZrI₄), hafnium halide (for example, HfF₄, HfCl₄, HfBr₄, and/or HfI₄), vanadium halide (for example, VF₃, VCl3, VBr₃, and/or VI₃), niobium halide (for example, NbF₃, NbCl₃, NbBr₃, and/or NbI₃), tantalum halide (for example, TaF₃, TaCl₃, TaBr₃, and/or Talk), chromium halide (for example, CrF₃, CrCl₃, CrBr₃, and/or CrI₃), molybdenum halide (for example, MoF₃, MoCl₃, MoBr₃, and/or Mols), tungsten halide (for example, WF₃, WCl₃, WBr₃, and/or WI₃), manganese halide (for example, MnF₂, MnCl₂, MnBr₂, and/or MnI₂), technetium halide (for example, TcF₂, TcCl₂, TcBr₂, and/or TcI₂), rhenium halide (for example, ReF₂, ReCl₂, ReBr₂, and/or ReI₂), iron halide (for example, FeF₂, FeCl₂, FeBr₂, and/or FeI₂), ruthenium halide (for example, RuF₂, RuCl₂, RuBr₂, and/or RuI₂), osmium halide (for example, OsF₂, OsCl₂, OsBr₂, and/or OsI₂), cobalt halide (for example, CoF₂, COCl₂, CoBr₂, and/or COI₂), rhodium halide (for example, RhF₂, RhCl₂, RhBr₂, and/or RhI₂), iridium halide (for example, IrF₂, IrCl₂, IrBr₂, and/or IrI₂), nickel halide (for example, NiF₂, NiCl₂, NiBr₂, and/or NiI₂), palladium halide (for example, PdF₂, PdCl₂, PdBr₂, and/or PdI₂), platinum halide (for example, PtF₂, PtCl₂, PtBr₂, and/or PtI₂), copper halide (for example, CuF, CuCl, CuBr, and/or CuI), silver halide (for example, AgF, AgCl, AgBr, and/or AgI), and gold halide (for example, AuF, AuCl, AuBr, and/or AuI).

Non-limiting examples of the post-transition metal halide are zinc halide (for example, ZnF₂, ZnCl₂, ZnBr₂, and/or ZnI₂), indium halide (for example, InI₃), and tin halide (for example, SnI₂).

Non-limiting examples of the lanthanide metal halide are YbF, YbF₂, YbF₃, SmF₃, YbCl, YbCl₂, YbCl₃, SmCl₃, YbBr, YbBr₂, YbBrs, SmBrs, YbI, YbI₂, YbI₃, and SmI₃.

An example of the metalloid halide is antimony halide (for example, SbCl₅).

Non-limiting examples of the metal telluride are an alkali metal telluride (for example, Li₂Te, Na₂Te, K₂Te, Rb₂Te, and/or Cs₂Te), alkaline earth metal telluride (for example, BeTe, MgTe, CaTe, SrTe, and/or BaTe), transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, and/or Au₂Te), post-transition metal telluride (for example, ZnTe), and lanthanide metal telluride (for example, LaTe, CeTe, PrTe, NdTe, PmTe, EuTe, GdTe, TbTe, DyTe, HoTe, ErTe, TmTe, YbTe, and/or LuTe).

### [Emission Layer in Interlayer 130]

When the light-emitting device 10 is a full-color light-emitting device, the emission layer may be patterned into a red emission layer, a green emission layer, and/or a blue emission layer, according to a sub-pixel. In an embodiment, the emission layer may have a stacked structure of two or more layers of a red emission layer, a green emission layer, and a blue emission layer, in which the two or more layers contact each other or are separated from each other. In one or more embodiments, the emission layer may include two or more materials of a red light-emitting material, a green light-emitting material, and a blue light-emitting material, in which the two or more materials are mixed with each other in a single layer to emit white light.

The emission layer may include a host and a dopant. The dopant may include a phosphorescent dopant, a fluorescent dopant, or any combination thereof.

An amount of the dopant in the emission layer may be in a range of about 0.01 parts by weight to about 15 parts by weight based on 100 parts by weight of the host.

In one or more embodiments, the emission layer may include a quantum dot.

In one embodiment, the emission layer may include a delayed fluorescence material. The delayed fluorescence material may serve as the host or the dopant in the emission layer.

A thickness of the emission layer may be in a range of about 100 Å to about 1,000 Å, for example, about 200 Å to about 600 Å. When the thickness of the emission layer is within these ranges, suitable (e.g., excellent) light-emission characteristics may be obtained without a substantial increase in driving voltage.

### [Host]

In an embodiment, the host may include a compound represented by Formula 301:

[Ar₃₀₁]_{xb11}-[(L₃₀₁)_{xb1}-R₃₀₁]_{xb21} Formula 301
wherein, in Formula 301,
Ar₃₀₁ and L₃₀₁ may each independently be a C₅-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer selected from 0 to 5,
R₃₀₁ may be hydrogen, deuterium, —F, —Cl, —Br, —I, hydroxyl group, cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer selected from 1 to 5, and
Q₃₀₁ to 0303 may each independently be the same as described in connection with Q₁.

In one or more embodiments, when xb11 in Formula 301 is 2 or more, two or more of Ar₃₀₁(s) may be linked to each other via a single bond.

In one or more embodiments, the host may include a compound represented by Formula 301-1, a compound represented by Formula 301-2, or any combination embodiment:

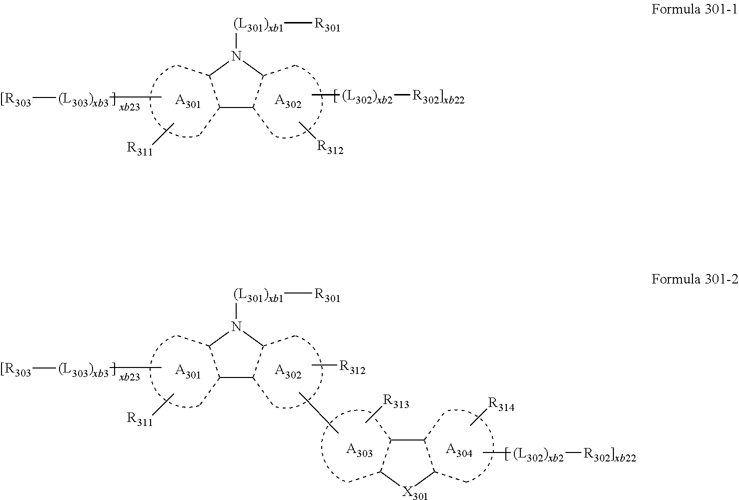

wherein, in Formulae 301-1 and 301-2,
ring A₃₀₁ to ring A₃₀₄ may each independently be a C₅-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N-[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each independently be the same as respectively described in the present specification,
L₃₀₂ to L₃₀₄ may each independently be the same as described in connection with L₃₀₁,
xb2 to xb4 may each independently be the same as described in connection with xb1, and
R₃₀₂ to R₃₀₅ and R₃₁₁ to R₃₁₄ may each independently be the same as described in connection with R₃₀₁.

In one or more embodiments, the host may include an alkaline earth metal complex. In an embodiment, the host may be a Be complex (for example, Compound H55), a Mg complex, a Zn complex, or any combination thereof.

In an embodiment, the host may include one of Compounds H1 to H124, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di-9-carbazolylbenzene (mCP), 1,3,5-tri(carbazol-9-yl)benzene (TCP), or any combination thereof, but embodiments of the present disclosure are not limited thereto:

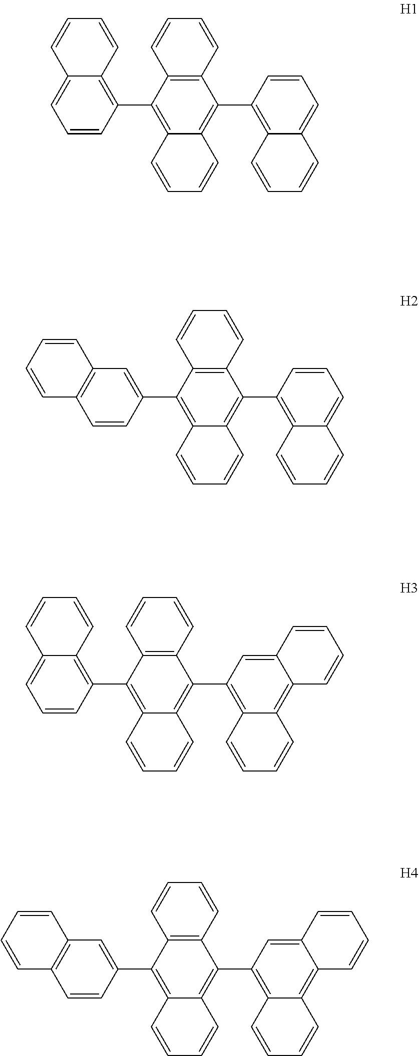

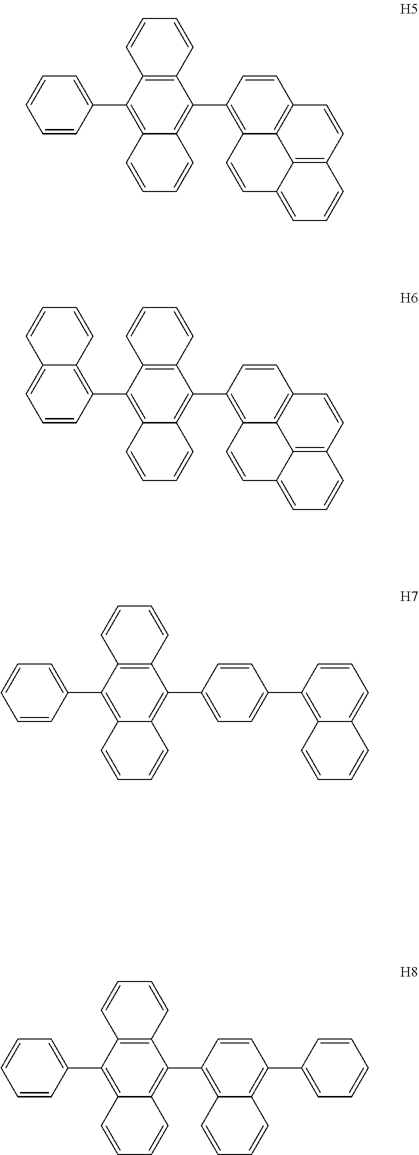

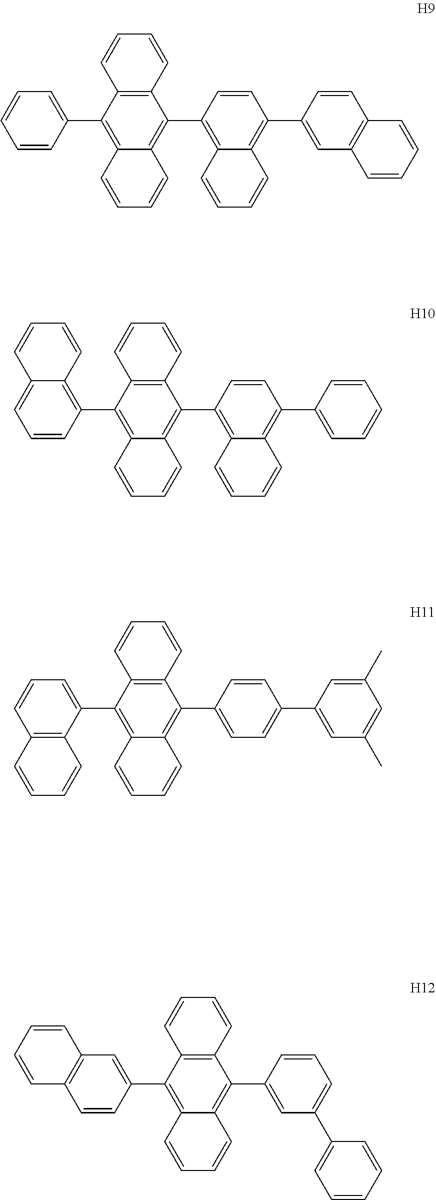

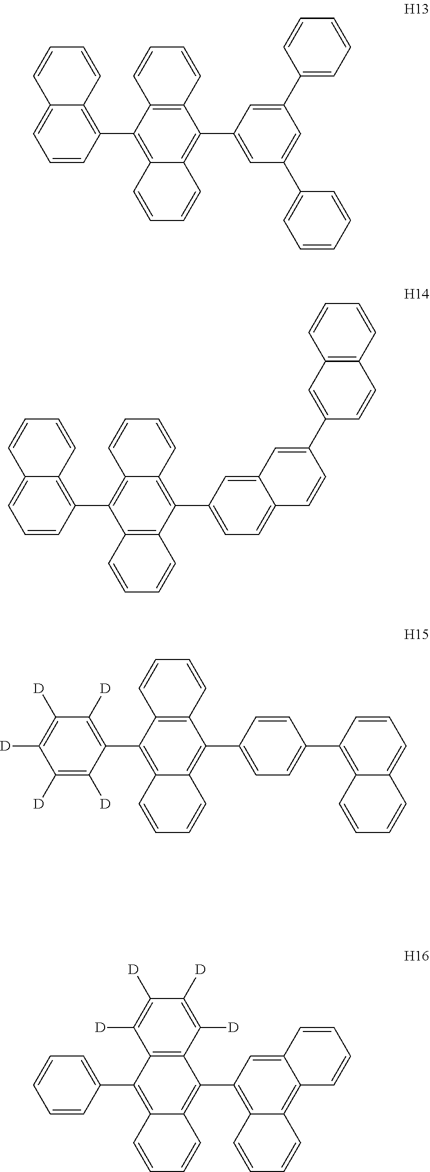

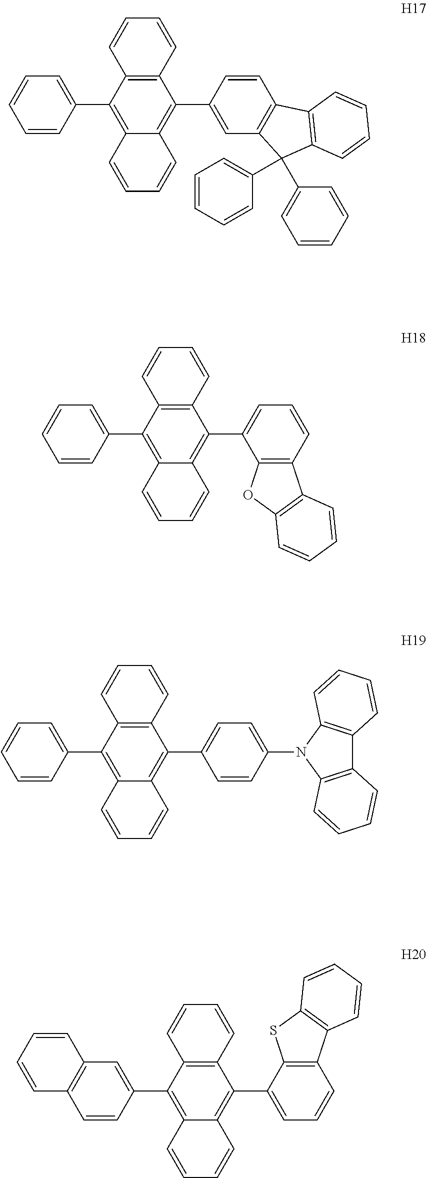

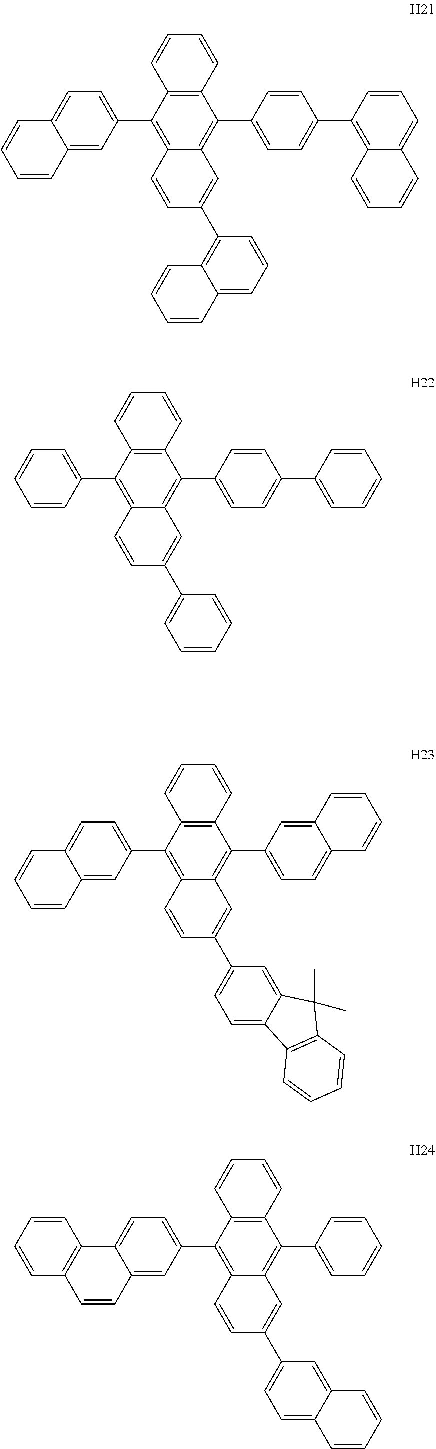

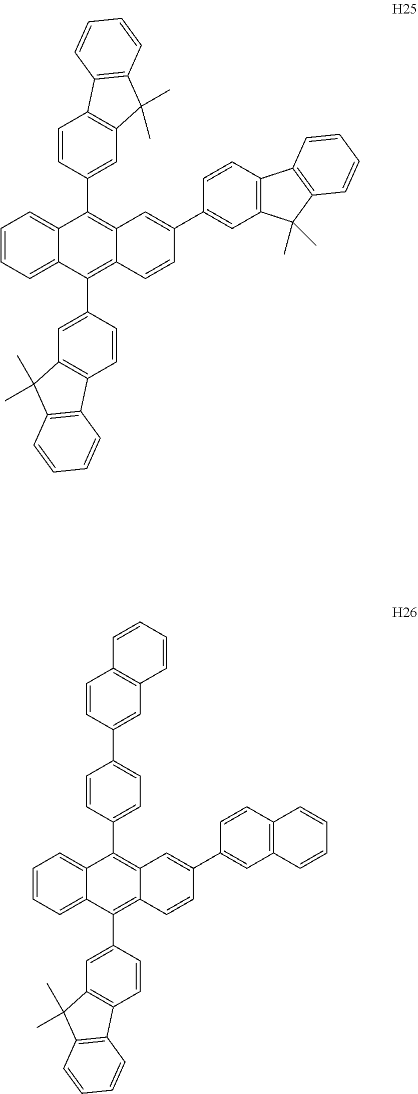

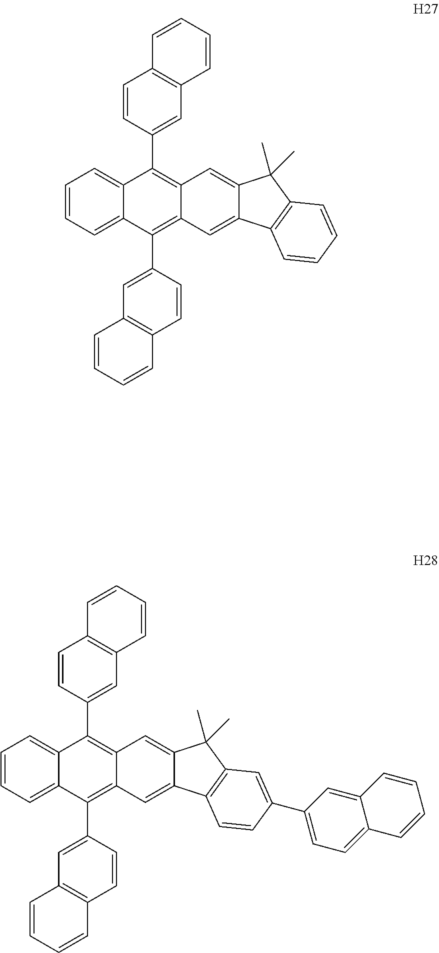

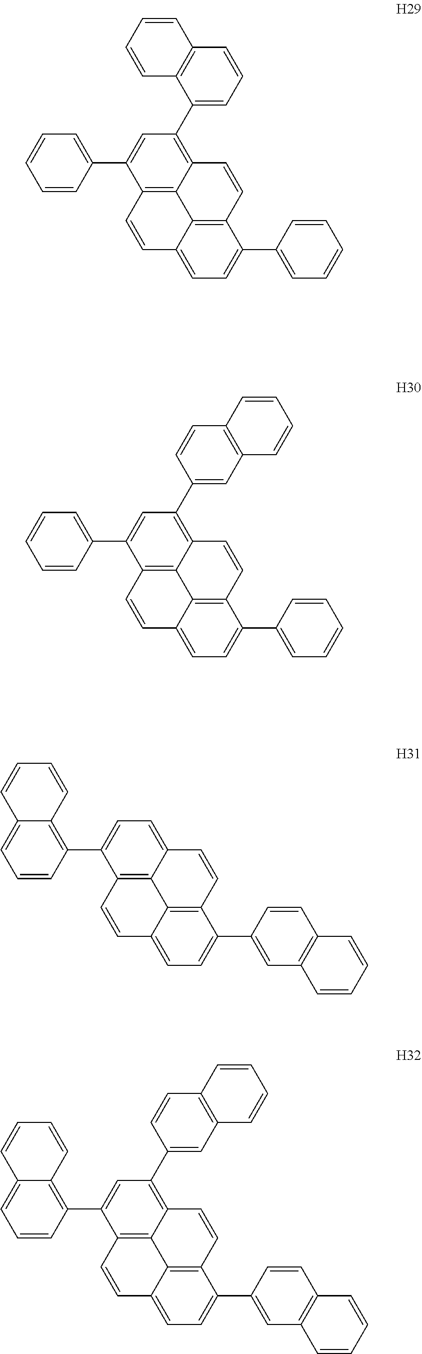

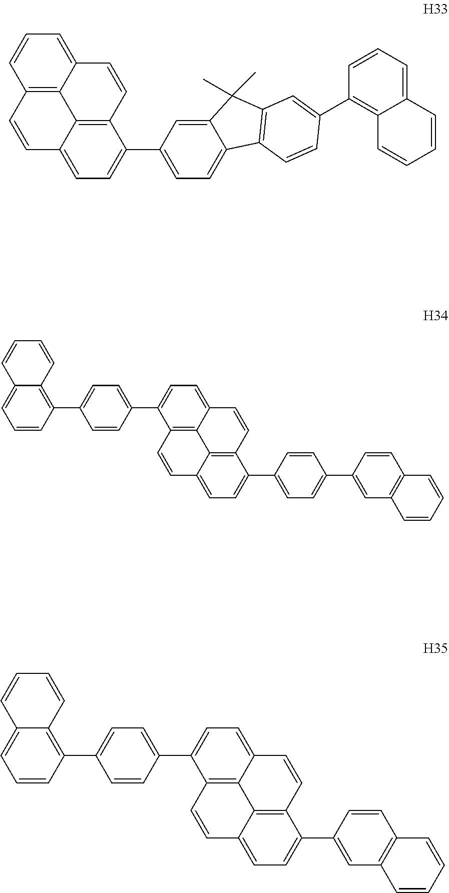

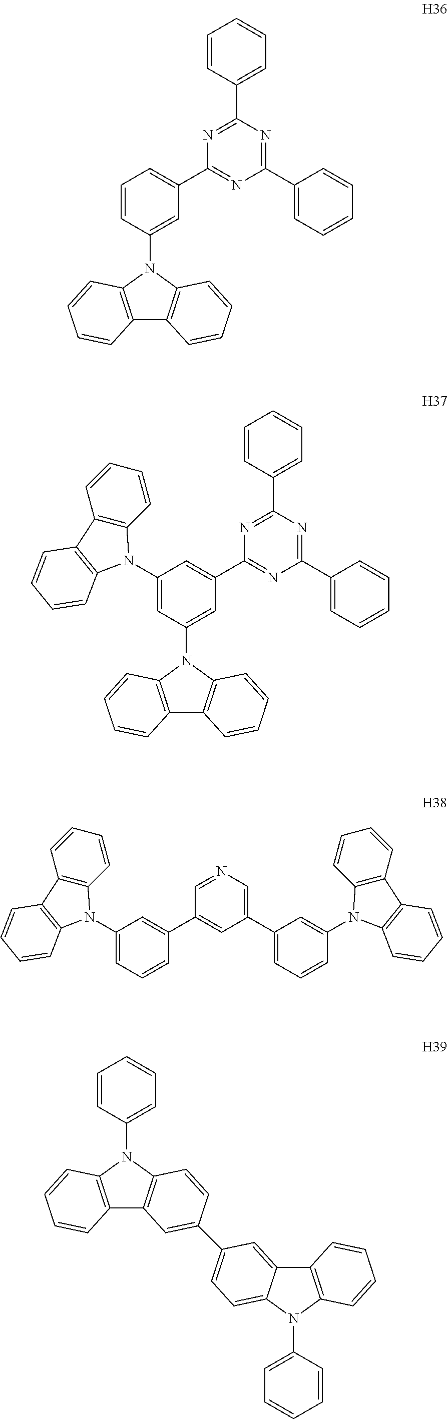 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1]

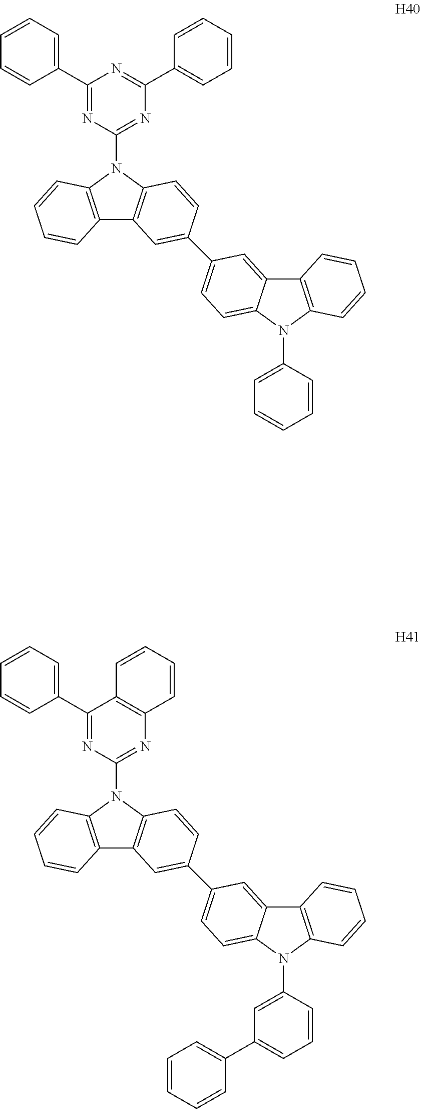 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1]

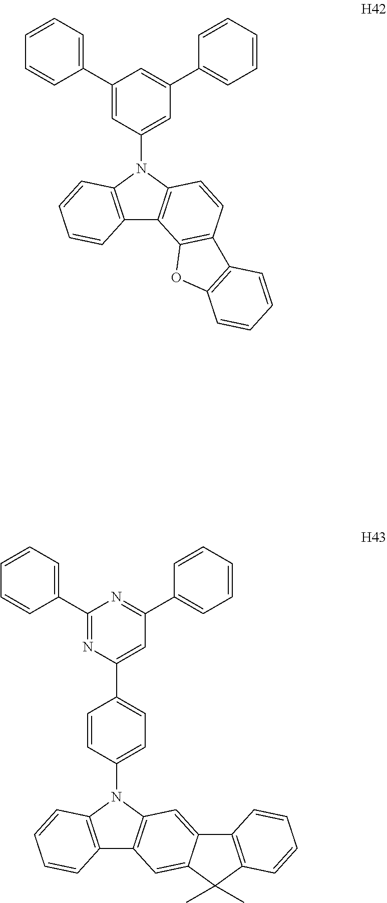 [SMILES: c1ccc(-c2cc(-c3ccccc3)cc(-n3c4ccccc4c4c5oc6ccccc6c5ccc43)c2)cc1 ; CC1(C)c2ccccc2-c2cc3c(cc21)c1ccccc1n3-c1ccc(-c2cc(-c3ccccc3)nc(-c3ccccc3)n2)cc1]

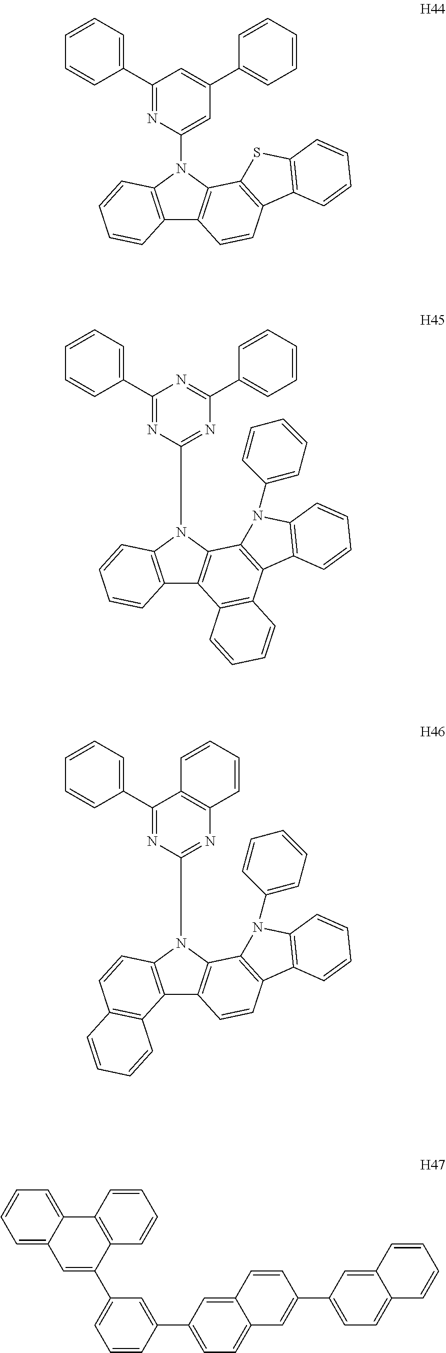

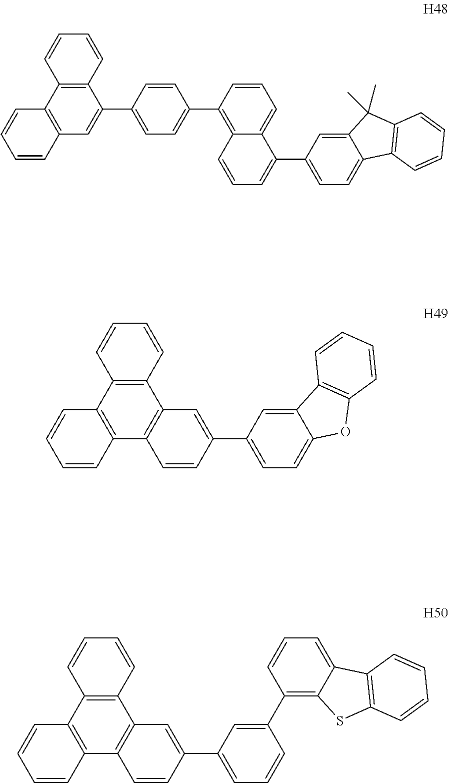

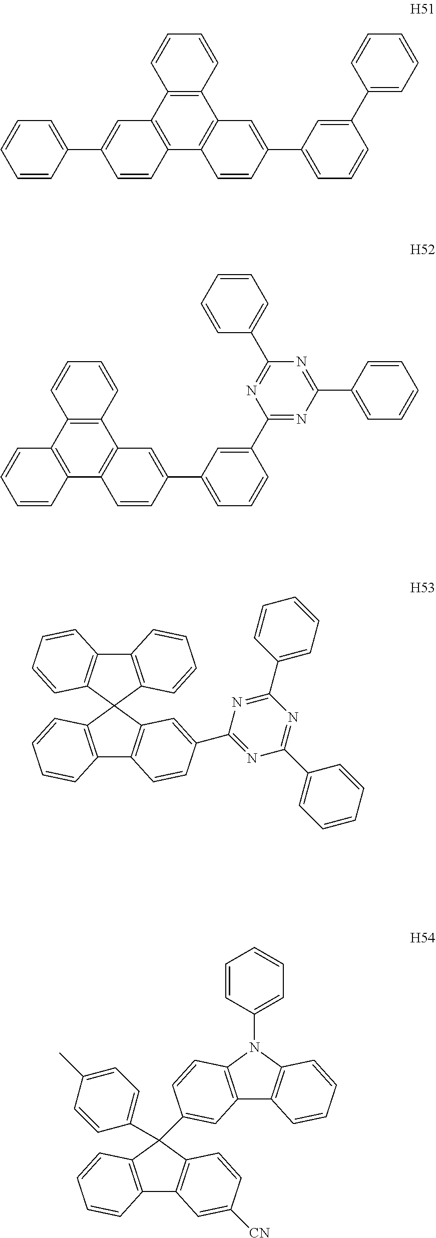

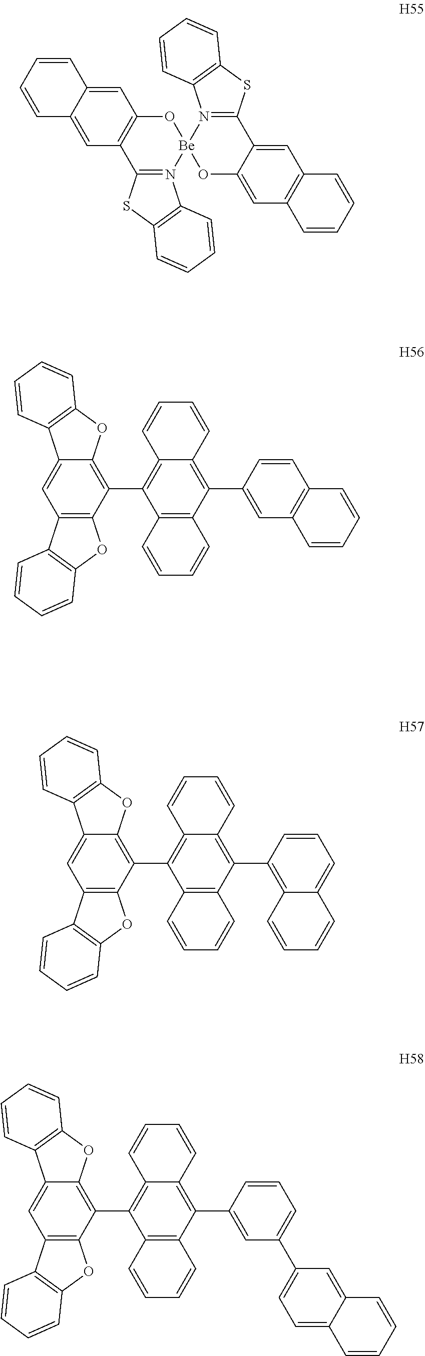

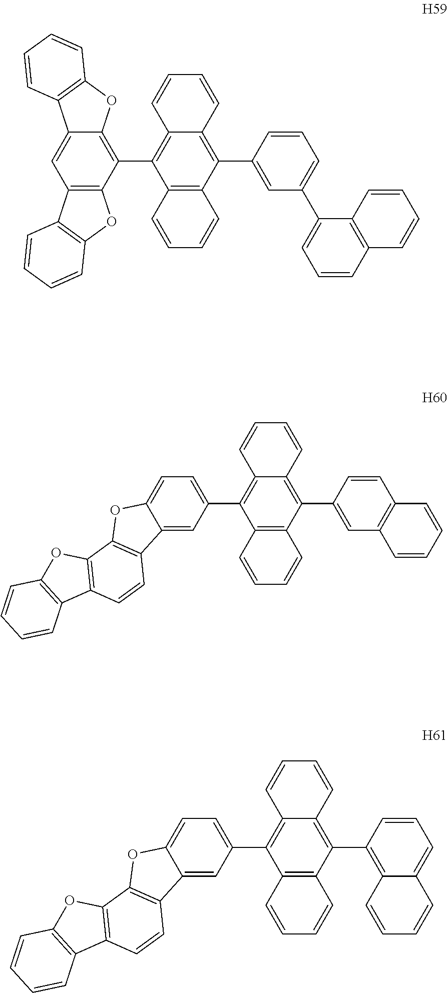 [SMILES: c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1]

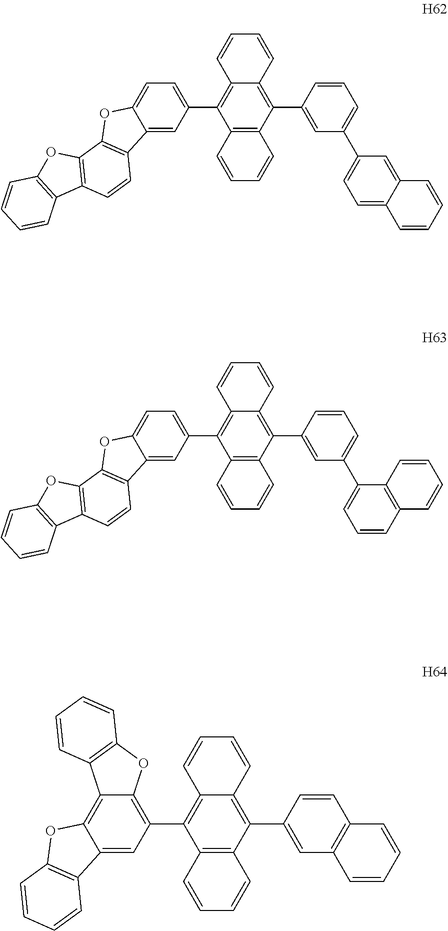 [SMILES: c1cc(-c2ccc3ccccc3c2)cc(-c2c3ccccc3c(-c3ccc4oc5c(ccc6c7ccccc7oc65)c4c3)c3ccccc23)c1 ; c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1]

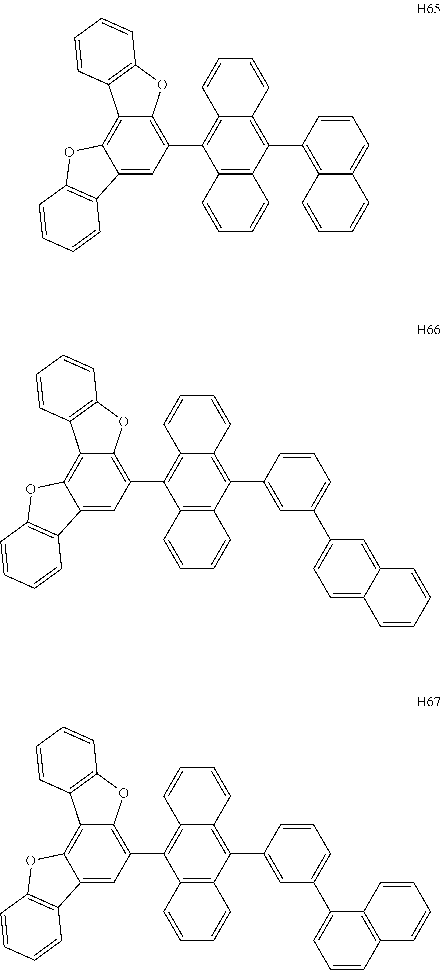 [SMILES: c1ccc2c(-c3c4ccccc4c(-c4cc5c6ccccc6oc5c5c4oc4ccccc45)c4ccccc34)cccc2c1 ; c1cc(-c2ccc3ccccc3c2)cc(-c2c3ccccc3c(-c3cc4c5ccccc5oc4c4c3oc3ccccc34)c3ccccc23)c1 ; c1cc(-c2cccc3ccccc23)cc(-c2c3ccccc3c(-c3cc4c5ccccc5oc4c4c3oc3ccccc34)c3ccccc23)c1]

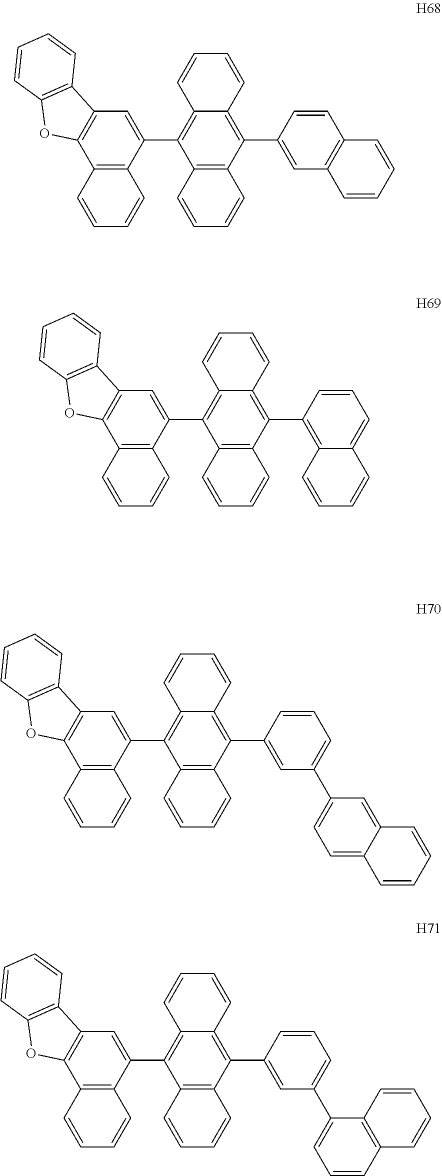 [SMILES: c1ccc2cc(-c3c4ccccc4c(-c4cc5c6ccccc6oc5c5ccccc45)c4ccccc34)ccc2c1 ; c1ccc2c(-c3c4ccccc4c(-c4cc5c6ccccc6oc5c5ccccc45)c4ccccc34)cccc2c1 ; c1cc(-c2ccc3ccccc3c2)cc(-c2c3ccccc3c(-c3cc4c5ccccc5oc4c4ccccc34)c3ccccc23)c1 ; c1cc(-c2cccc3ccccc23)cc(-c2c3ccccc3c(-c3cc4c5ccccc5oc4c4ccccc34)c3ccccc23)c1]

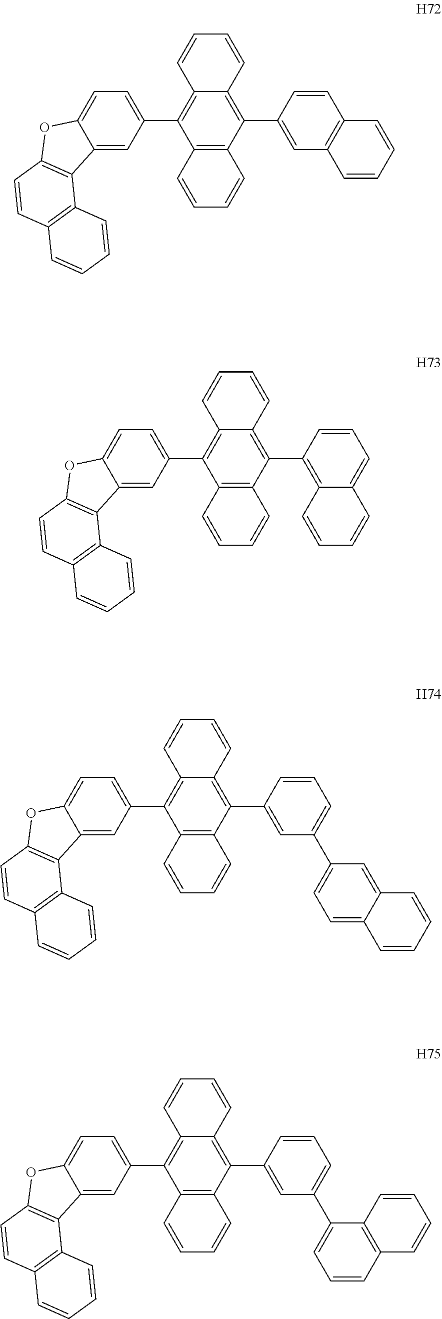 [SMILES: c1ccc2cc(-c3c4ccccc4c(-c4ccc5oc6ccc7ccccc7c6c5c4)c4ccccc34)ccc2c1 ; c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1]

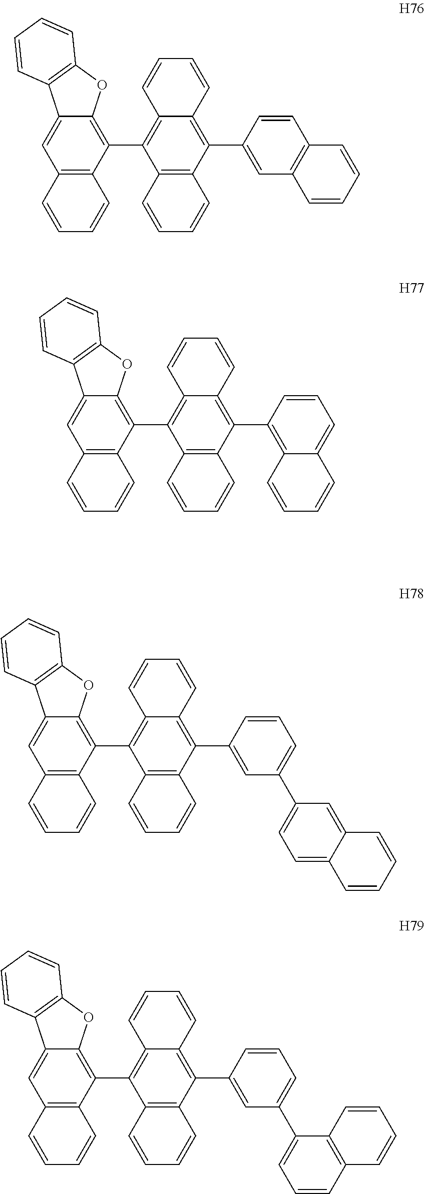 [SMILES: c1ccc2cc(-c3c4ccccc4c(-c4c5ccccc5cc5c4oc4ccccc45)c4ccccc34)ccc2c1 ; c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1]

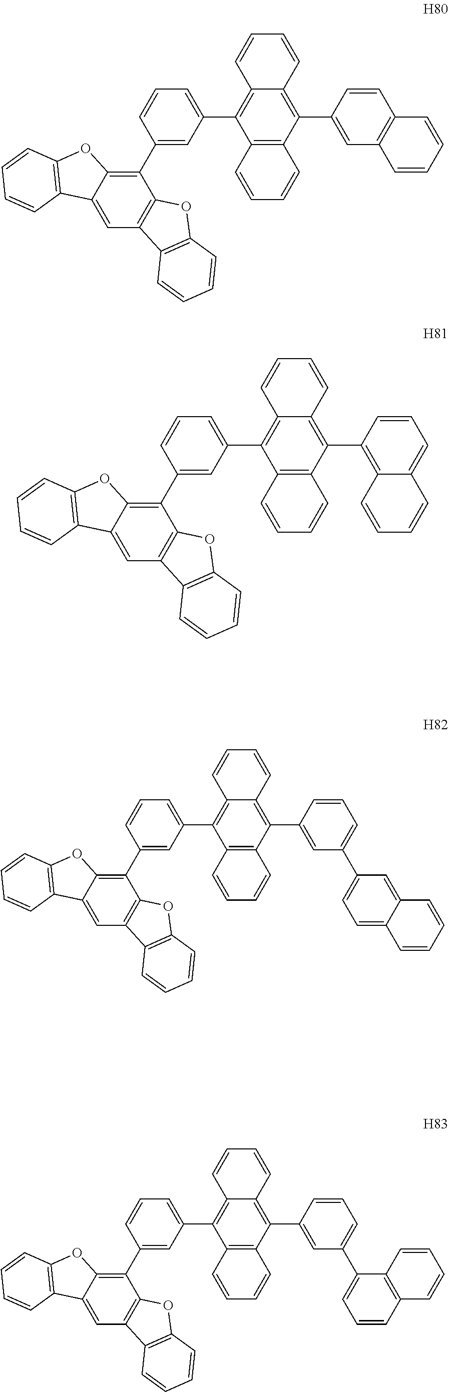 [SMILES: c1cc(-c2c3ccccc3c(-c3ccc4ccccc4c3)c3ccccc23)cc(-c2c3oc4ccccc4c3cc3c2oc2ccccc23)c1 ; c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1]

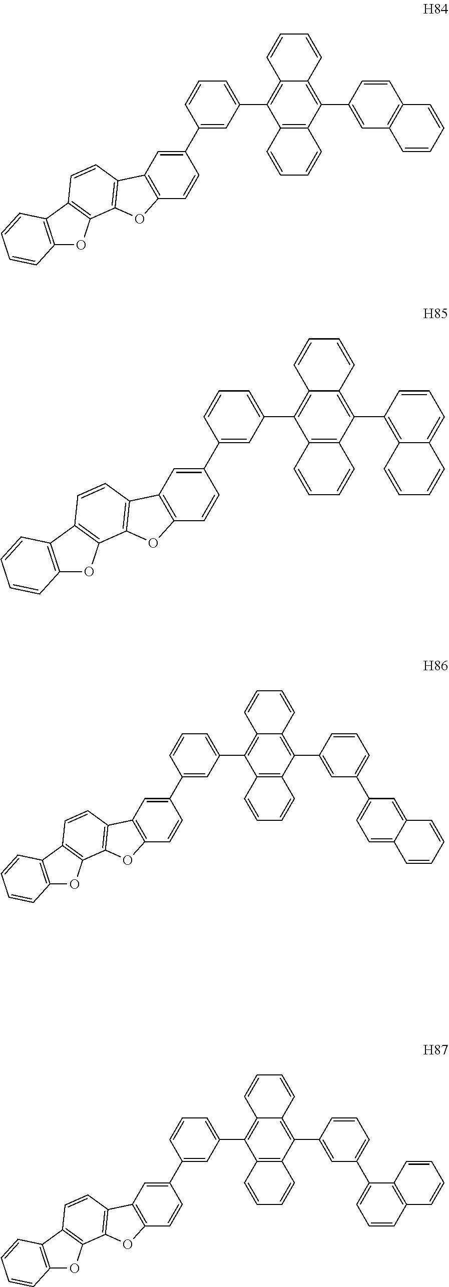 [SMILES: c1cc(-c2ccc3oc4c(ccc5c6ccccc6oc54)c3c2)cc(-c2c3ccccc3c(-c3ccc4ccccc4c3)c3ccccc23)c1 ; c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1]

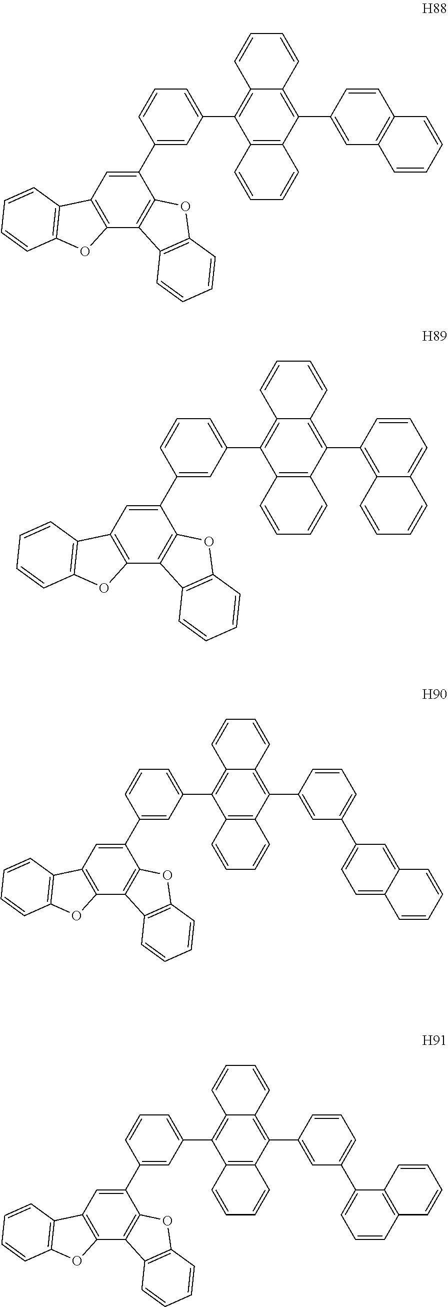 [SMILES: c1cc(-c2c3ccccc3c(-c3ccc4ccccc4c3)c3ccccc23)cc(-c2cc3c4ccccc4oc3c3c2oc2ccccc23)c1 ; c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1]

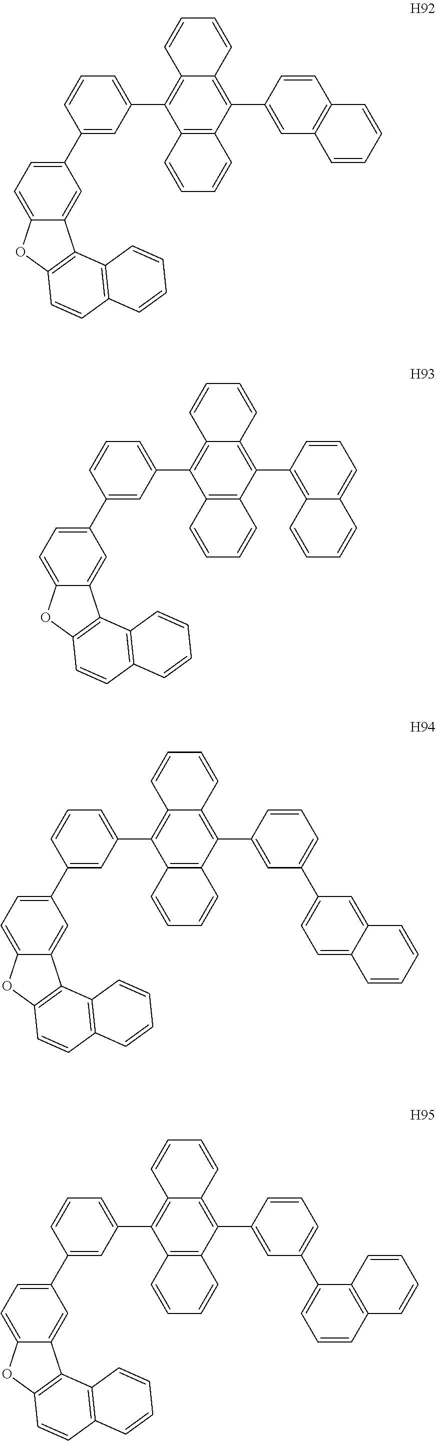 [SMILES: c1cc(-c2ccc3oc4ccc5ccccc5c4c3c2)cc(-c2c3ccccc3c(-c3ccc4ccccc4c3)c3ccccc23)c1 ; c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1]

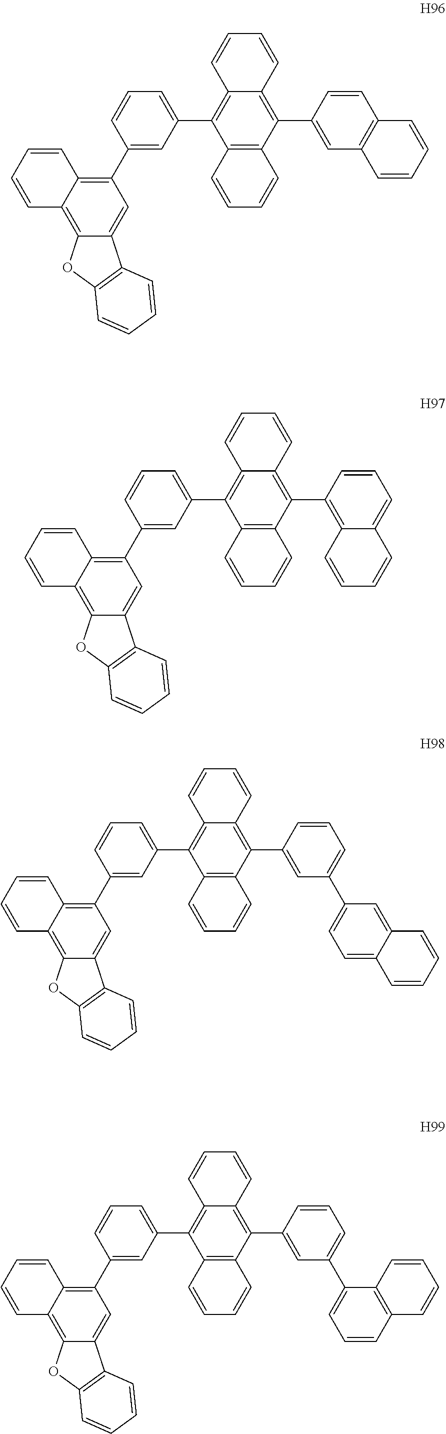 [SMILES: c1cc(-c2c3ccccc3c(-c3ccc4ccccc4c3)c3ccccc23)cc(-c2cc3c4ccccc4oc3c3ccccc23)c1 ; c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1]

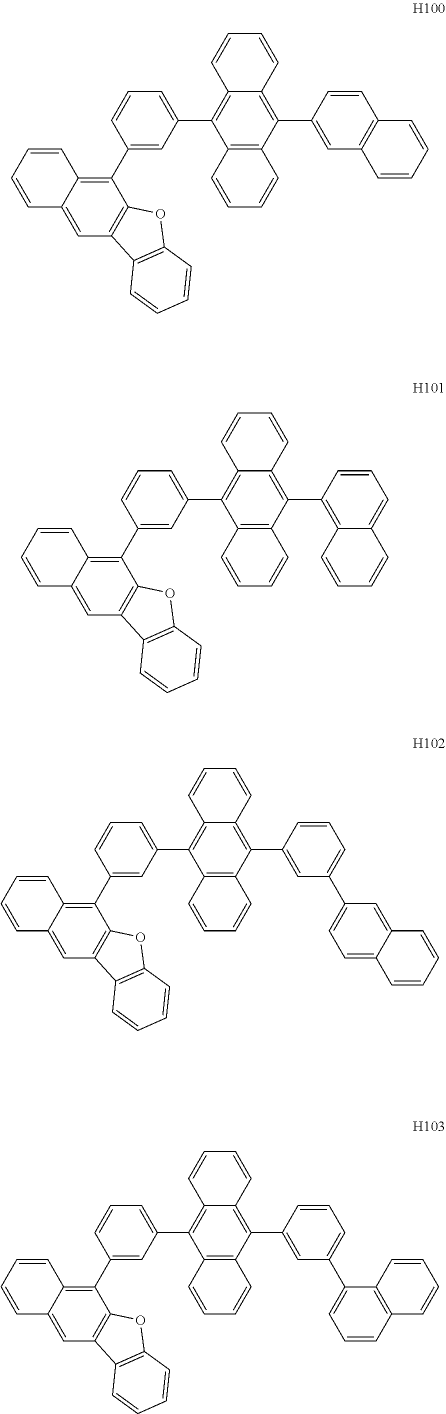 [SMILES: c1cc(-c2c3ccccc3c(-c3ccc4ccccc4c3)c3ccccc23)cc(-c2c3ccccc3cc3c2oc2ccccc23)c1 ; c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1]

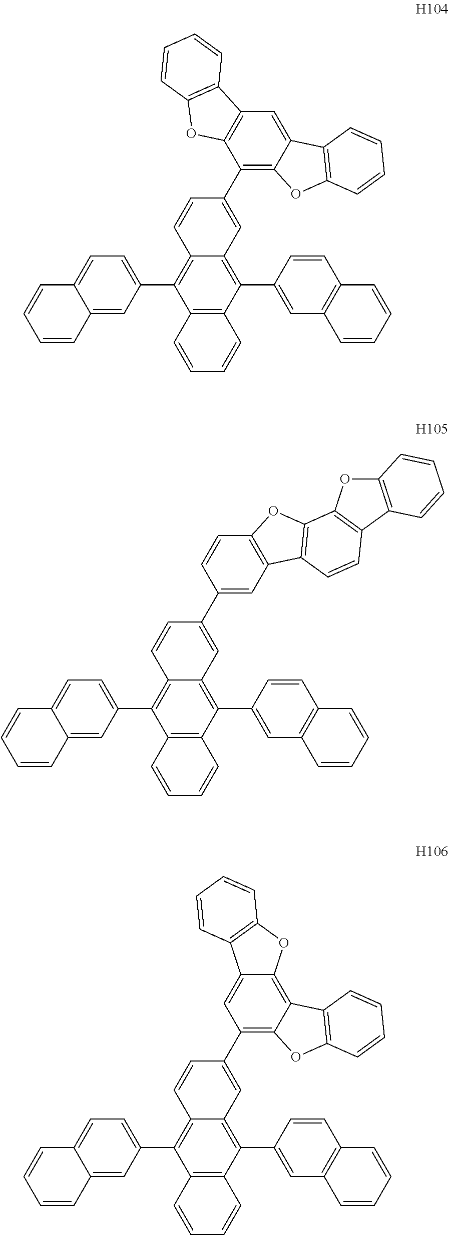 [SMILES: c1ccc2cc(-c3c4ccccc4c(-c4ccc5ccccc5c4)c4cc(-c5c6oc7ccccc7c6cc6c5oc5ccccc56)ccc34)ccc2c1 ; c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1]

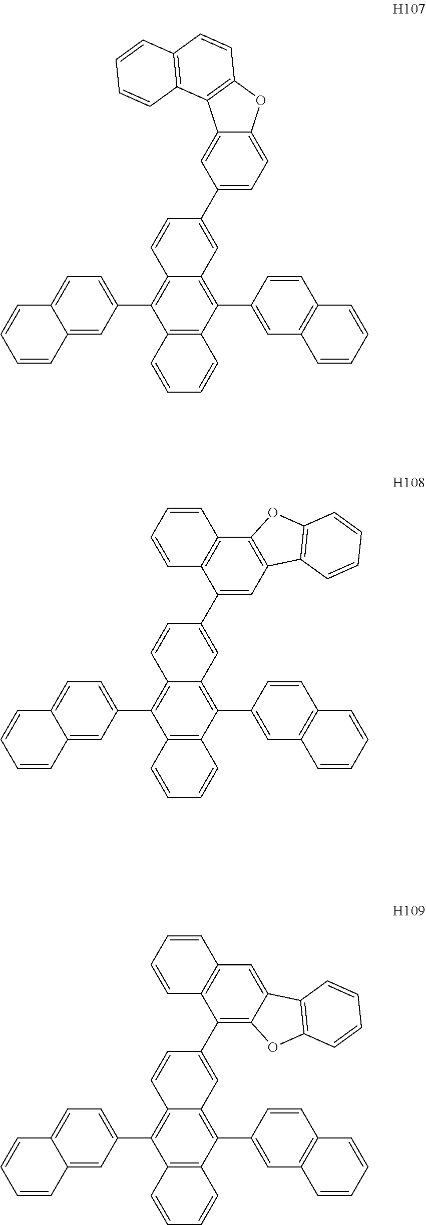 [SMILES: c1ccc2cc(-c3c4ccccc4c(-c4ccc5ccccc5c4)c4cc(-c5ccc6oc7ccc8ccccc8c7c6c5)ccc34)ccc2c1 ; c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1]

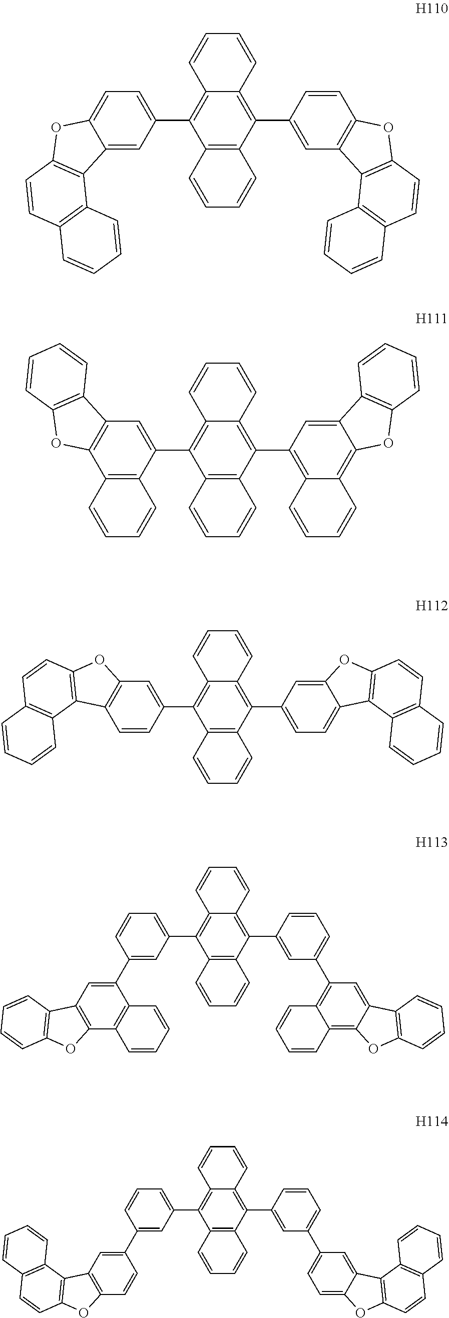 [SMILES: c1ccc2c(c1)ccc1oc3ccc(-c4c5ccccc5c(-c5ccc6oc7ccc8ccccc8c7c6c5)c5ccccc45)cc3c12 ; c1ccc2c(c1)oc1c3ccccc3c(-c3c4ccccc4c(-c4cc5c6ccccc6oc5c5ccccc45)c4ccccc34)cc21 ; c1ccc2c(c1)ccc1oc3cc(-c4c5ccccc5c(-c5ccc6c(c5)oc5ccc7ccccc7c56)c5ccccc45)ccc3c12 ; c1cc(-c2c3ccccc3c(-c3cccc(-c4cc5c6ccccc6oc5c5ccccc45)c3)c3ccccc23)cc(-c2cc3c4ccccc4oc3c3ccccc23)c1 ; c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1]

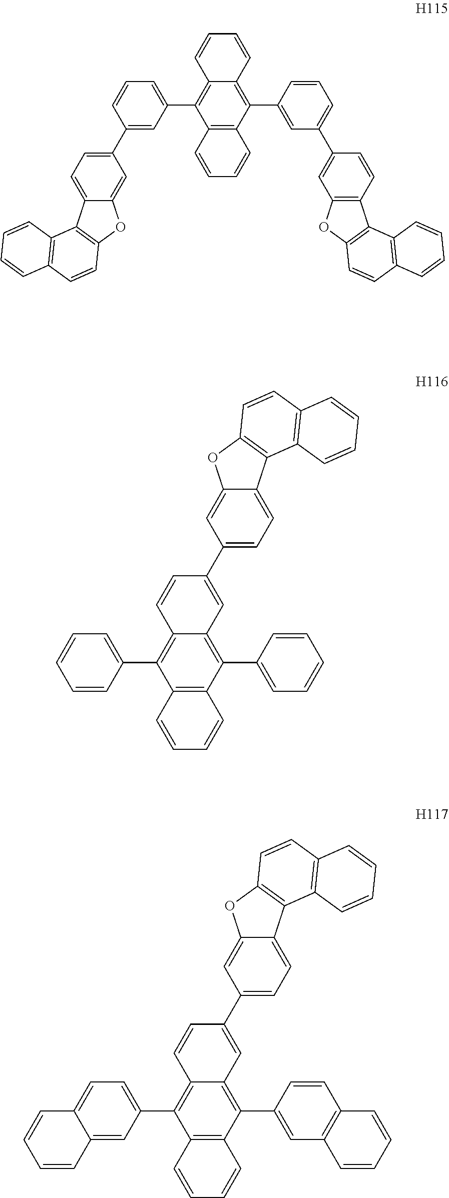 [SMILES: c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1]

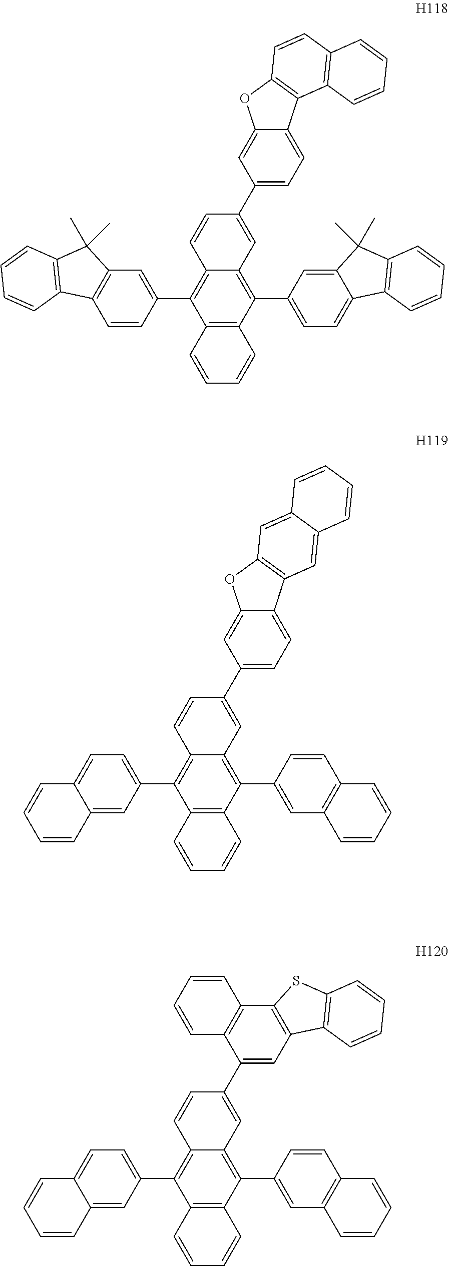 [SMILES: CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21 ; c1ccc2cc(-c3c4ccccc4c(-c4ccc5ccccc5c4)c4cc(-c5ccc6c(c5)oc5cc7ccccc7cc56)ccc34)ccc2c1 ; c1ccc2cc(-c3c4ccccc4c(-c4ccc5ccccc5c4)c4cc(-c5cc6c7ccccc7sc6c6ccccc56)ccc34)ccc2c1]

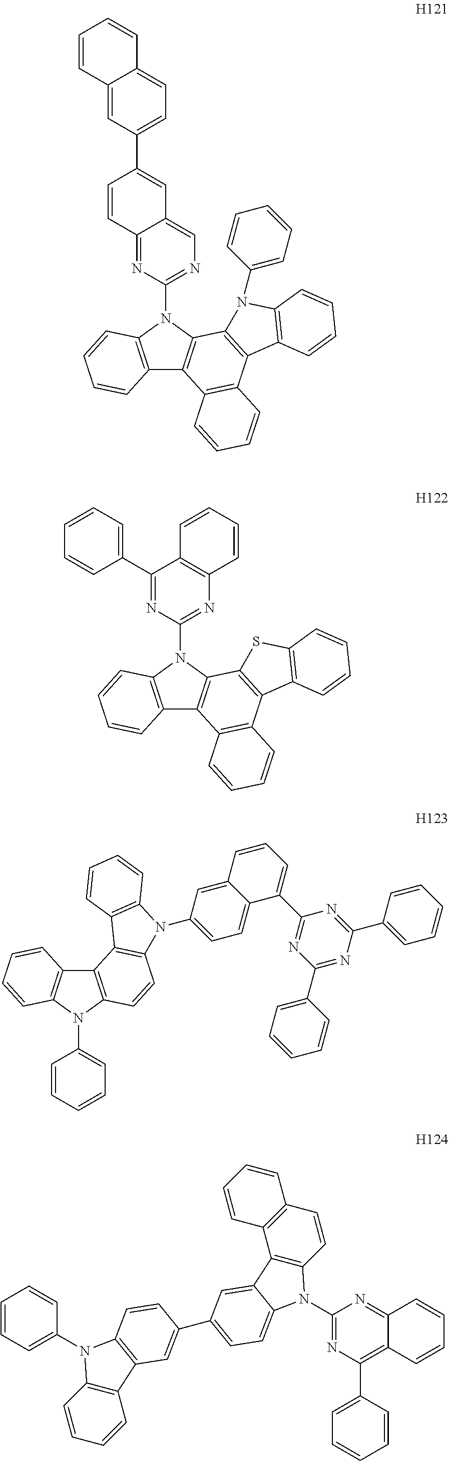 [SMILES: c1ccc(-n2c3ccccc3c3c4ccccc4c4c5ccccc5n(-c5ncc6cc(-c7ccc8ccccc8c7)ccc6n5)c4c32)cc1 ; c1ccc(-c2nc(-n3c4ccccc4c4c5ccccc5c5c6ccccc6sc5c43)nc3ccccc23)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

### [Delayed Fluorescence Material]

The emission layer may include a delayed fluorescence material.

The delayed fluorescence material utilized herein may be selected from any compound that is capable of emitting delayed fluorescent light based on a delayed fluorescence emission mechanism.

The delayed fluorescence material included in the emission layer may act as a host or a dopant, depending on the kind (e.g., type) of other materials included in the emission layer.

In an embodiment, a difference between a triplet energy level (eV) of the delayed fluorescence material and a singlet energy level (eV) of the delayed fluorescence material may be equal to or greater than 0 eV and equal to or less than 0.5 eV. When the difference between the triplet energy level (eV) of the delayed fluorescence material and the singlet energy level (eV) of the delayed fluorescence material is within the range above, up-conversion from the triplet state to the singlet state of the delayed fluorescence materials may effectively occur, and thus, the luminescence efficiency of the light-emitting device 10 may be improved.

In an embodiment, the delayed fluorescence material may include i) a material that includes at least one electron donor (for example, a π electron-rich C₃-C₆₀ cyclic group, such as a carbazole group) and at least one electron acceptor (for example, a sulfoxide group, a cyano group, and/or a π electron-deficient nitrogen-containing C₁-C₆₀ cyclic group), and/or ii) a material including a C₈-C₆₀ polycyclic group in which two or more cyclic groups share boron (B) and are condensed with each other.

The delayed fluorescence material may include at least one of Compounds DF1 to DF9:

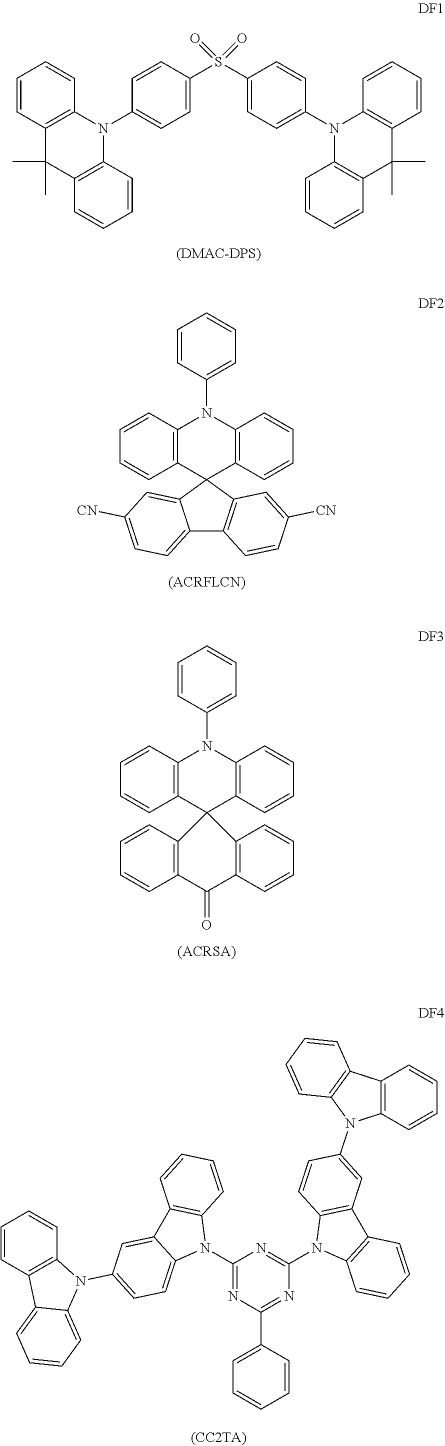

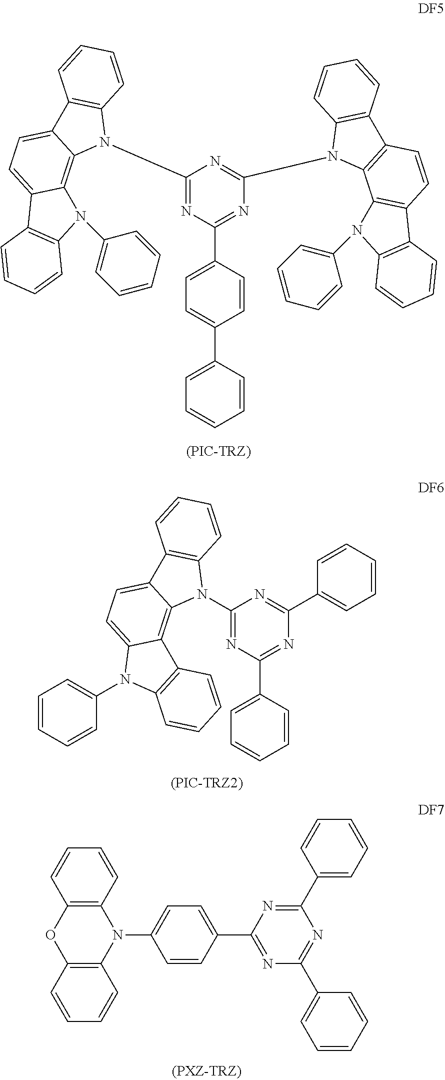

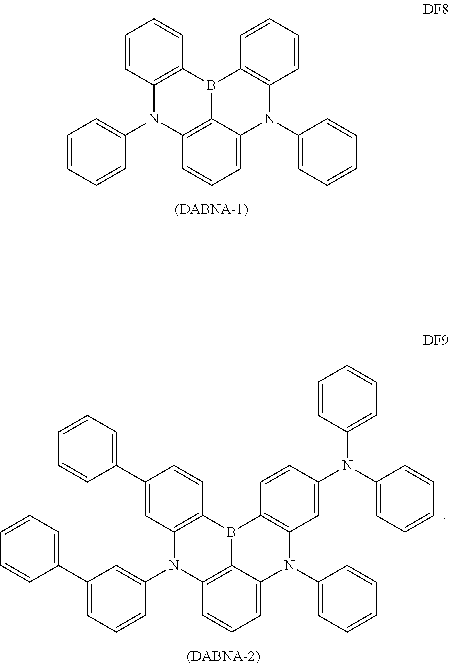

### [Quantum Dot]

The emission layer may include a quantum dot.

The term “quantum dot” as used herein refers to a crystal of a semiconductor compound, and may include any material that is capable of emitting light of various suitable emission wavelengths depending on the size of the crystal.

A diameter of the quantum dot may be, for example, in a range of about 1 nm to about 10 nm.

The quantum dot may be synthesized by a wet chemical process, an organometallic chemical vapor deposition process, a molecular beam epitaxy process, or a process that is similar to these processes.

The wet chemical process refers to a method in which a solvent and a precursor material are mixed, and then, a quantum dot particle crystal is grown. When the crystal grows, the organic solvent acts as a dispersant naturally coordinated on the surface of the quantum dot crystal and controls the growth of the crystal. Accordingly, by utilizing a process that is easily performed at low costs compared to a vapor deposition process, such as a metal organic chemical vapor deposition (MOCVD) process and/or a molecular beam epitaxy (MBE) process, the growth of quantum dot particles may be controlled.

The quantum dot may include: Groups II-VI semiconductor compounds; Groups III-V semiconductor compounds; Groups III-VI semiconductor compounds; Group I-III-VI semiconductor compounds; Groups IV-VI semiconductor compounds; a Group IV element or compound; or any combination thereof.

Non-limiting examples of the Groups II-VI semiconductor compounds are: a binary compound, such as CdSe, CdTe, ZnS, ZnSe, ZnTe, ZnO, HgS, HgSe, HgTe, MgSe, and/or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS; a quaternary compound, such as CdZnSeS, CdZnSeTe, CdZnSTe, CdHgSeS, CdHgSeTe, CdHgSTe, HgZnSeS, HgZnSeTe, and/or HgZnSTe; or any combination thereof.

Non-limiting examples of the Groups III-V semiconductor compounds are: a binary compound, such as GaN, GaP, GaAs, GaSb, AlN, AlP, AlAs, AlSb, InN, InP, InAs, and/or InSb; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and/or InPSb; a quaternary compound, such as GaAlNAs, GaAlNSb, GaAlPAs, GaAlPSb, GaInNP, GaInNAs, GalnNSb, GaInPAs, GalnPSb, InAlNP, InAlNAs, InAlNSb, InAlPAs, InAlPSb, and/or GaAlNP; or any combination thereof. The Groups III-V semiconductor compounds may further include a Group II element. Non-limiting examples of the Groups III-V semiconductor compounds further including the Group II element are InZnP, InGaZnP, and InAlZnP.

Non-limiting examples of the Groups III-VI semiconductor compounds are: a binary compound, such as GaS, GaSe, Ga₂Se₃, GaTe, InS, In₂S₃, InSe, In₂Se₃, and/or InTe; a ternary compound, such as InGaS₃ and/or InGaSes; or any combination thereof.

Non-limiting examples of the Group I-III-VI semiconductor compound are a ternary compound, such as AgInS, AgInS₂, CuInS, CuInS₂, CuGaO₂, AgGaO₂, and/or AgAlO₂; or any combination thereof.

Non-limiting examples of the Group IV-VI semiconductor compounds are: a binary compound, such as SnS, SnSe, SnTe, PbS, PbSe, and/or PbTe; a ternary compound, such as SnSeS, SnSeTe, SnSTe, PbSeS, PbSeTe, PbSTe, SnPbS, SnPbSe, and/or SnPbTe; a quaternary compound, such as SnPbSSe, SnPbSeTe, and/or SnPbSTe; or any combination thereof.

In an embodiment, the Group IV element or compound may include: a single element compound, such as Si and/or Ge; a binary compound, such as SiC and/or SiGe; or any combination thereof.

Each element included in a multi-element compound such as the binary compound, ternary compound, and quaternary compound may be present in the particle at a uniform concentration or a non-uniform concentration.

In one embodiment, the quantum dot may have a single structure having a uniform concentration of each element included in the corresponding quantum dot or a dual structure of a core-shell. For example, the material included in the core may be different from the material included in the shell.

The shell of the quantum dot may function as a protective layer for maintaining semiconductor characteristics by reducing or preventing chemical degeneration of the core and/or may function as a charging layer for imparting electrophoretic characteristics to the quantum dots. The shell may be a single layer or a multilayer. An interface between the core and the shell may have a concentration gradient in which the concentration of elements existing in the shell decreases toward the center.

Non-limiting examples of the shell of the quantum dot are a metal oxide or non-metal oxide, a semiconductor compound, or any combination thereof. Non-limiting examples of the metal oxide or non-metal oxide are: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; a ternary compound, such as MgAl₂O₄, CoFe₂O₄, NiFe₂O₄, and/or CoMn₂O₄; or any combination thereof. Non-limiting examples of the semiconductor compound are, as described herein, Groups III-VI semiconductor compounds; Groups II-VI semiconductor compounds; Groups III-V semiconductor compounds; Groups III-VI semiconductor compounds; Group I-III-VI semiconductor compounds; Groups IV-VI semiconductor compounds; or any combination thereof. For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

A full width of half maximum (FWHM) of an emission wavelength spectrum of the quantum dot may be equal to or less than about 45 nm, for example, equal to or less than about 40 nm, or, equal to or less than about 30 nm. When the FWHM of the emission wavelength spectrum of the quantum dot is within the ranges above, color purity and/or color reproduction may be improved. In addition, light emitted through such a quantum dot is irradiated in omnidirection (e.g., in all directions). Accordingly, a wide viewing angle may be increased.

In addition, the quantum dot may be, for example, a spherical nanoparticle, a pyramidal nanoparticle, a multi-arm nanoparticle, a cubic nanoparticle, a nanotube particle, a nanowire particle, a nanofiber particle, or a nanoplate particle.

By adjusting the size of the quantum dot, the energy band gap may also be adjusted, thereby obtaining light of various suitable wavelengths in the quantum dot emission layer. Therefore, by utilizing quantum dots of different sizes, a light-emitting device that emits light of various suitable wavelengths may be implemented. In an embodiment, the size of the quantum dot may be selected to emit red, green and/or blue light. In addition, the size of the quantum dot may be configured (e.g., selected) to allow combination of light of various suitable colors, so as to emit white light.

### [Electron Transport Region in Interlayer 130]

The electron transport region may have: i) a single-layered structure (e.g., consisting of a single layer) including (e.g., consisting of) a single material, ii) a single-layered structure (e.g., consisting of a single layer) including (e.g., consisting of) a plurality of different materials, or iii) a multi-layered structure including a plurality of layers including different materials.

The electron transport region may include a buffer layer, a hole blocking layer, an electron control layer, an electron transport layer, an electron injection layer, or any combination thereof.

For example, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein, in each structure, constituting layers are sequentially stacked on the emission layer in the respective stated order.

The electron transport region (for example, the buffer layer, the hole blocking layer, the electron control layer, or the electron transport layer in the electron transport region) may include a metal-free compound including at least one π electron-deficient nitrogen-containing C₁-C₆₀ cyclic group.

In an embodiment, the electron transport region may include a compound represented by Formula 601:

[Ar₆₀₁]ₓₑ₁₁-[(L₆₀₁)ₓₑ₁-R₆₀₁]ₓₑ₂₁ Formula 601
wherein, in Formula 601,
Ar₆₀₁ and L₆₀₁ may each independently be a C₅-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described in connection with Q₁,
xe21 may be 1, 2, 3, 4, or 5, and
at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

In one or more embodiments, when xe11 in Formula 601 is 2 or more, two or more of Ar₆₀₁(s) may be linked to each other via a single bond.

In one or more embodiments, Ar₆₀₁ in Formula 601 may be a substituted or unsubstituted anthracene group.

In an embodiment, the electron transport region may include a compound represented by Formula 601-1:

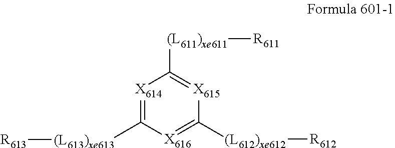

In Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,
L₆₁₁ to L₆₁₃ may each independently be the same as described in connection with L₆₀₁,
xe611 to xe613 may each independently be the same as described in connection with xe1,
R₆₁₁ to R₆₁₃ may each independently be the same as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, xe1 and xe611 to xe613 in Formulae 601 and 601-1 may each independently be 0, 1, or 2.

The electron transport region may include one of Compounds ET1 to ET45, 2,9-dimethyl-4,7-diphenyl-1,10-phenanthroline (BCP), 4,7-diphenyl-1,10-phenanthroline (Bphen), Alq₃, BAlq, TAZ, NTAZ, diphenyl(4-(triphenylsilyl)phenyl)phosphine oxide (TSPO1), 1,3,5-tris(1-phenyl-1H-benzo[d]imidazol-2-yl)benzene (TPBI), or any combination thereof:

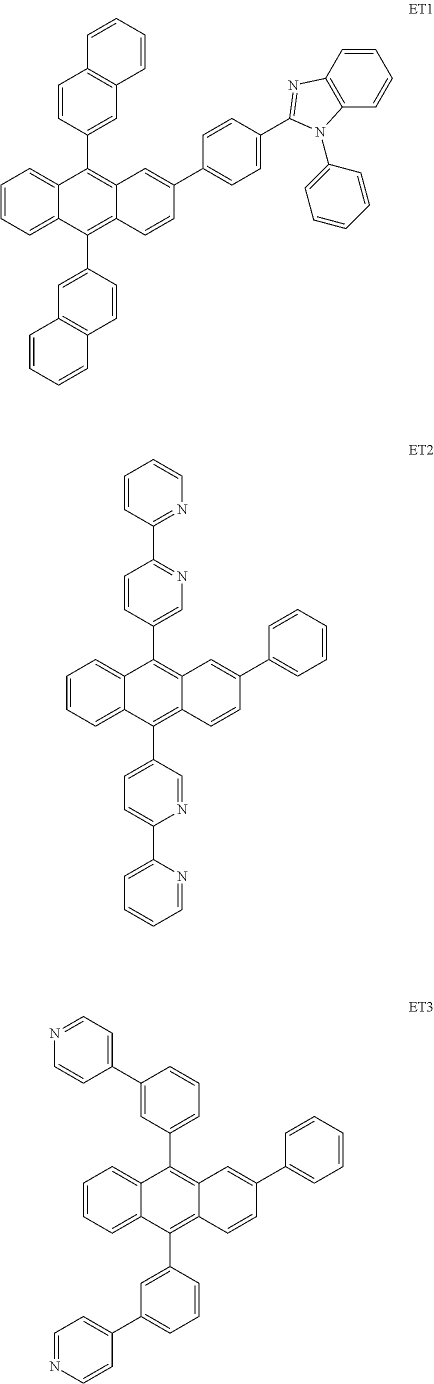 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

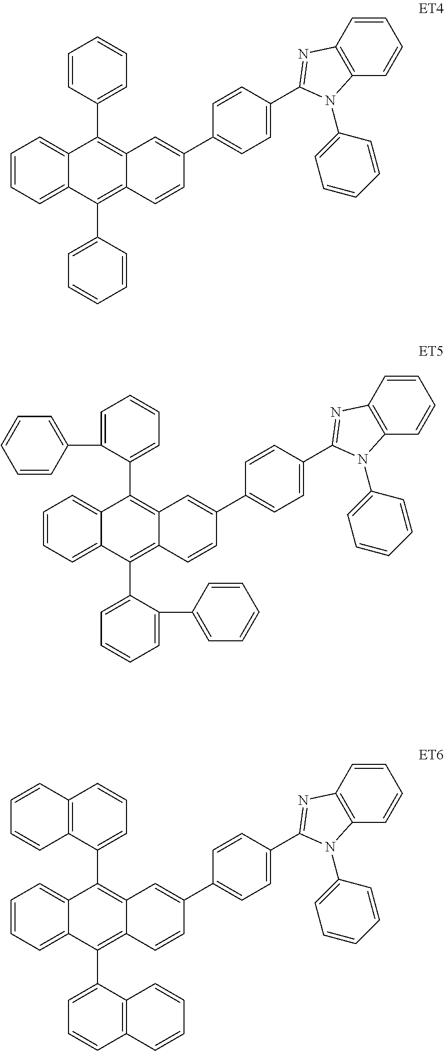 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

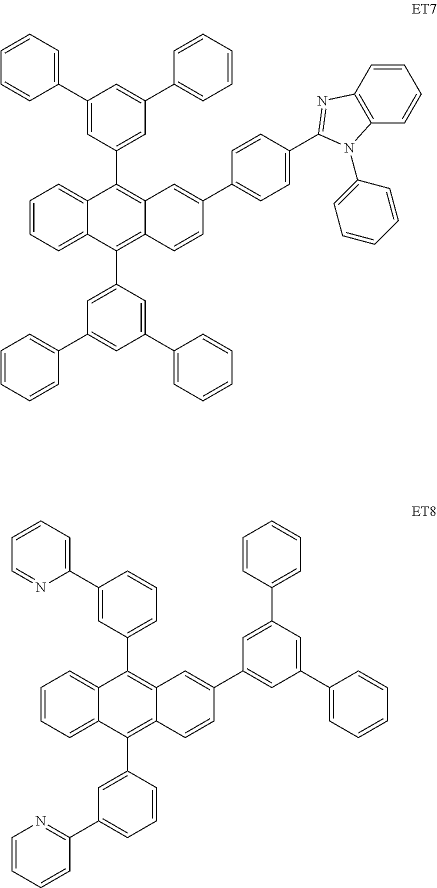 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1]

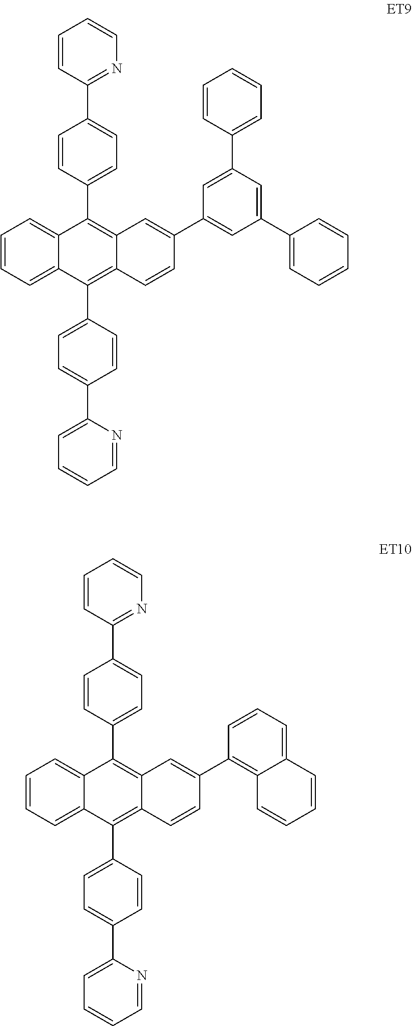 [SMILES: c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

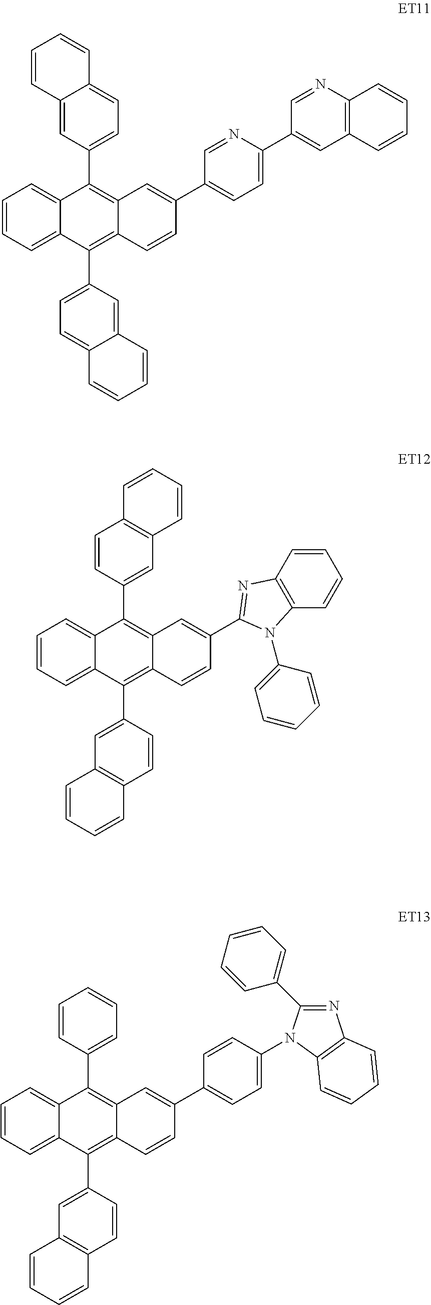 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

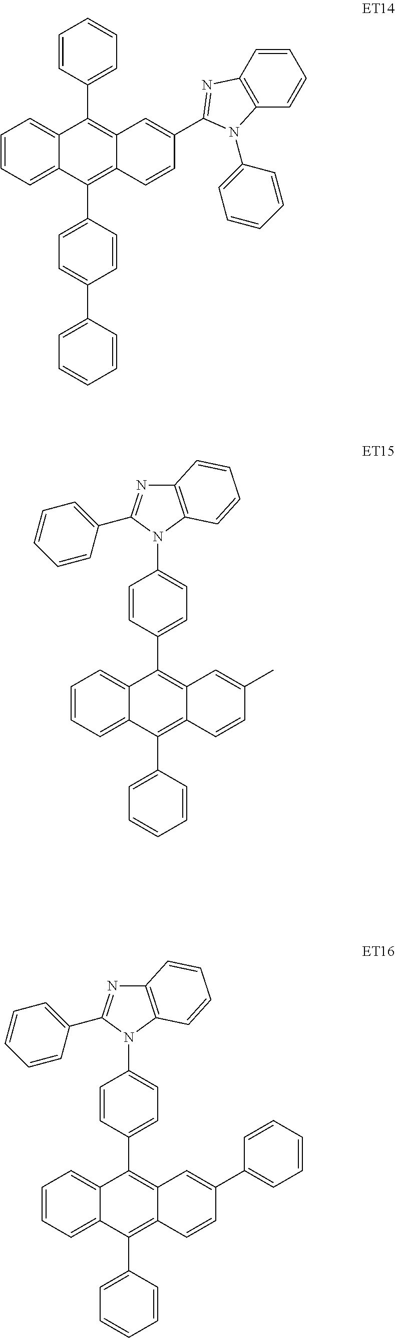 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

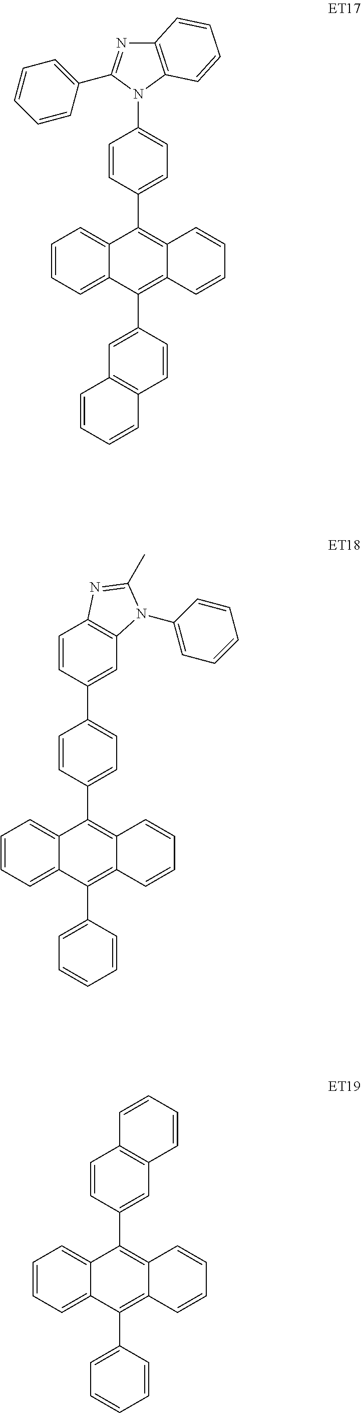

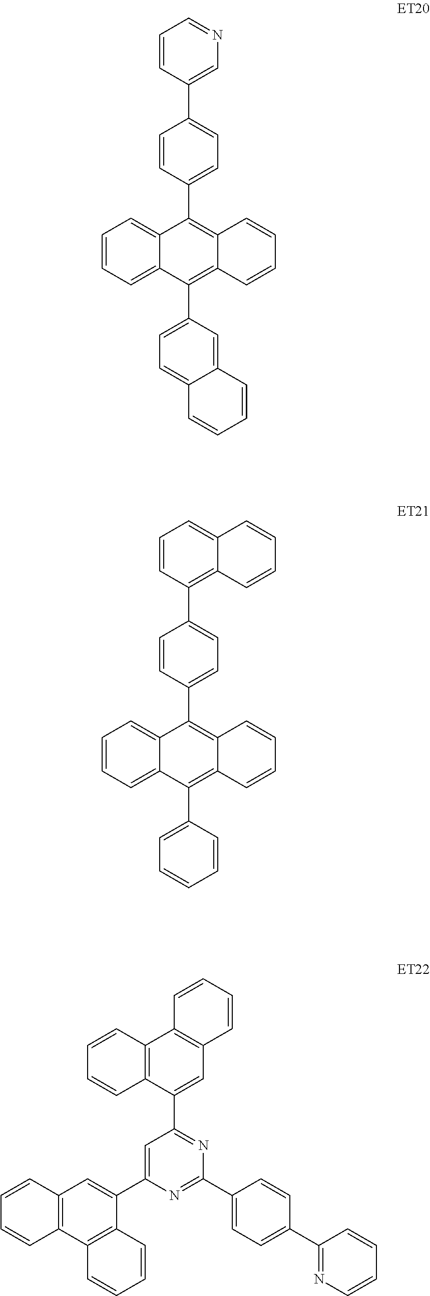

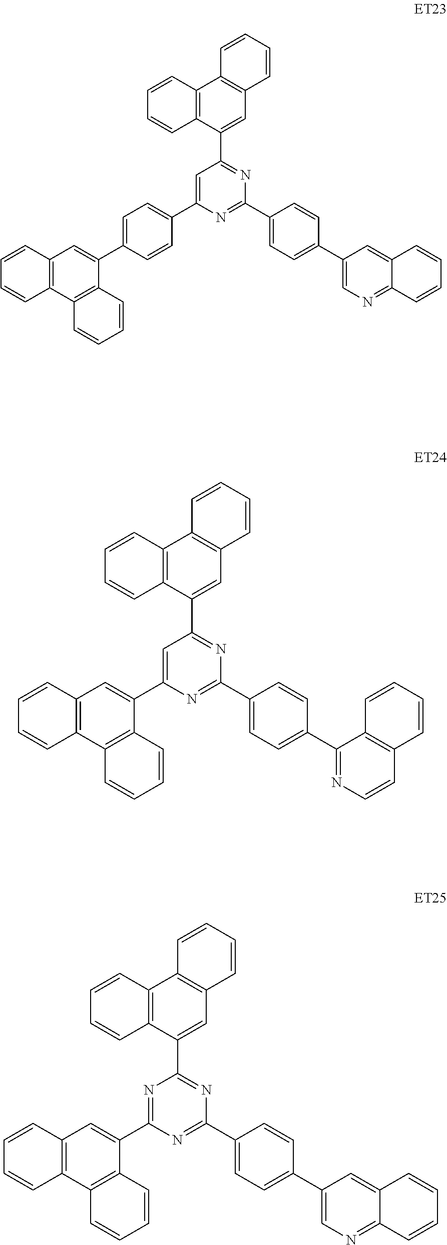 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

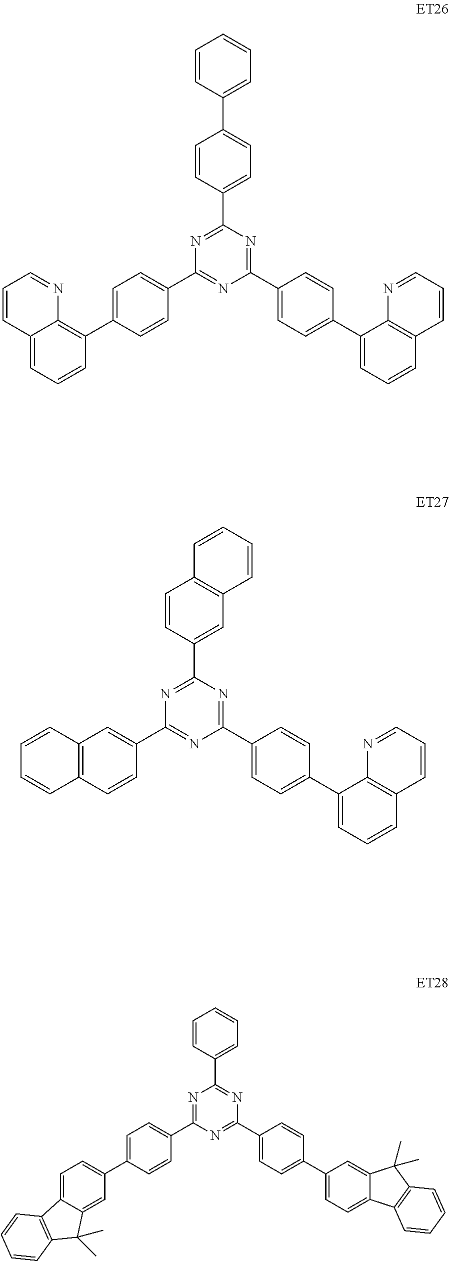 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

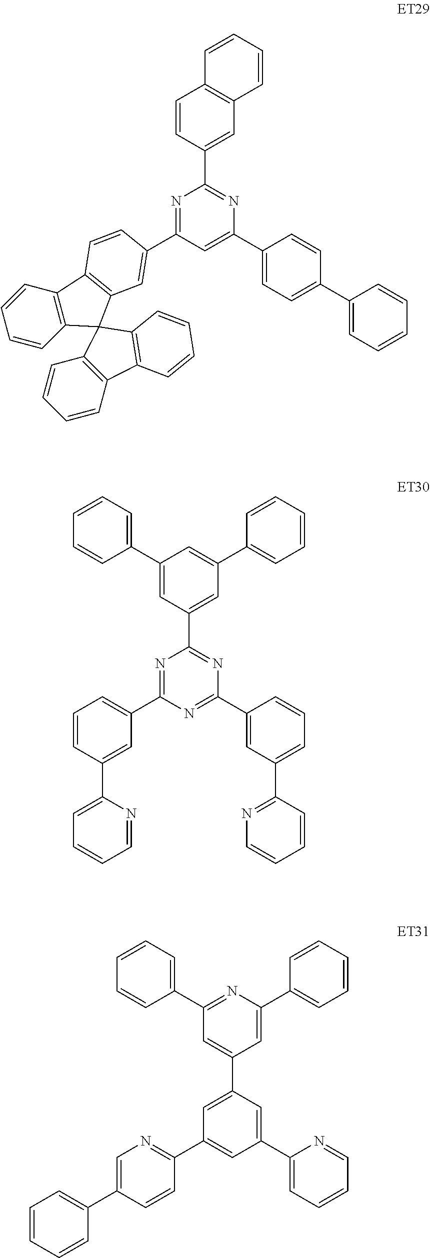 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

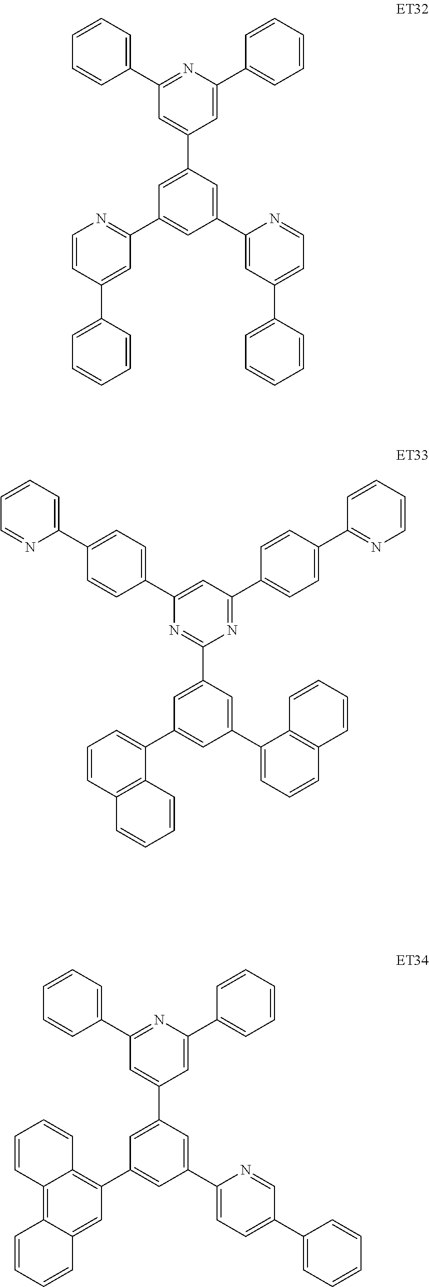 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

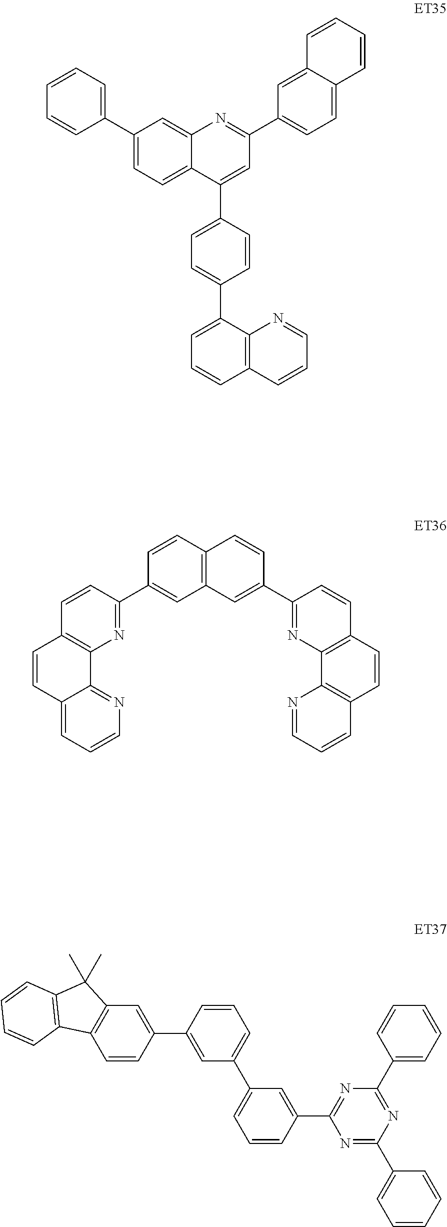 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21]

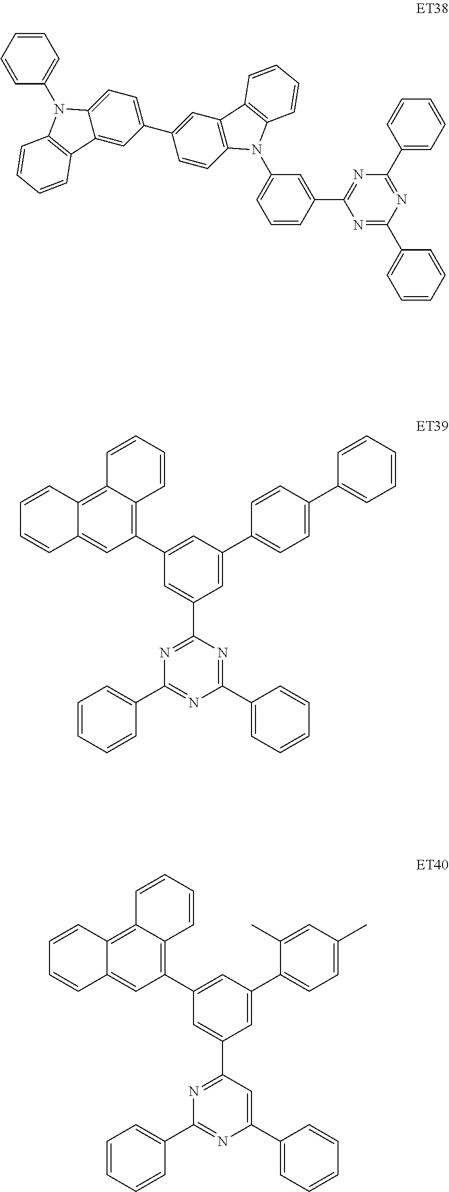 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

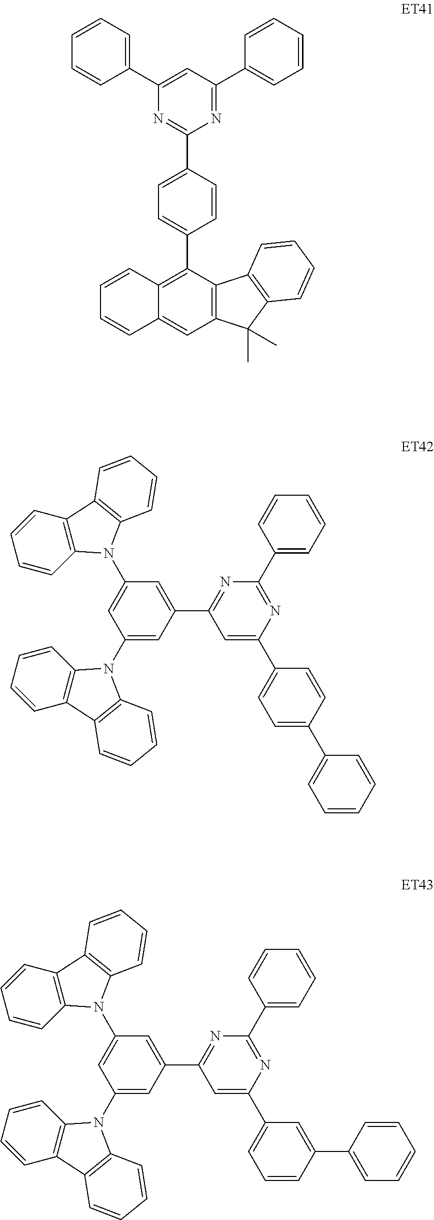 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

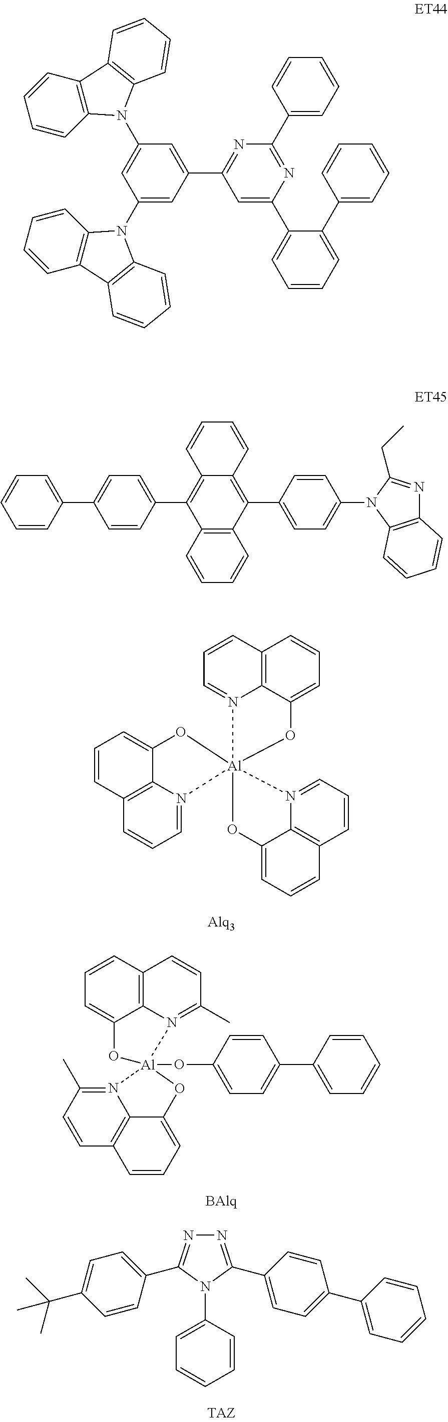

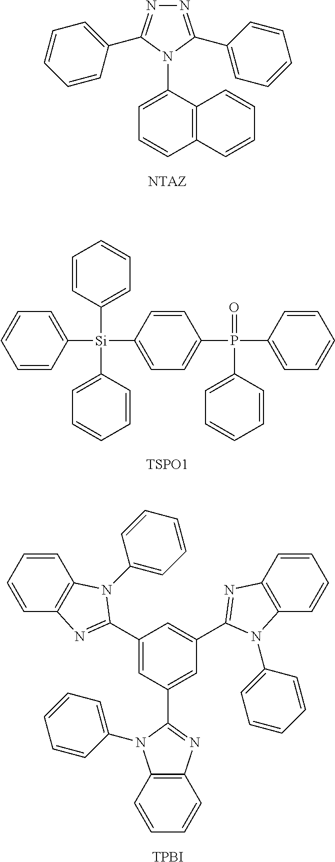

A thickness of the electron transport region may be in a range of about 100 Å to about 5,000 Å, for example, about 100 Å to about 4,000 Å. When the electron transport region includes a buffer layer, a hole blocking layer, an electron control layer, an electron transport layer, or any combination thereof, a thickness of each of the buffer layer, the hole blocking layer, or the electron control layer may be in a range of about 20 Å to about 1,000 Å, for example, about 30 Å to about 300 Å, and a thickness of the electron transport layer may be in a range of about 100 Å to about 1,000 Å, for example, about 150 Å to about 500 Å. When the thicknesses of the buffer layer, the hole blocking layer, the electron control layer, and/or the electron transport layer are within these ranges, satisfactory electron transporting characteristics may be obtained without a substantial increase in driving voltage.

The electron transport region (for example, the electron transport layer in the electron transport region) may further include, in addition to the materials described above, a metal-containing material.

The metal-containing material may include an alkali metal complex, an alkaline earth-metal complex, or any combination thereof. A metal ion of the alkali metal complex may be a Li ion, a Na ion, a K ion, a Rb ion, and/or a Cs ion, and a metal ion of the alkaline earth-metal complex may be a Be ion, a Mg ion, a Ca ion, a Sr ion, and/or a Ba ion. A ligand coordinated with the metal ion of the alkali metal complex and/or the alkaline earth-metal complex may be a hydroxy quinoline, a hydroxy isoquinoline, a hydroxy benzoquinoline, a hydroxy acridine, a hydroxy phenanthridine, a hydroxy phenyloxazole, a hydroxy phenylthiazole, a hydroxy phenyloxadiazole, a hydroxy phenylthiadiazole, a hydroxy phenylpyridine, a hydroxy phenylbenzimidazole, a hydroxy phenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or ET-D2:

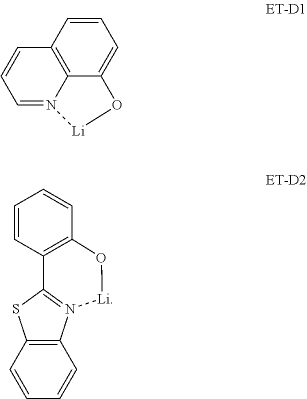

The electron transport region may include an electron injection layer that facilitates the injection of electrons from the second electrode 150. The electron injection layer may directly contact the second electrode 150.

The electron injection layer may have: i) a single-layered structure consisting of a single layer consisting of a single material, ii) a single-layered structure consisting of a single layer consisting of a plurality of different materials, or iii) a multi-layered structure including a plurality of layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combinations thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may be oxides and/or halides (for example, fluorides, chlorides, bromides, and/or iodides) of the alkali metal, the alkaline earth metal, and the rare earth metal, telluride, or any combination thereof.

The alkali metal-containing compound may be alkali metal oxides (such as Li₂O, Cs₂O, and/or K₂O), alkali metal halides (such as LiF, NaF, CsF, KF, LiI, NaI, CsI, and/or KI), or any combination thereof. The alkaline earth metal-containing compound may include an alkaline earth metal oxide, such as BaO, SrO, CaO, BaₓSr₁₋ₓO (x is a real number that satisfies the condition of 0<x<1), and/or BaₓCa₁₋ₓO (x is a real number that satisfies the condition of 0<x<1). The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In an embodiment, the rare earth metal-containing compound may include lanthanide metal telluride. Non-limiting examples of the lanthanide metal telluride are LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

The alkali metal complex, the alkaline earth-metal complex, and the rare earth metal complex may include i) one of the metal ions of the alkali metal, the alkaline earth metal, and the rare earth metal and ii) as a ligand linked to the metal ion, for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof.

The electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof, or may further include an organic material (for example, a compound represented by Formula 601).

In an embodiment, the electron injection layer may include (e.g., consist of) i) an alkali metal-containing compound (for example, an alkali metal halide), or ii) a) an alkali metal-containing compound (for example, an alkali metal halide); and b) an alkali metal, an alkaline earth metal, a rare earth metal, or any combination thereof. In an embodiment, the electron injection layer may be a KI:Yb co-deposited layer or a RbI:Yb co-deposited layer.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combination thereof may be homogeneously or non-homogeneously dispersed in a matrix including the organic material.

A thickness of the electron injection layer may be in a range of about 1 Å to about 100 Å, for example, about 3 Å to about 90 Å. When the thickness of the electron injection layer is within the ranges described above, satisfactory electron injection characteristics may be obtained without a substantial increase in driving voltage.

### [Second Electrode 150]

The second electrode 150 may be located on the interlayer 130 having such a structure. The second electrode 150 may be a cathode, which is an electron injection electrode, and as the material for forming the second electrode 150, a metal, an alloy, an electrically conductive compound, or any combination thereof, each having a low work function, may be utilized.

The second electrode 150 may include at least one selected from lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or a combination thereof. The second electrode 150 may be a transmissive electrode, a semi-transmissive electrode, or a reflective electrode.

The second electrode 150 may have a single-layered structure or a multi-layered structure including two or more layers.

### [Capping Layer]

A first capping layer may be located outside the first electrode 110 (e.g., on the side opposite to the second electrode), and/or a second capping layer may be located outside the second electrode 150 (e.g., on the side opposite to the first electrode). For example, the light-emitting device 10 may have a structure in which the first capping layer, the first electrode 110, the interlayer 130, and the second electrode 150 are sequentially stacked in this stated order, a structure in which the first electrode 110, the interlayer 130, the second electrode 150, and the second capping layer are sequentially stacked in this stated order, or a structure in which the first capping layer, the first electrode 110, the interlayer 130, the second electrode 150, and the second capping layer are sequentially stacked in this stated order.

Light generated in the emission layer of the interlayer 130 of the light-emitting device 10 may be extracted (e.g., emitted) toward the outside through the first electrode 110 and the first capping layer, each of which may include a semi-transmissive material (e.g., is a semi-transmissive electrode or layer) or a transmissive material (e.g., is a transmissive electrode or layer), or light generated in the emission layer of the interlayer 130 of the light-emitting device 10 may be extracted (e.g., emitted) toward the outside through the second electrode 150 and the second capping layer, each of which may include a semi-transmissive material (e.g., is a semi-transmissive electrode or layer) or a transmissive material (e.g., is a transmissive electrode or layer).

The first capping layer and the second capping layer may increase external luminescence efficiency according to the principle of constructive interference. Accordingly, light extraction efficiency of the light-emitting device 10 may be increased, so that luminescence efficiency of the light-emitting device 10 may be also improved.

The first capping layer and the second capping layer may each include a material having a refractive index of equal to or greater than 1.6 (at 589 nm).

The first capping layer and the second capping layer may each independently be an organic capping layer including an organic material, an inorganic capping layer including an inorganic material, or a composite capping layer including an organic material and an inorganic material.

At least one selected from the first capping layer and the second capping layer may each independently include a carbocyclic compound, a heterocyclic compound, an amine group-containing compound, a porphyrine derivative, a phthalocyanine derivative, a naphthalocyanine derivative, an alkali metal complex, an alkaline earth-metal complex, or a combination thereof. The carbocyclic compound, the heterocyclic compound, and the amine group-containing compound may be optionally substituted with a substituent containing O, N, S, Se, Si, F, Cl, Br, I, or any combination thereof. In an embodiment, at least one of the first capping layer and the second capping layer may each independently include an amine group-containing compound.

In an embodiment, at least one of the first capping layer and the second capping layer may each independently include a compound represented by Formula 201, a compound represented by Formula 202, or any combination thereof.

In one or more embodiments, at least one of the first capping layer and the second capping layer may each independently include a compound selected from Compounds HT28 to HT33, Compounds CP1 to CP6, β-NPB, or any combination thereof:

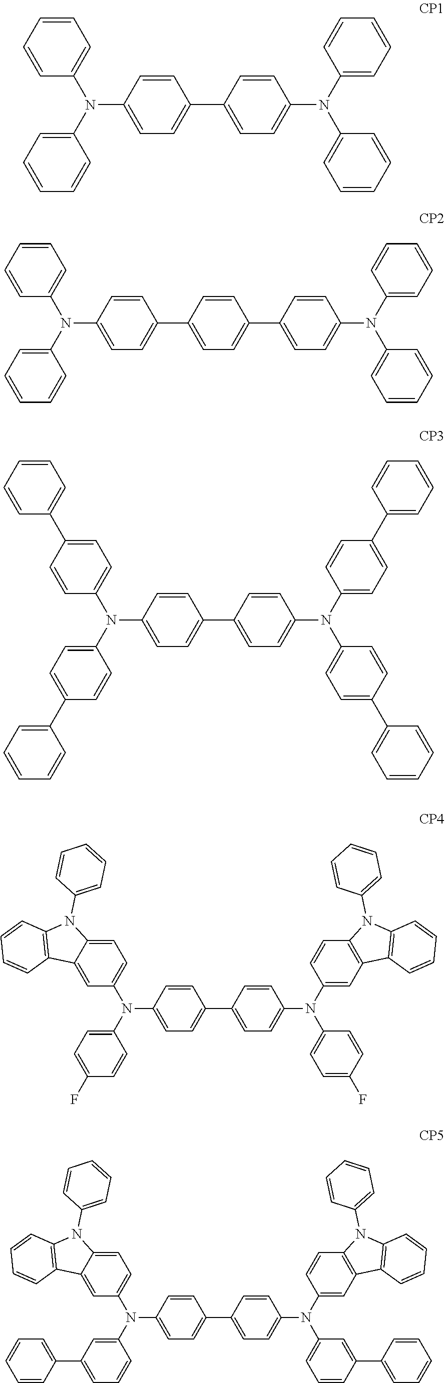 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

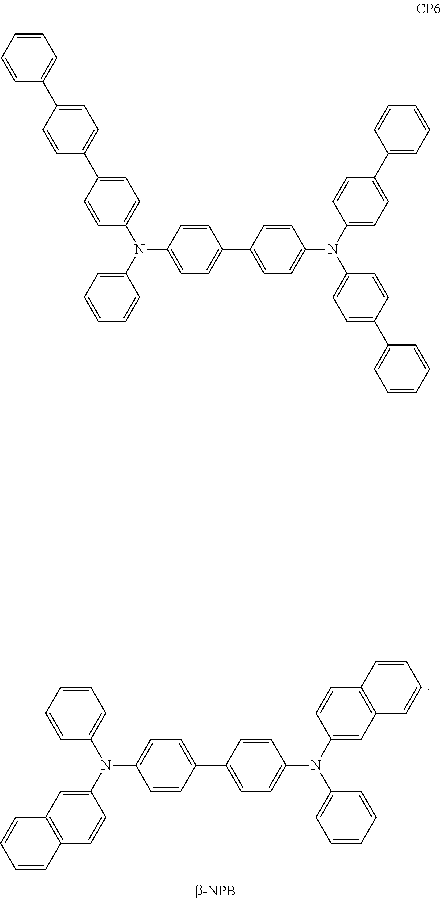 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### [Electronic Apparatus]

The light-emitting device may be included in various suitable electronic apparatuses. In an embodiment, the electronic apparatus including the light-emitting device may be a light-emitting apparatus, an authentication apparatus, and/or the like.

The electronic apparatus (for example, a light-emitting apparatus) may further include, in addition to the light-emitting device, i) a color filter, ii) a color conversion layer, or iii) a color filter and a color conversion layer. The color filter and/or the color conversion layer may be located in at least one traveling direction of light emitted from the light-emitting device. In an embodiment, light emitted from the light-emitting device may be blue light or white light. The light-emitting device may be the same as described above. In an embodiment, the color conversion layer may include quantum dots. The quantum dots may be the same as, for example, the quantum dots described above.

The electronic apparatus may include a first substrate. The first substrate may include a plurality of subpixel areas, the color filter may include a plurality of color filter areas corresponding to the plurality of subpixel areas, respectively, and the color conversion layer may include a plurality of color conversion areas corresponding to the subpixel areas, respectively.

A pixel-defining film may be located between the plurality of subpixel areas to define each of the subpixel areas.

The color filter may further include a plurality of color filter areas and a light-blocking pattern located between adjacent color filter areas of the plurality of color filter areas, and the color conversion layer may further include a plurality of color conversion areas and a light-blocking pattern located between adjacent color conversion areas of the plurality of color conversion areas.

The plurality of color filter areas (or the plurality of color conversion areas) may include a first area emitting first color light, a second area emitting second color light, and/or a third area emitting third color light, and the first color light, the second color light, and/or the third color light may have different maximum luminescence wavelengths from one another. For example, the first color light may be red light, the second color light may be green light, and the third color light may be blue light. For example, the plurality of color filter areas (or the plurality of color conversion areas) may include quantum dots. For example, the first area may include a red quantum dot (e.g., a red light emitting quantum dot), the second area may include a green quantum dot (e.g., a green light emitting quantum dot), and the third area may not include a quantum dot. The quantum dot may be the same as described in the present specification. Each of the first area, the second area, and/or the third area may further include a scattering body (e.g., a scatterer).

For example, the light-emitting device may emit a first light, the first area may absorb the first light to emit first first-color light, the second area may absorb the first light to emit second first-color light, and the third area may absorb the first light to emit third first-color light. In this regard, the first first-color light, the second first-color light, and the third first-color light may have different maximum emission wavelengths from one another. In one embodiment, the first light may be blue light, the first first-color light may be red light, the second first-color light may be green light, and the third first-color light may be blue light.

The electronic apparatus may further include a thin-film transistor in addition to the light-emitting device 10 as described above. The thin-film transistor may include a source electrode, a drain electrode, and an activation layer (e.g., an active layer), wherein the source electrode or the drain electrode may be electrically connected to the first electrode or the second electrode of the light-emitting device.

The thin-film transistor may further include a gate electrode, a gate insulation layer, and/or the like.

The active layer may include crystalline silicon, amorphous silicon, an organic semiconductor, an oxide semiconductor, and/or the like.

The electronic apparatus may further include a sealing portion (e.g., a sealing layer) for sealing the light-emitting device. The sealing portion may be located between the color filter and the light-emitting device and/or between the color conversion layer and the light-emitting device. The sealing portion allows light from the light-emitting device 10 to be extracted (e.g., emitted) to the outside, while concurrently or simultaneously preventing or substantially preventing external air and moisture from penetrating into the light-emitting device 10. The sealing portion may be a sealing substrate including a transparent glass substrate or a plastic substrate. The sealing portion may be a thin film encapsulation layer including at least one layer of an organic layer and an inorganic layer. When the sealing portion is a thin-film encapsulation layer, the electronic apparatus may be flexible.

On the sealing portion, in addition to the color filter and/or color conversion layer, various suitable functional layers may be further located according to the usage of the electronic apparatus. The functional layers may include a touchscreen layer, a polarization layer, and/or the like. The touchscreen layer may be a pressure-sensitive touchscreen layer, a capacitive touchscreen layer, and/or an infrared touchscreen layer. The authentication apparatus may be, for example, a biometric authentication apparatus for authenticating an individual by utilizing biometric information of a biometric body (for example, a finger tip, a pupil, and/or the like).

The authentication apparatus may further include, in addition to the light-emitting device, a biometric information collector.

The electronic apparatus may be applied to various suitable displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, and/or endoscope displays), fish finders, various suitable measuring instruments, meters (for example, meters for a vehicle, an aircraft, and a vessel), projectors, and/or the like.

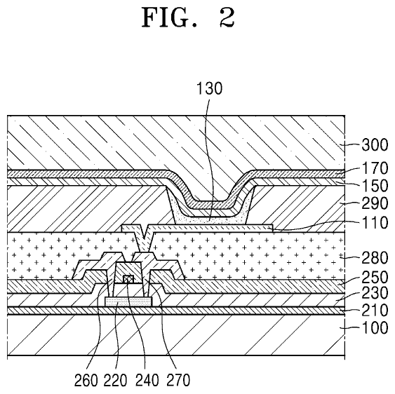

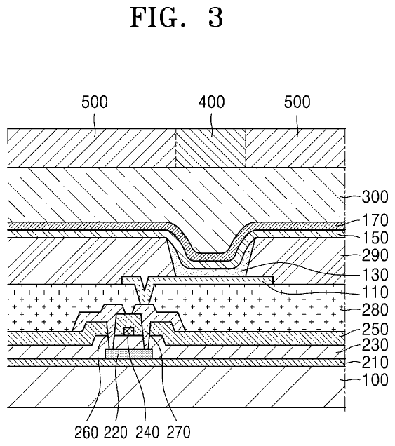

### [Description of FIGS. 2 and 3]

FIG. 2 is a schematic cross-sectional view showing a light-emitting apparatus according to another embodiment of the present disclosure.

The light-emitting apparatus of FIG. 2 includes a substrate 100, a thin-film transistor (TFT), a light-emitting device, and an encapsulation portion 300 that seals light-emitting device.

The substrate 100 may be a flexible substrate, a glass substrate, or a metal substrate. A buffer layer 210 may be located on the substrate 100. The buffer layer 210 may prevent or substantially prevent the penetration of impurities through the substrate 100 and may provide a flat surface on the substrate 100.

A TFT may be located on the buffer layer 210. The TFT may include an activation layer (e.g., an active layer) 220, a gate electrode 240, a source electrode 260, and a drain electrode 270.

The activation layer 220 may include an inorganic semiconductor, such as silicon or polysilicon, an organic semiconductor, or an oxide semiconductor, and may include a source region, a drain region, and a channel region.

A gate insulating film 230 for insulating the activation layer 220 from the gate electrode 240 may be located on the activation layer 220, and the gate electrode 240 may be located on the gate insulating film 230.

An interlayer insulating film 250 may be located on the gate electrode 240. The interlayer insulating film 250 may be located between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be located on the interlayer insulating film 250. The interlayer insulating film 250 and the gate insulating film 230 may be formed to expose the source region and the drain region of the activation layer 220, and the source electrode 260 and the drain electrode 270 may be located to be in contact with the exposed portions of the source region and the drain region of the activation layer 220.

The TFT may be electrically connected to the light-emitting device to drive the light-emitting device, and may be covered by a passivation layer 280. The passivation layer 280 may include an inorganic insulating film, an organic insulating film, or a combination thereof. The light-emitting device may be provided on the passivation layer 280. The light-emitting device includes the first electrode 110, the interlayer 130, and the second electrode 150.

The first electrode 110 may be located on the passivation layer 280. The passivation layer 280 may expose a portion of the drain electrode 270 without completely covering the drain electrode 270, and the first electrode 110 may be connected to the exposed portion of the drain electrode 270.

A pixel defining layer 290 including an insulating material may be located on the first electrode 110. The pixel defining layer 290 may expose a certain region of the first electrode 110, and the interlayer 130 may be formed in the exposed region of the first electrode 110. The pixel defining layer 290 may be a polyimide-based organic film or a polyacryl-based organic film. In one embodiment, at least one or more layers of the interlayer 130 may extend to the upper portion of the pixel defining layer 290 and may be in the form of a common layer.

The second electrode 150 may be located on the interlayer 130, and a capping layer 170 may be additionally formed on the second electrode 150. The capping layer 170 may be formed to cover the second electrode 150.

The encapsulation portion 300 may be located on the capping layer 170. The encapsulation portion 300 may be located on the light-emitting device to serve as a layer that protects the light-emitting device from moisture and/or oxygen. The encapsulation portion 300 may include: an inorganic film including silicon nitride (SiNₓ), silicon oxide (SiOₓ), indium tin oxide, indium zinc oxide, or a combination thereof; an organic film including polyethylene terephthalate, polyethylene naphthalate, polycarbonate, polyimide, polyethylene sulfonate, polyoxymethylene, polyarylate, hexamethyldisiloxane, an acrylic-based resin (for example, polymethyl methacrylate and/or polyacrylic acid), an epoxy-based resin (for example, aliphatic glycidyl ether (AGE)), or a combination thereof); or a combination of an inorganic film and an organic film.

FIG. 3 is a schematic cross-sectional view showing a light-emitting apparatus according to another embodiment of the present disclosure.

The light-emitting apparatus of FIG. 3 is the same as the light-emitting apparatus of FIG. 2, except that a light-blocking pattern 500 and a functional region 400 are additionally located on the encapsulation portion 300. The functional region 400 may be i) a color filter area, ii) a color conversion area, or iii) a combination of the color filter area and the color conversion area. In an embodiment, a light-emitting device included in the light-emitting apparatus of FIG. 3 may be a tandem light-emitting device.

### [Preparation Method]

Layers constituting the hole transport region, the emission layer, and layers constituting the electron transport region may be formed in a certain region by utilizing one or more suitable methods selected from vacuum deposition, spin coating, casting, Langmuir-Blodgett (LB) deposition, ink-jet printing, laser-printing, and laser-induced thermal imaging.

When layers constituting the hole transport region, the emission layer, and layers constituting the electron transport region are formed by vacuum deposition, the deposition may be performed at a deposition temperature of about 100° C. to about 500° C., a vacuum degree of about 10⁻⁸ torr to about 10⁻³ torr, and a deposition speed of about 0.01 Å/sec to about 100 Å/sec by taking into account a material to be included in the layer to be formed and the structure of the layer to be formed.

### Definition of Terms

The term “C₃-C₆₀ carbocyclic group” as used herein refers to a cyclic group that consists of only carbon as a ring-forming atom and has three to sixty carbon atoms, preferably C₅-C₃₀ carbocyclic group or C₅-C₆₀ carbocyclic group, and the term “C₁-C₆₀ heterocyclic group” as used herein refers to a cyclic group that has one to sixty carbon atoms and further includes, in addition to carbon, a heteroatom as a ring-forming atom, preferably C₁-C₃₀ heterocyclic group. The C₃-C₆₀ carbocyclic group and the C₁-C₆₀ heterocyclic group may each be a monocyclic group that consists of one ring or a polycyclic group in which two or more rings are condensed with each other. For example, the number of ring-forming atoms of the C₁-C₆₀ heterocyclic group may be from 3 to 61.

The term “cyclic group” as used herein includes the C₃-C₆₀ carbocyclic group and the C₁-C₆₀ heterocyclic group.

The term “π electron-rich C₃-C₆₀ cyclic group” as used herein refers to a cyclic group that has one to sixty carbon atoms and does not include *—N═*′ as a ring-forming moiety, and the term “π electron-deficient nitrogen-containing C₁-C₆₀ cyclic group” as used herein refers to a heterocyclic group that has one to sixty carbon atoms and also includes *—N═*′ as a ring-forming moiety.

For example,
the C₃-C₆₀ carbocyclic group may be i) a group T1 or ii) a condensed cyclic group in which two or more groups T1 are condensed with each other (for example, a cyclopentadiene group, an adamantane group, a norbornane group, a benzene group, a pentalene group, a naphthalene group, an azulene group, an indacene group, acenaphthene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, and/or an indenoanthracene group),
the C₁-C₆₀ heterocyclic group may be i) a group T2, ii) a condensed cyclic group in which two or more groups T2 are condensed with each other, or iii) a condensed cyclic group in which at least one group T2 and at least one group T1 are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothieno dibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, and/or an azadibenzofuran group),
the π electron-rich C₃-C₆₀ cyclic group may be i) a group T1, ii) a condensed cyclic group in which two or more groups T1 are condensed with each other, iii) a group T3, iv) a condensed cyclic group in which two or more groups T3 are condensed with each other, or v) a condensed cyclic group in which at least one group T3 and at least one group T1 are condensed with each other (for example, a C₃-C₆₀ carbocyclic group, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, and/or a benzothienodibenzothiophene group),
the π electron-deficient nitrogen-containing C₁-C₆₀ cyclic group may be i) a group T4, ii) a condensed cyclic group in which two or more groups T4 are condensed with each other, iii) a condensed cyclic group in which at least one group T4 and at least one group T1 are condensed with each other, iv) a condensed cyclic group in which at least one group T4 and at least one group T3 are condensed with each other, or v) a condensed cyclic group in which at least one group T4, at least one group T1, and at least one group T3 are condensed with each other (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, and/or an azadibenzofuran group),
the group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane group (or, a bicyclo[2.2.1]heptane group), a norbornene group, a bicyclo[1.1.1]pentane group, a bicyclo[2.1.1]hexane group, a bicyclo[2.2.2]octane group, or a benzene group,
the group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group,
the group T3 may be a furan group, a thiophene group, a 1H-pyrrole group, a silole group, or a borole group, and
the group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The term “cyclic group,” “C₃-C₆₀ carbocyclic group,” “C₁-C₆₀ heterocyclic group,” “π electron-rich C₃-C₆₀ cyclic group,” or “π electron-deficient nitrogen-containing C₁-C₆₀ cyclic group” as used herein each refers to a monovalent group or a polyvalent group (for example, a divalent group, a trivalent group, a tetravalent group, and/or the like), that is condensed with (e.g., combined together with) a cyclic group, according to the structure of a formula described with corresponding terms. For example, the “benzene group” may be a benzo group, a phenyl group, a phenylene group, and/or the like, which may be easily understand by one of ordinary skill in the art according to the structure of a formula including the “benzene group”.

In an embodiment, non-limiting examples of the monovalent C₃-C₆₀ carbocyclic group and the monovalent C₁-C₆₀ heterocyclic group are a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and non-limiting examples of the divalent C₃-C₆₀ carbocyclic group and the divalent C₁-C₆₀ heterocyclic group are a C₃-C₁₀ cycloalkylene group, a C₁-C₁₀heterocycloalkylene group, a C₃-C₁₀ cycloalkenylene group, a C₁-C₁₀heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein refers to a linear or branched aliphatic hydrocarbon monovalent group having 1 to 60 carbon atoms, preferably C₁-C₂₀ alkyl group, and non-limiting examples thereof are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as used herein refers to a divalent group having the same structure as the C₁-C₆₀ alkyl group, preferably C₁-C₂₀ alkylene group or C₁-C₅ alkylene group.

The term “C₂-C₆₀ alkenyl group” as used herein refers to a monovalent hydrocarbon group having at least one carbon-carbon double bond in the middle or at a terminal end (e.g., the terminus) of a C₂-C₆₀ alkyl group, preferably C₂-C₂₀ alkenyl group, and non-limiting examples thereof include an ethenyl group, a propenyl group, and a butenyl group. The term “C₂-C₆₀ alkenylene group” as used herein refers to a divalent group having the same structure as the C₂-C₆₀ alkenyl group, preferably C₂-C₂₀ alkenylene group or C₂-C₅ alkenylene group.

The term “C₂-C₆₀ alkynyl group” as used herein refers to a monovalent hydrocarbon group having at least one carbon-carbon triple bond in the middle or at a terminal end (e.g., the terminus) of a C₂-C₆₀ alkyl group, preferably C₂-C₂₀ alkynyl group, and non-limiting examples thereof include an ethynyl group, and a propynyl group. The term “C₂-C₆₀ alkynylene group” as used herein refers to a divalent group having the same structure as the C₂-C₆₀ alkynyl group.

The term “C₁-C₆₀ alkoxy group” as used herein refers to a monovalent group represented by —OA₁₀₁ (wherein A₁₀₁ is the C₁-C₆₀ alkyl group), preferably C₁-C₂₀ alkoxy group, and non-limiting examples thereof include a methoxy group, an ethoxy group, and an isopropyloxy group.

The term “C₃-C₁₀ cycloalkyl group” as used herein refers to a monovalent saturated hydrocarbon cyclic group having 3 to 10 carbon atoms, and non-limiting examples thereof are a cyclopropyl group, a cyclobutyl group, a cyclopentyl group, a cyclohexyl group, a cycloheptyl group, a cycloctyl group, an adamantanyl group, a norbornanyl group (or a bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent cyclic group that further includes, in addition to 1 to 10 carbon atoms, at least one heteroatom as a ring-forming atom, and non-limiting examples thereof are a 1,2,3,4-oxatriazolidinyl group, a tetrahydrofuranyl group, and a tetrahydrothienyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent monocyclic group that has 3 to 10 carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent cyclic group that has, in addition to 1 to 10 carbon atoms, at least one heteroatom as a ring-forming atom, and at least one double bond in the cyclic structure thereof. Non-limiting examples of the C₁-C₁₀ heterocycloalkenyl group include a 4,5-dihydro-1,2,3,4-oxatriazolyl group, a 2,3-dihydrofuranyl group, and a 2,3-dihydrothienyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Non-limiting examples of the C₆-C₆₀ aryl group are a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, a fluorenyl group and an ovalenyl group. When the C₆-C₆₀ aryl group and the C₆-C₆₀ arylene group each include two or more rings, the two or more rings may be fused to each other.

The term “C₁-C₆₀ heteroaryl group” as used herein refers to a monovalent group having a heterocyclic aromatic system that has, in addition to 1 to 60 carbon atoms, at least one heteroatom as a ring-forming atom. The term “C₁-C₆₀ heteroarylene group” as used herein refers to a divalent group having a heterocyclic aromatic system that has, in addition to 1 to 60 carbon atoms, at least one heteroatom as a ring-forming atom. Non-limiting examples of the C₁-C₆₀ heteroaryl group are a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a carbazolyl group, a dibenzofuranyl group, a dibenzothiofuranyl group, and a naphthyridinyl group. When the C₁-C₆₀ heteroaryl group and the C₁-C₆₀ heteroarylene group each include two or more rings, the two or more rings may be condensed with each other.

The term “monovalent non-aromatic condensed polycyclic group” as used herein refers to a monovalent group having two or more rings condensed with each other, only carbon atoms (for example, having 8 to 60 carbon atoms) as ring-forming atoms, and no aromaticity in its entire molecular structure (e.g., the entire molecular structure is not aromatic). Non-limiting examples of the monovalent non-aromatic condensed polycyclic group are an indenyl group, a fluorenyl group, a spiro-bifluorenyl group, a benzofluorenyl group, an indenophenanthrenyl group, an adamantyl group, and an indenoanthracenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group having two or more rings condensed to each other, at least one heteroatom other than carbon atoms (for example, having 1 to 60 carbon atoms), as a ring-forming atom, and no aromaticity in its entire molecular structure (e.g., the entire molecular structure is not aromatic). Non-limiting examples of the monovalent non-aromatic condensed heteropolycyclic group are a pyrrolyl group, a thienyl group, a furanyl group, an indolyl group, a benzoindolyl group, a naphthoindolyl group, an isoindolyl group, a benzoisoindolyl group, a naphthoisoindolyl group, a benzosilolyl group, a benzothienyl group, a benzofuranyl group, a 9H-xanthenyl group, a dibenzosilolyl group, a dibenzothienyl group, an azacarbazolyl group, an azafluorenyl group, an azadibenzosilolyl group, an azadibenzothienyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothienyl group, a benzonaphthosilolyl group, a benzofurodibenzofuranyl group, a benzofurodibenzothienyl group, an azaadamantyl group, and a benzothienodibenzothienyl group. The term “divalent non-aromatic condensed heteropolycyclic group” as used herein refers to a divalent group having the same structure as the monovalent non-aromatic condensed heteropolycyclic group.

The term “C₆-C₆₀ aryloxy group” as used herein refers to a monovalent group represented by —OA₁₀₂ (wherein A₁₀₂ is the C₆-C₆₀ aryl group), and the term “C₆-C₆₀ arylthio group” as used herein refers to a monovalent group represented by —SA₁₀₃ (wherein A₁₀₃ is the C₆-C₆₀ aryl group).

The term “R₁₀ₐ” as used herein may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —CI, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —CI, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the present specification, Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as used herein refers to any atom other than a carbon atom. Non-limiting examples of the heteroatom are O, S, N, P, Si, B, Ge, Se, and any combination thereof.

The term “Ph” as used herein refers to a phenyl group, the term “Me” as used herein refers to a methyl group, the term “Et” as used herein refers to an ethyl group, the term “tert-Bu” or “Bu^{t}” as used herein refers to a tert-butyl group, and the term “OMe” as used herein refers to a methoxy group.

The term “biphenyl group” as used herein refers to “a phenyl group substituted with a phenyl group.” In other words, the “biphenyl group” is a substituted phenyl group having a C₆-C₆₀ aryl group as a substituent.

The term “terphenyl group” as used herein refers to “a phenyl group substituted with a biphenyl group.” In other words, the “terphenyl group” is a substituted phenyl group having, as a substituent, a C₆-C₆₀ aryl group substituted with a C₆-C₆₀ aryl group.

* and *′ as used herein, unless defined otherwise, each refer to a binding site to a neighboring atom in a corresponding formula.

Hereinafter, a compound according to embodiments and a light-emitting device according to embodiments will be described in more detail with reference to Synthesis Examples and Examples. The wording “B was utilized instead of A” used in describing Synthesis Examples refers to that an identical molar equivalent of B was utilized in place of A.

### EXAMPLES

### Synthesis Example 1: Synthesis of Compound 1

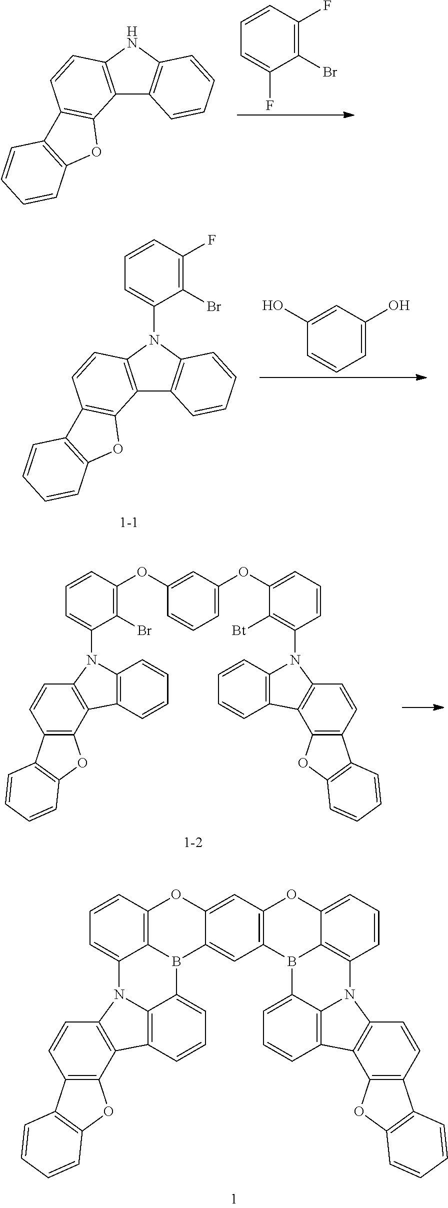

### Synthesis of Intermediate 1-1

5H-benzofuro[3,2-c]carbazole (1 eq), 2-bromo-1,3-difluorobenzene (1.5 eq), and K₃PO₄ (2 eq) were dissolved in DMF, and the mixed solution was stirred at a temperature of 160° C. for 12 hours. After cooling, the solvent was removed therefrom under reduced pressure, and the resultant product was washed three times with ethyl acetate and water, and an organic layer obtained by an extraction process was dried utilizing MgSO₄ and dried under reduced pressure. Then, the resultant product was subjected to column chromatography utilizing MC and n-Hexane, so as to obtain Intermediate 1-1. (Yield:55%)

### Synthesis of Intermediate 1-2

Resorcinol (1 eq), Intermediate 1-1 (2.1 eq), and K₃PO₄ (3 eq) were dissolved in DMF, and the mixed solution was stirred at a temperature of 160° C. for 12 hours. After cooling, the solvent was removed therefrom under reduced pressure, and the resultant product was washed three times with ethyl acetate and water, and an organic layer obtained by an extraction process was dried utilizing MgSO₄ and dried under reduced pressure. Then, the resultant product was subjected to column chromatography utilizing MC and n-Hexane, so as to obtain Intermediate 1-2. (Yield 52%)

### Synthesis of Compound 1

Intermediate 1-2 (1 eq) was dissolved in o-xylene, and then, the mixed solution was cooled to a temperature of 0° C. in the nitrogen atmosphere. n-BuLi (4 eq) was slowly injected thereto, and the reaction solution was stirred for 2 hours after the reaction temperature was raised to 70° C. Then, the reaction solution was stirred again for 2 hours after the reaction temperature was raised to 120° C. After cooling the temperature of the reactor to 0° C., BBr₃ (5 eq) was slowly injected thereto. After completion of injection, the reaction solution was stirred for 1 hour. After cooling the temperature of the reactor to 0° C., triethylamine (6 eq) was injected thereto, and the reaction solution was stirred again for 12 hours after the temperature was raised to 140° C. After cooling, triethylamine was slowly dropped into the flask including the reaction product to terminate the reaction. Then, ethyl alcohol was added to the reaction product for precipitation, so as to obtain a solid product by filtration. The solid product thus obtained was subjected to column chromatography, so as to obtain Compound 1. (Yield:6%)

### Synthesis Example 2: Synthesis of Compound 3

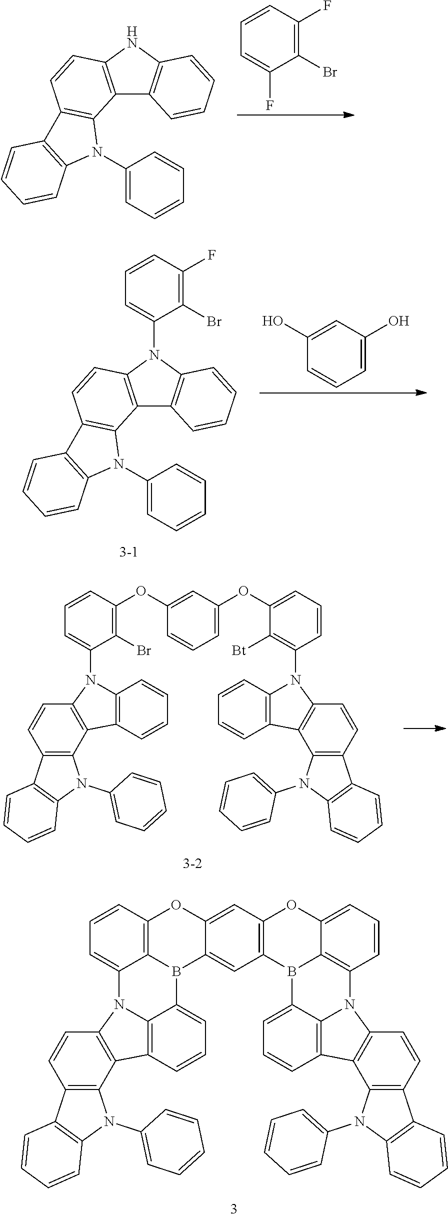

### Synthesis of Intermediate 3-1

Intermediate 3-1 was synthesized in the same manner as utilized to prepare Intermediate 1-1, except that 12-phenyl-5,12-dihydroindolo[3,2-a]carbazole was utilized instead of 5H-benzofuro[3,2-c]carbazole. (Yield:62%)

### Synthesis of Intermediate 3-2

Intermediate 3-2 was synthesized in the same manner as utilized to prepare Intermediate 1-2, except that Intermediate 3-1 was utilized instead of Intermediate 1-1. (Yield:55%)

### Synthesis of Compound 3

Compound 3 was synthesized in the same manner as utilized to prepare Compound 1, except that Intermediate 3-2 was utilized instead of Intermediate 1-2. (Yield:5%)

### Synthesis Example 3: Synthesis of Compound 6

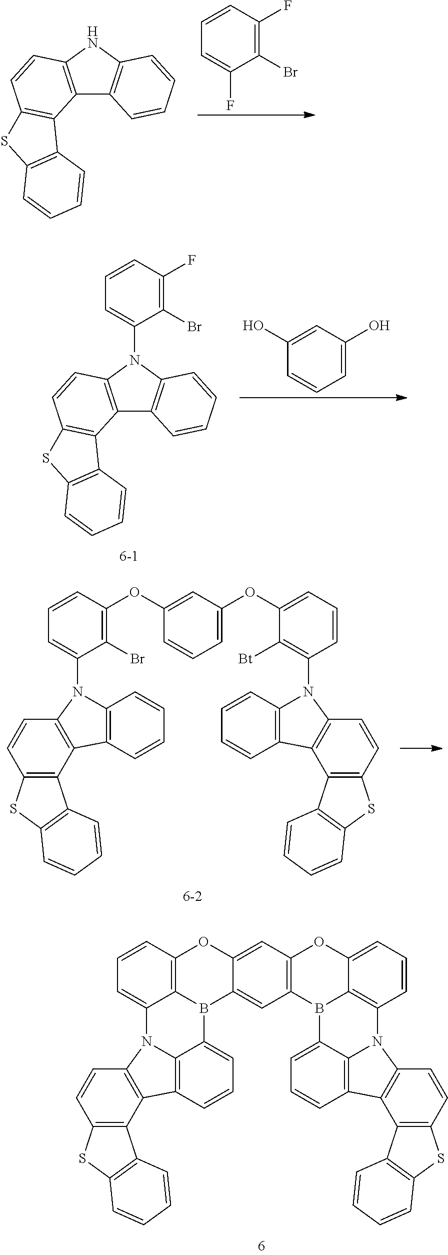

### Synthesis of Intermediate 6-1

Intermediate 6-1 was synthesized in the same manner as utilized to prepare Intermediate 1-1, except that 8H-benzo[4,5]thieno[2,3-c]carbazole was utilized instead of 5H-benzofuro[3,2-c]carbazole. (Yield:58%)

### Synthesis of Intermediate 6-2

Intermediate 6-2 was synthesized in the same manner as utilized to prepare Intermediate 1-2, except that Intermediate 6-1 was utilized instead of Intermediate 1-1. (Yield:70%)

### Synthesis of Compound 6

Compound 6 was synthesized in the same manner as utilized to prepare Compound 1, except that Intermediate 6-2 was utilized instead of Intermediate 1-2. (Yield:3%)

### Synthesis Example 4: Synthesis of Compound 7

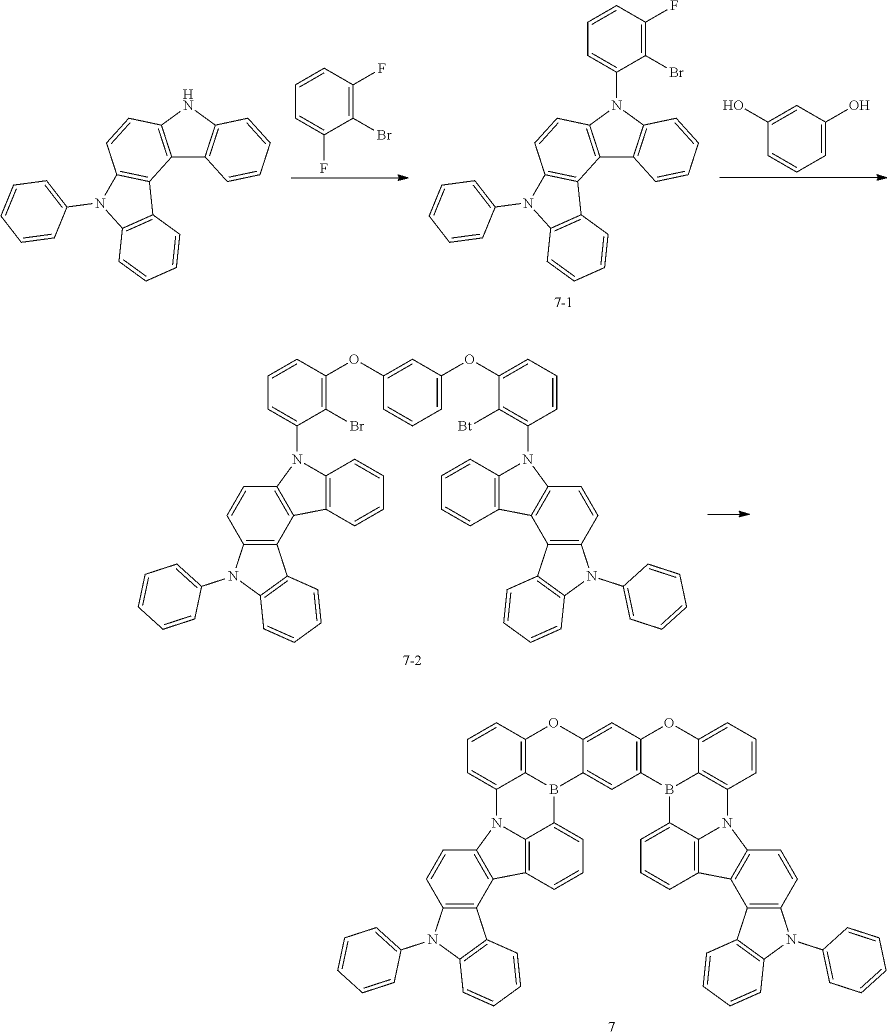

### Synthesis of Intermediate 7-1

Intermediate 7-1 was synthesized in the same manner as utilized to prepare Intermediate 1-1, except that 5-phenyl-5,8-dihydroindolo[2,3-c]carbazole was utilized instead of 5H-benzofuro[3,2-c]carbazole. (Yield:64%)

### Synthesis of Intermediate 7-2

Intermediate 7-2 was synthesized in the same manner as utilized to prepare Intermediate 1-2, except that Intermediate 7-1 was utilized instead of Intermediate 1-1. (Yield:50%)

### Synthesis of Compound 7

Compound 7 was synthesized in the same manner as utilized to prepare Compound 1, except that Intermediate 7-2 was utilized instead of Intermediate 1-2. (Yield:5%)

### Synthesis Example 5: Synthesis of Compound 26

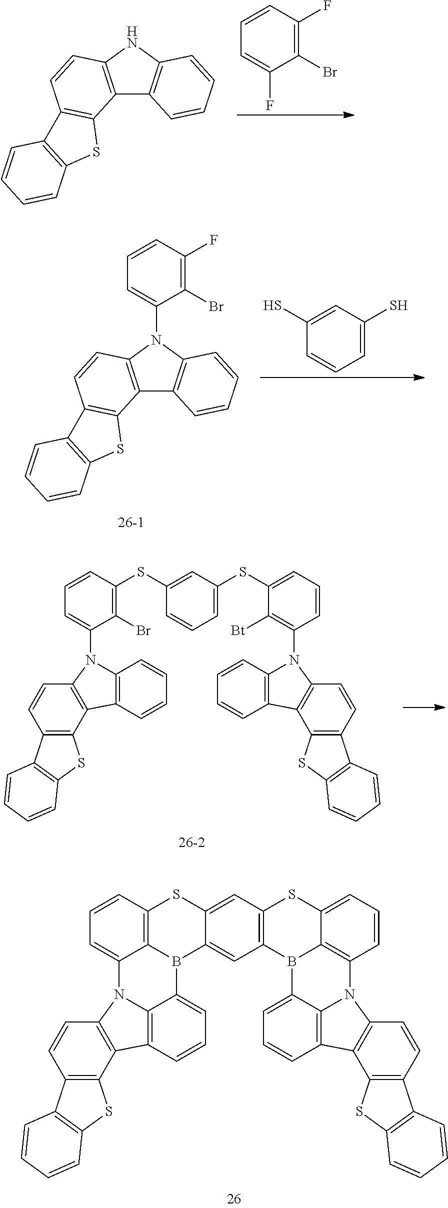

### Synthesis of Intermediate 26-1

Intermediate 26-1 was synthesized in the same manner as utilized to prepare Intermediate 1-1, except that 5H-benzo[4,5]thieno[3,2-c]carbazole was utilized instead of 5H-benzofuro[3,2-c]carbazole. (Yield:44%)

### Synthesis of Intermediate 26-2

Intermediate 26-2 was synthesized in the same manner as utilized to prepare Intermediate 1-2, except that Intermediate 26-1 was utilized instead of Intermediate 1-1. (Yield:64%)

### Synthesis of Compound 26

Compound 26 was synthesized in the same manner as utilized to prepare Compound 1, except that Intermediate 26-2 was utilized instead of Intermediate 1-2. (Yield:2%)

¹H NMR and MS/FAB of the compounds synthesize according to Synthesis Examples 1 to 5 are shown in Table 1. The synthesis of additional compounds other than the compounds shown in Table 1 may be easily recognized by those skilled in the art by referring to the above synthesis routes and source materials.

TABLE 1

| | | MS/FAB | |
|---|---|---|---|
| Compound | ¹H NMR (δ) | Calc | found |
| 1 | 10.3 (1H, s), 9.32-9.24 (2H, d), 8.35-8.30 (2H, m), | 788.43 | 788.42 |
| | 8.01-7.97 (2H, m), 7.55-7.38 (12H, m), 7.35-7.32 (4H, | | |
| | m), 6.57-6.45 (3H, m) | | |
| 3 | 10.3 (1H, s), 9.31-9.26 (2H, d), 8.32-8.30 (2H, | 938.66 | 938.65 |
| | m), 8.25-8.21 (4H, m), 7.63-7.52 (10H, m), 7.45-7.38 | | |
| | (10H, m), 7.35-7.32 (2H, m), 7.24-7.21 (2H, m), 6.61- | | |
| | 6.50 (3H, m) | | |
| 6 | 10.3 (1H, s), 9.36-9.27 (2H, d), 8.33-8.30 (2H, | 820.55 | 820.54 |
| | m)8.05-7.40 (12H, m), 7.35-7.32 (2H, m), 7.52- | | |
| | 7.38(4H, m), 6.58-6.51 (3H, m) | | |
| 7 | 10.3 (1H, s), 9.33-9.22 (2H, d), 8.34-8.30 (2H, | 938.66 | 938.65 |
| | m)8.25-8.21 (2H, m), 7.66-7.52 (10H, m), 7.45-7.38 | | |
| | (8H, m), 7.35-7.32 (2H, m), 7.52-7.38(4H, m), 7.24- | | |
| | 7.21 (2H, m), 6.55-6.45 (3H, m) | | |
| 26 | 10.4 (1H, s), 9.44-9.35 (2H, d), 8.45-8.30 (6H, | 852.68 | 852.67 |
| | m), 7.76-7.64 (2H, m), 7.51-7.40 (4H, m), 7.52-7.32 | | |
| | (8H, m), 7.15-7.10 (3H, m), | | |

### Example 1

As an anode, a Corning 15 Ω/cm² (1,200 Å) ITO glass substrate was cut to a size of 50 mm×50 mm×0.7 mm, sonicated with isopropyl alcohol and pure water each for 5 minutes, and then cleaned by exposure to ultraviolet rays and ozone for 30 minutes. The ITO glass substrate was provided to a vacuum deposition apparatus.

NPD was vacuum-deposited on the ITO anode formed on the ITO glass substrate to form a hole injection layer having a thickness of 300 Å, and HT6 was vacuum-deposited on the hole injection layer to form a first hole transport layer having a thickness of 200 Å.

CzSi, which is a hole transport compound, was vacuum-deposited on the first hole transport layer to form a second hole transport layer having a thickness of 100 Å.

mCP (host) and Compound 1 (dopant) were co-deposited at a weight ratio of 99:1 on the second hole transport layer to form an emission layer having a thickness of 200 Å.

Subsequently, TSPO1 was deposited on the emission layer to form a buffer layer having a thickness of 200 Å, and TPBI was deposited on the buffer layer to form an electron transport layer having a thickness of 300 Å.

LiF, which is a halogenated alkali metal, was deposited on the electron transport layer to form an electron injection layer having a thickness of 10 Å, and Al was vacuum-deposited thereon to form a LiF/Al electrode having a thickness of 3,000 Å. HT28 was vacuum-deposited on the LiF/Al electrode to form a capping layer having a thickness of 700 Å, thereby completing the manufacture of a light-emitting device.

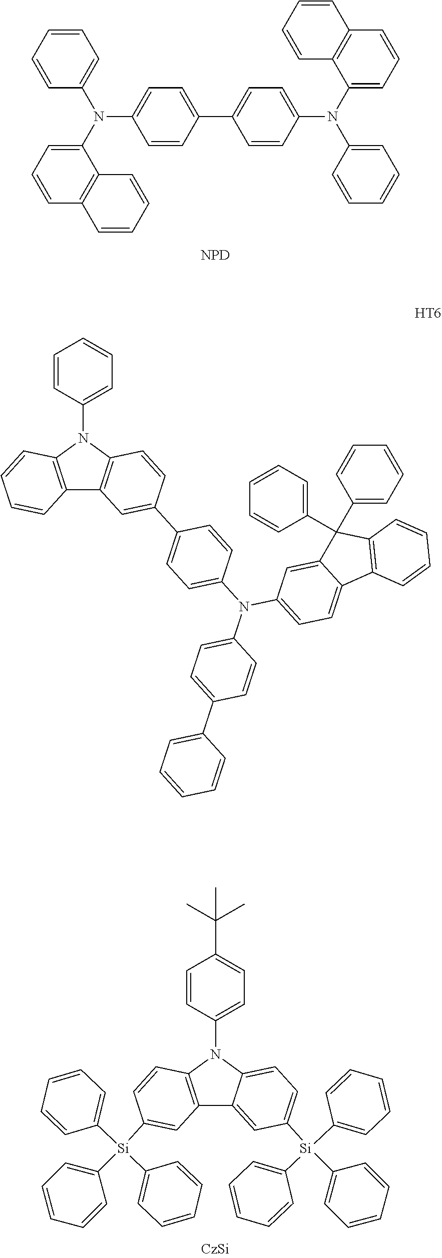 [SMILES: c1ccc(N(c2ccc(-c3ccc(N(c4ccccc4)c4cccc5ccccc45)cc3)cc2)c2cccc3ccccc23)cc1 ; "NPD" ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1]

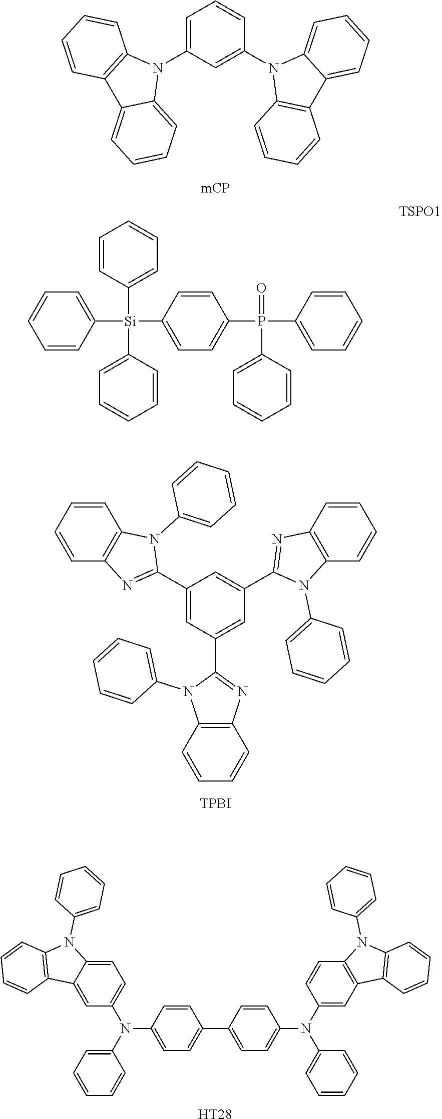

### Examples 2 to 10 and Comparative Examples 1 to 7

Light-emitting devices were manufactured in the same manner as in Example 1, except that materials shown in Table 2 were each utilized instead of HT6 in forming a respective first hole transport layer, and that compounds shown in Table 2 were each utilized instead of Compound 1 in forming a respective emission layer.

### Evaluation Example 1

To evaluate characteristics of the light-emitting devices of Examples 1 to 10 and Comparative Examples 1 to 7, the driving voltage at current density of 10 mA/cm², luminescence efficiency, and maximum external quantum efficiency (EQE) of each were measured. The driving voltage of the light-emitting device was measured utilizing a source meter (Keithley Instrument, 2400 series), and the maximum EQE was measured utilizing an external quantum efficiency measurement device C9920-2-12 of Hamamatsu Photonics Inc. In evaluating the maximum EQE, the luminance/current density was measured utilizing a luminance meter that was calibrated for wavelength sensitivity, and the maximum EQE was converted under the assumption that an angular luminance distribution (Lambertian) was obtained with respect to a fully diffused reflective surface. The results of the characteristics evaluation of the light-emitting devices are shown in Table 2.

TABLE 2

| | Hole | | | | | |
|---|---|---|---|---|---|---|
| | transport | | Driving | Luminescence | Maximum | |
| | layer | Dopant in | voltage | efficiency | EQE | Emission |
| | material | emission layer | (V) | (cd/A) | (%) | color |
| Example 1 | HT6 | Compound 1 | 4.6 | 25.3 | 24.9 | Blue |
| Example 2 | HT6 | Compound 3 | 4.7 | 25.4 | 25.0 | Blue |
| Example 3 | HT6 | Compound 6 | 4.7 | 25.2 | 25.1 | Blue |
| Example 4 | HT6 | Compound 7 | 4.5 | 25.3 | 24.8 | Blue |
| Example 5 | HT6 | Compound 26 | 4.7 | 25.6 | 25.3 | Blue |
| Example 6 | HT44 | Compound 1 | 4.7 | 25.2 | 24.1 | Blue |
| Example 7 | HT44 | Compound 3 | 4.7 | 25.6 | 24.9 | Blue |
| Example 8 | HT44 | Compound 6 | 4.7 | 25.5 | 24.8 | Blue |
| Example 9 | HT44 | Compound 7 | 4.6 | 25.3 | 24.5 | Blue |
| Example 10 | HT44 | Compound 26 | 4.7 | 25.2 | 24.3 | Blue |
| Comparative | HT6 | Compound A | 5.7 | 15.5 | 15.9 | Blue |
| Example 1 | | | | | | |
| Comparative | HT6 | Compound B | 5.0 | 21.5 | 20.8 | Blue |
| Example 2 | | | | | | |
| Comparative | HT44 | Compound A | 5.8 | 14.9 | 14.6 | Blue |
| Example 3 | | | | | | |
| Comparative | HT44 | Compound B | 4.9 | 23.3 | 22.2 | Blue |
| Example 4 | | | | | | |
| Comparative | NPD | Compound 1 | 5.1 | 20.1 | 18.9 | Blue |
| Example 5 | | | | | | |
| Comparative | NPD | Compound 3 | 5.2 | 19.8 | 19.5 | Blue |
| Example 6 | | | | | | |
| Comparative | NPD | Compound 26 | 5.1 | 20.9 | 19.0 | Blue |
| Example 7 | | | | | | |

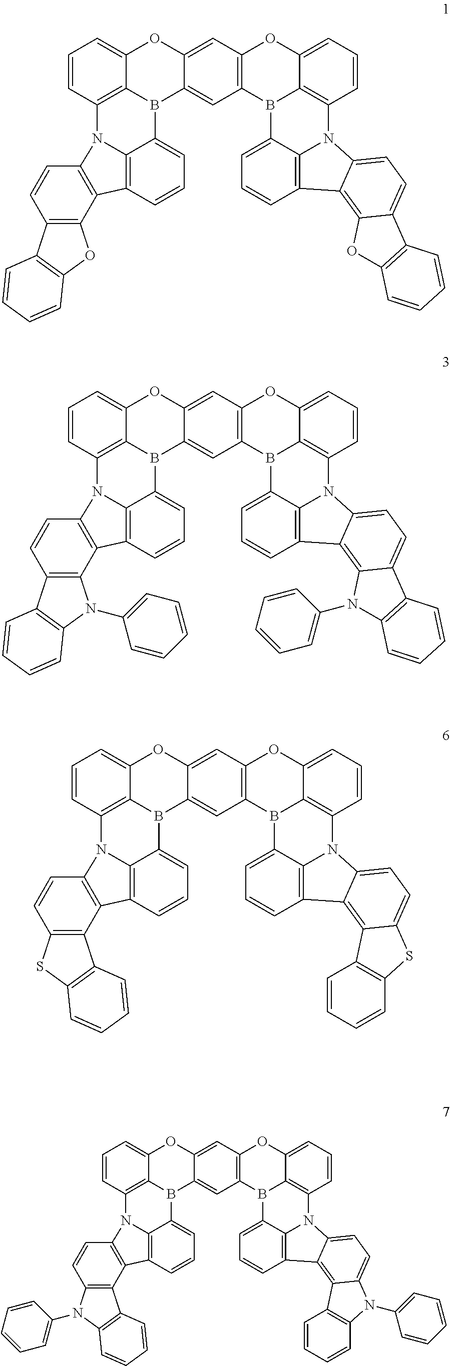 [SMILES: c1cc2c3c(c1)-n1c4ccc5c6ccccc6oc5c4c4cccc(c41)B3c1cc3c(cc1O2)Oc1cccc2c1B3c1cccc3c4c5oc6ccccc6c5ccc4n-2c13 ; c1ccc(-n2c3ccccc3c3ccc4c(c5cccc6c5n4-c4cccc5c4B6c4cc6c(cc4O5)Oc4cccc5c4B6c4cccc6c7c(ccc8c9ccccc9n(-c9ccccc9)c87)n-5c46)c32)cc1 ; c1cc2c3c(c1)-n1c4ccc5sc6ccccc6c5c4c4cccc(c41)B3c1cc3c(cc1O2)Oc1cccc2c1B3c1cccc3c4c5c(ccc4n-2c13)sc1ccccc15 ; c1ccc(-n2c3ccccc3c3c4c5cccc6c5n(c4ccc32)-c2cccc3c2B6c2cc4c(cc2O3)Oc2cccc3c2B4c2cccc4c5c6c7ccccc7n(-c7ccccc7)c6ccc5n-3c24)cc1]

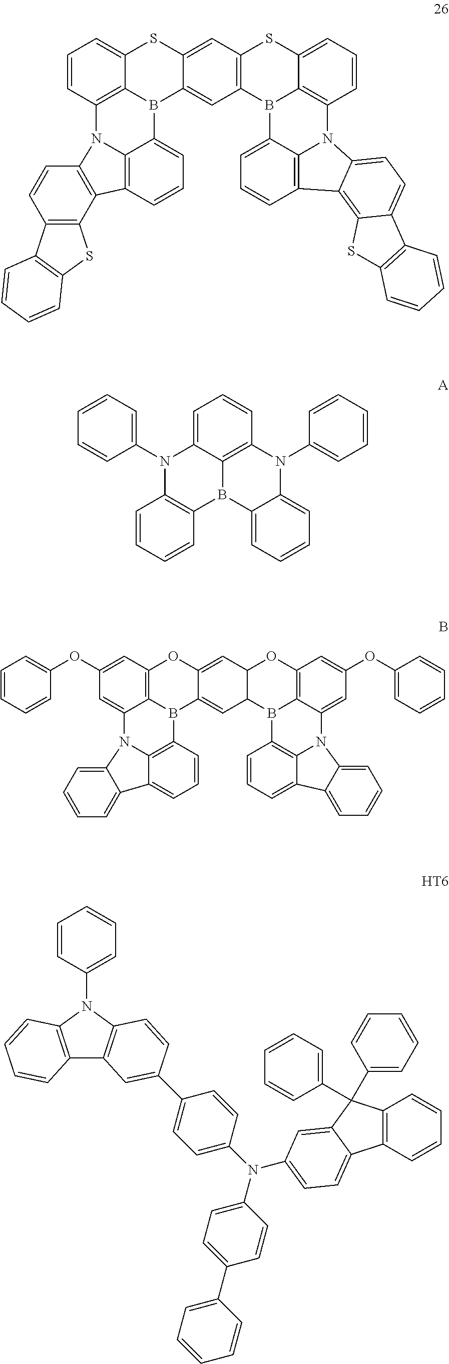 [SMILES: c1cc2c3c(c1)-n1c4ccc5c6ccccc6sc5c4c4cccc(c41)B3c1cc3c(cc1S2)Sc1cccc2c1B3c1cccc3c4c5sc6ccccc6c5ccc4n-2c13 ; c1ccc(N2c3ccccc3B3c4ccccc4N(c4ccccc4)c4cccc2c43)cc1 ; C1=C2Oc3cc(Oc4ccccc4)cc4c3B(C2=CC2B3c5c(cc(Oc6ccccc6)cc5-n5c6ccccc6c6cccc3c65)OC12)c1cccc2c3ccccc3n-4c12 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

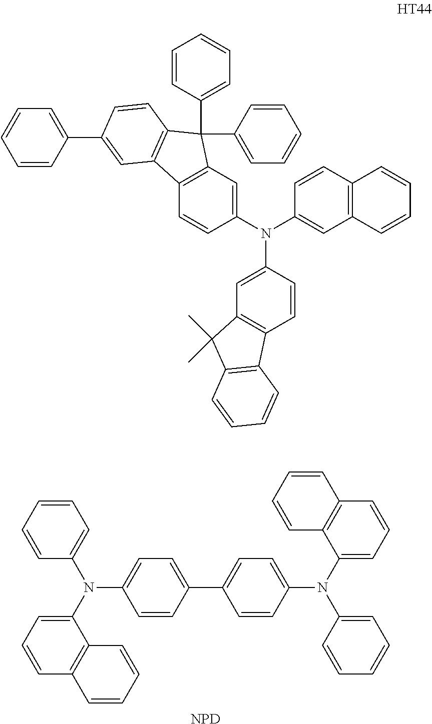

Referring to Table 2, it was confirmed that the light-emitting devices of Examples 1 to 10 had lowered driving voltage, increased luminescence efficiency, and increased maximum EQE compared to the light-emitting devices of Comparative Examples 1 to 7.

According to the one or more embodiments, a light-emitting device may have low driving voltage, high efficiency, and long lifespan, and in this regard, such a light-emitting device may be utilized to manufacture a high-quality electronic apparatus.

According to an embodiment, at least one of the hole transport region and the emission layer includes an arylamine-containing compound, an acridine-containing compound, a carbazole-containing compound, or any combination thereof; or at least one of the emission layer and the electron transport region includes a silicon-containing compound, a phosphine oxide-containing compound, a sulfur oxide-containing compound, a phosphorus oxide-containing compound, a triazine-containing compound, a pyrimidine-containing compound, a pyridine-containing compound, a dibenzofuran-containing compound, a dibenzothiophene-containing compound or any combination thereof.

The use of “may” when describing embodiments of the present invention refers to “one or more embodiments of the present invention.” It will be understood that when an element or layer is referred to as being “on”, “connected to”, “coupled to”, or “adjacent to” another element or layer, it can be directly on, connected to, coupled to, or adjacent to the other element or layer, or one or more intervening elements or layers may be present. In contrast, when an element or layer is referred to as being “directly on,” “directly connected to”, “directly coupled to”, or “immediately adjacent to” another element or layer, there are no intervening elements or layers present.

As used herein, the term “substantially,” “about,” and similar terms are used as terms of approximation and not as terms of degree, and are intended to account for the inherent deviations in measured or calculated values that would be recognized by those of ordinary skill in the art. Moreover, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a), and 35 U.S.C. § 132(a).

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various suitable changes in form and details may be made therein without departing from the spirit and scope as defined by the following claims, and equivalents thereof.

What is claimed is:

1. A condensed cyclic compound represented by Formula 1: 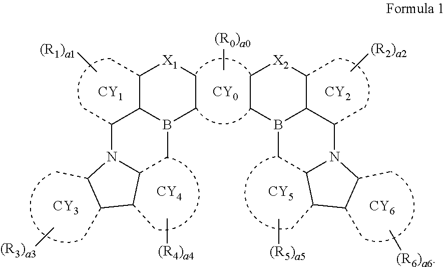
wherein, in Formula 1,
X₁ and X₂ are each independently 0 or S,
ring CY₀ to ring CY₆ are each independently a C₅-C₃₀ carbocyclic group or a C₁-C₃₀ heterocyclic group, wherein at least one selected from ring CY₃ and ring CY₆ is not a benzene group,
R₀ to R₆ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a0 to a6 are each independently an integer selected from 0 to 20,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —CI, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —CI; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

2. The condensed cyclic compound of claim 1, wherein ring CY₀ to ring CY₆ are each independently a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-a fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group, wherein at least one selected from ring CY₃ and ring CY₆ is not a benzene group.

3. The condensed cyclic compound of claim 1, wherein at least one selected from ring CY₀ to ring CY₂ is a benzene group.

4. The condensed cyclic compound of claim 1, wherein at least one selected from ring CY₃ and ring CY₆ is a fluorene group, a carbazole group, a dibenzofuran group, or a dibenzothiophene group.

5. The condensed cyclic compound of claim 1, wherein
a group represented by 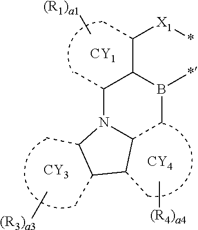
in Formula 1 is represented by any of Formulae CY3-1 to CY3-3: 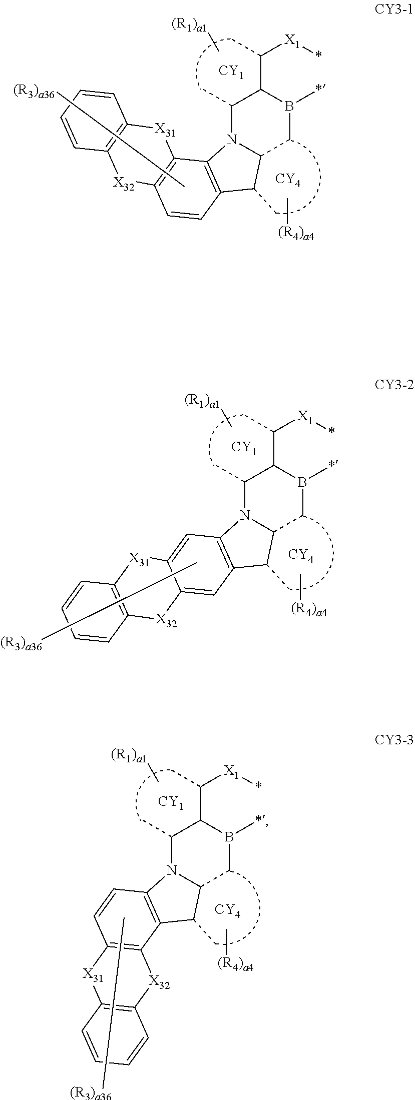
and
wherein, in Formulae CY3-1 to CY3-3,
X₁, ring CY₁, ring CY₄, R₁, R₃, R₄, a1, and a4 are each independently the same as respectively described in connection with Formula 1,
* and *′ each indicate a connection site to ring CY₀ in Formula 1,
X₃₁ is a single bond, O, S, Se, C(R₃₁ₐ)(R_{31b}), Si(R₃₁ₐ)(R_{31b}), or N(R₃₁ₐ),
X₃₂ is a single bond, O, S, Se, C(R₃₂ₐ)(R_{32b}), Si(R₃₂ₐ)(R_{32b}), or N(R₃₂ₐ),
X₃₁ and X₃₂ are not both single bonds at the same time,
R₃₁ₐ, R_{31b}, R₃₂ₐ, and R_{32b} are each independently the same as described in connection with R₃, and
a36 is an integer selected from 0 to 6.

6. The condensed cyclic compound of claim 1, wherein
a group represented by 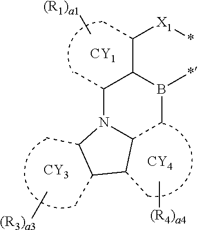
in Formula 1 is represented by any of Formulae CY3(1) to CY3(6): 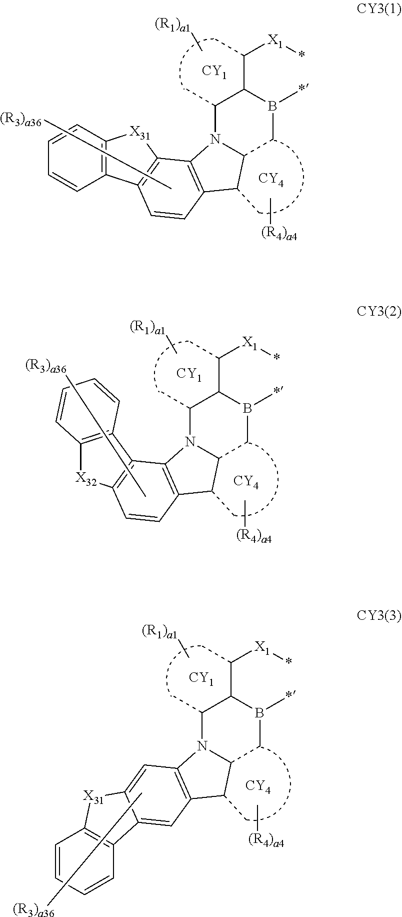 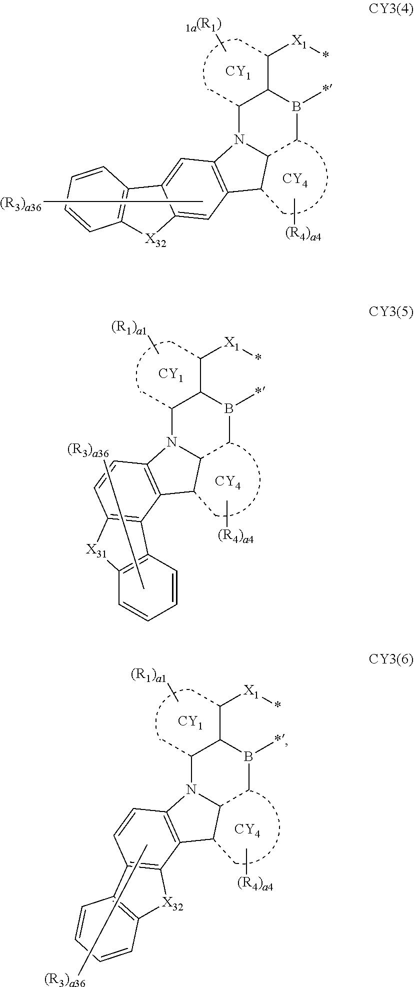
and
wherein, in Formulae CY3(1) to CY3(6),
X₁, ring CY1, ring CY4, R₁, R₃, R₄, a1, and a4 are each independently the same as respectively described in connection with Formula 1,
* and *′ each indicate a connection site to ring CY₀ in Formula 1,
X₃₁ is O, S, Se, C(R₃₁ₐ)(R_{31b}), Si(R₃₁ₐ)(R_{31b}), or N(R₃₁ₐ),
X₃₂ is O, S, Se, C(R₃₂ₐ)(R_{32b}), Si(R₃₂ₐ)(R_{32b}), or N(R₃₂ₐ),
R₃₁ₐ, R_{31b}, R₃₂ₐ, and R_{32b} are each independently the same as described in connection with R₃, and
a36 is an integer selected from 0 to 6.

7. The condensed cyclic compound of claim 1, wherein
a group represented by 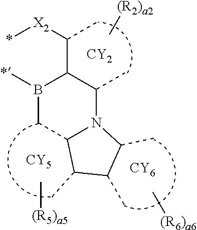
in Formula 1 is represented by any of Formulae CY6-1 to CY6-4: 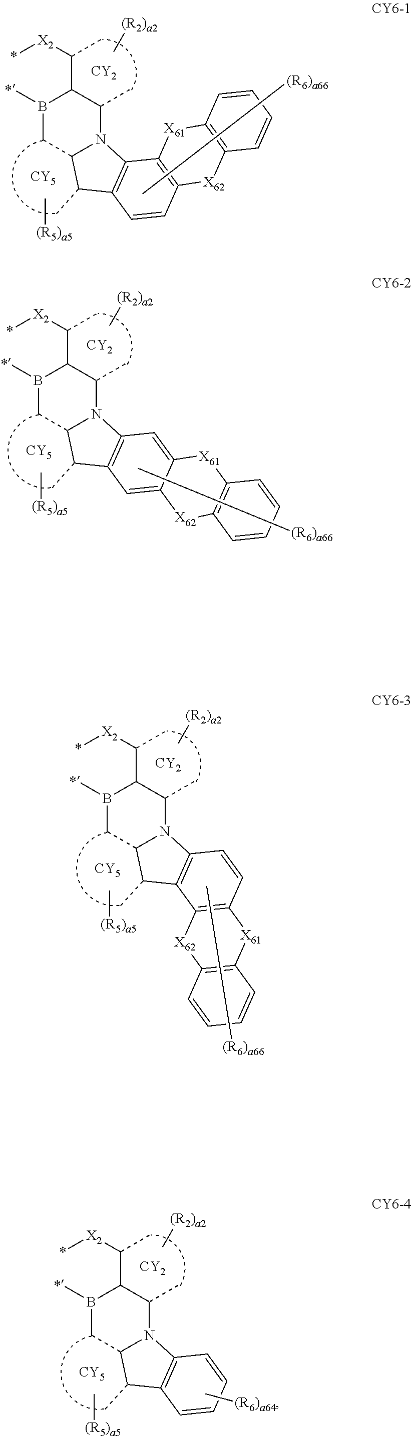
and
wherein, in Formulae CY6-1 to CY6-4,
X₂, ring CY2, ring CY5, R₂, R₅, R₆, a2, and a5 are each independently the same as respectively described in connection with Formula 1,
* and *′ each indicate a connection site to ring CY0 in Formula 1,
X₆₁ is a single bond, O, S, Se, C(R₆₁ₐ)(R_{61b}), Si(R₆₁ₐ)(R_{61b}), or N(R₆₁ₐ),
X₆₂ is single bond, O, S, Se, C(R₆₂ₐ)(R_{62b}), Si(R₆₂ₐ)(R_{62b}), or N(R₆₂ₐ),
X₆₁ and X₆₂ are not both single bonds at the same time,
R₆₁ₐ, R_{61b}, R₆₂ₐ, and R_{62b} are each independently the same as described in connection with R₆,
a64 is an integer selected from 0 to 4, and
a66 is an integer selected from 0 to 6.

8. The condensed cyclic compound of claim 1, wherein
a group represented by 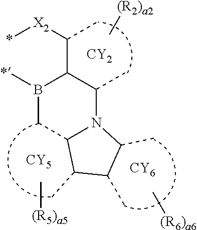
in Formula 1 is represented by any of Formulae CY6(1) to CY6(6) and CY6-4: 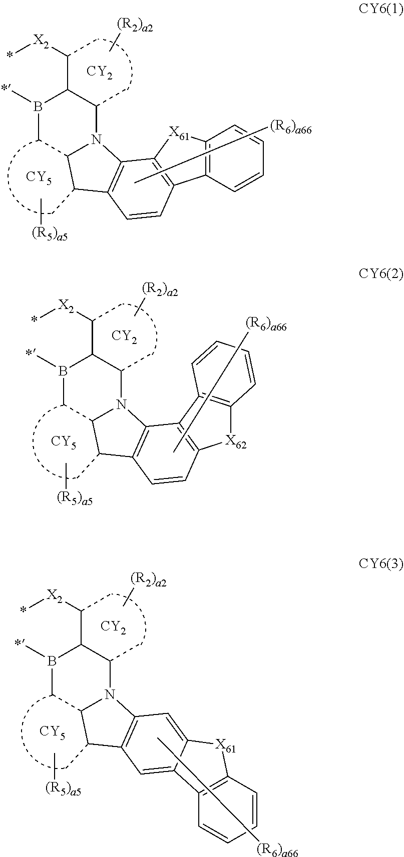 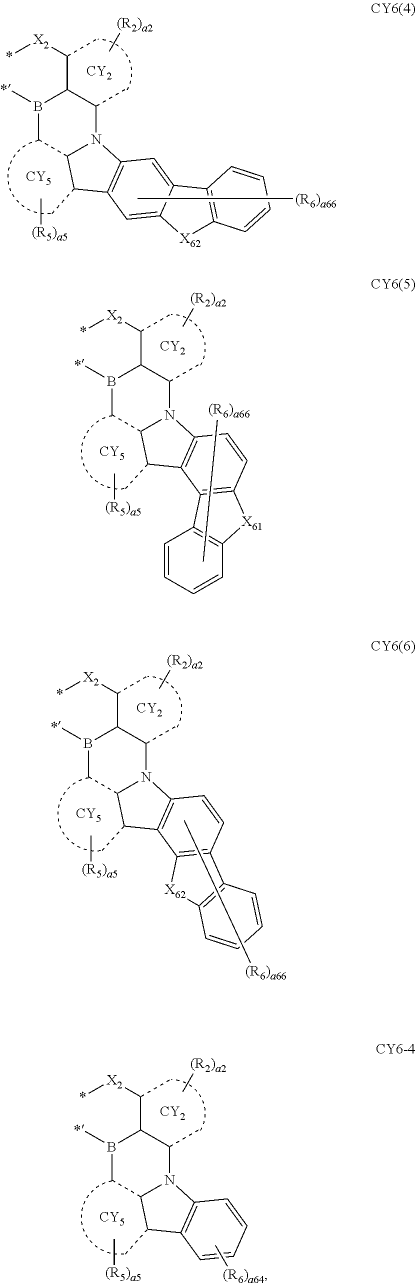
and
wherein, in Formulae CY6(1) to CY6(6) and CY6-4,
X₂, ring CY2, ring CY5, R₂, R₅, R₆, a2, and a5 are each independently the same as respectively described in connection with Formula 1,
* and *′ each indicate a connection site to ring CY0 in Formula 1,
X₆₁ is O, S, Se, C(R₆₁ₐ)(R_{61b}), Si(R₆₁ₐ)(R_{61b}), or N(R₆₁ₐ),
X₆₂ is O, S, Se, C(R₆₂ₐ)(R_{62b}), Si(R₆₂ₐ)(R_{62b}), or N(R₆₂ₐ),
R₆₁ₐ, R_{61b}, R₆₂ₐ, and R_{62b} are each independently the same as described in connection with R₆,
a64 is an integer selected from 0 to 4, and
a66 is an integer selected from 0 to 6.

9. The condensed cyclic compound of claim 1, wherein at least one selected from ring CY₄ and ring CY₅ is a benzene group.

10. The condensed cyclic compound of claim 1, wherein R₀ to R₆ are each independently:
hydrogen, deuterium, —F, —Cl, —Br, —I, a hydroxyl group, a cyano group, or a nitro group;
a C₁-C₂₀ alkyl group, a C₂-C₂₀ alkenyl group, a C₂-C₂₀ alkynyl group, or a C₁-C₂₀ alkoxy group, each unsubstituted or substituted with deuterium, —F, —Cl, —Br, —I, -CD₃, -CD₂H, -CDH₂, —CF₃, —CF₂H, —CFH₂, a hydroxyl group, a cyano group, a nitro group, a cyclopentyl group, a cyclohexyl group, a cycloheptyl group, a cycloctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or any combination thereof;
a cyclopentyl group, a cyclohexyl group, a cycloheptyl group, a cycloctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thienyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothienyl group, an benzoisothiazolyl group, a benzoxazolyl group, an benzoisoxazolyl group, a triazolyl group, a tetrazolyl group, an oxadiazolyl group, a triazinyl group, a dibenzofuranyl group, a dibenzothienyl group, a benzocarbazolyl group, a dibenzocarbazolyl group, an imidazopyridinyl group, or an imidazopyrimidinyl group, each unsubstituted or substituted with deuterium, —F, —CI, —Br, —I, -CD₃, -CD₂H, -CDH₂, —CF₃, —CF₂H, —CFH₂, a hydroxyl group, a cyano group, a nitro group, a C₁-C₂₀ alkyl group, a C₂-C₂₀ alkenyl group, a C₂-C₂₀ alkynyl group, a C₁-C₂₀ alkoxy group, a cyclopentyl group, a cyclohexyl group, a cycloheptyl group, a cycloctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thienyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothienyl group, an benzoisothiazolyl group, a benzoxazolyl group, an benzoisoxazolyl group, a triazolyl group, a tetrazolyl group, an oxadiazolyl group, a triazinyl group, a dibenzofuranyl group, a dibenzothienyl group, a benzocarbazolyl group, a dibenzocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or any combination thereof; or
—B(Q₁)(Q₂), —P(Q₁)(Q₂), or —C(═O)(Q₁).

11. The condensed cyclic compound of claim 1, wherein ring CY₃ and ring CY₆ are identical to each other.

12. The condensed cyclic compound of claim 1, wherein ring CY₄ and ring CY₅ are identical to each other.

13. The condensed cyclic compound of claim 1, wherein the condensed cyclic compound is one of Compounds 1 to 56:

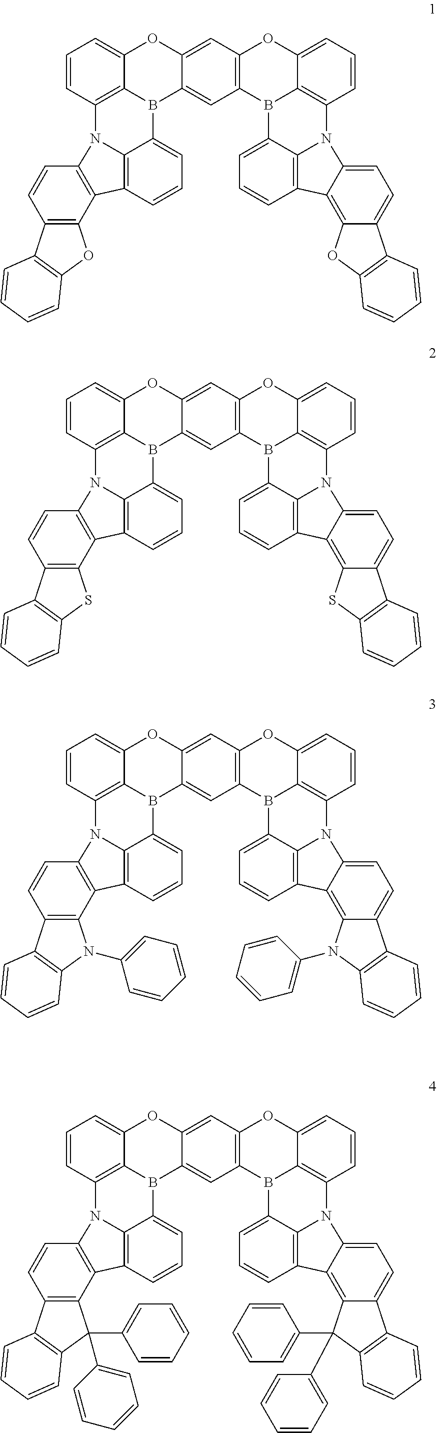 [SMILES: c1cc2c3c(c1)-n1c4ccc5c6ccccc6oc5c4c4cccc(c41)B3c1cc3c(cc1O2)Oc1cccc2c1B3c1cccc3c4c5oc6ccccc6c5ccc4n-2c13 ; c1cc2c3c(c1)-n1c4ccc5c6ccccc6sc5c4c4cccc(c41)B3c1cc3c(cc1O2)Oc1cccc2c1B3c1cccc3c4c5sc6ccccc6c5ccc4n-2c13 ; Cc1c(N2c3ccccc3B3c4cc5c(cc4Oc4cccc2c43)Oc2cccc3c2B5c2cccc4c5c(ccc6c7ccccc7n(-c7ccccc7)c65)n-3c24)ccc2c3ccccc3n(-c3ccccc3)c12 ; Cc1c(N2c3ccccc3B3c4cc5c(cc4Oc4cccc2c43)Oc2cccc3c2B5c2cccc4c5c6c(ccc5n-3c24)-c2ccccc2C6(c2ccccc2)c2ccccc2)ccc2c1C(c1ccccc1)(c1ccccc1)c1ccccc1-2]

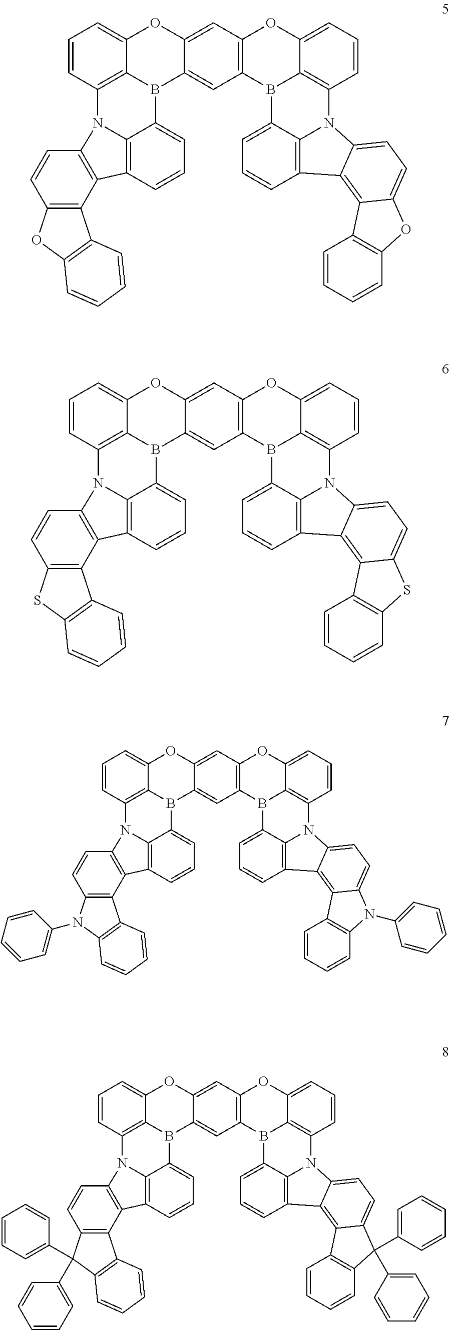 [SMILES: c1cc2c3c(c1)-n1c4ccc5oc6ccccc6c5c4c4cccc(c41)B3c1cc3c(cc1O2)Oc1cccc2c1B3c1cccc3c4c5c(ccc4n-2c13)oc1ccccc15 ; c1cc2c3c(c1)-n1c4ccc5sc6ccccc6c5c4c4cccc(c41)B3c1cc3c(cc1O2)Oc1cccc2c1B3c1cccc3c4c5c(ccc4n-2c13)sc1ccccc15 ; c1ccc(-n2c3ccccc3c3c4c5cccc6c5n(c4ccc32)-c2cccc3c2B6c2cc4c(cc2O3)Oc2cccc3c2B4c2cccc4c5c6c7ccccc7n(-c7ccccc7)c6ccc5n-3c24)cc1 ; c1ccc(C2(c3ccccc3)c3ccccc3-c3c2ccc2c3c3cccc4c3n2-c2cccc3c2B4c2cc4c(cc2O3)Oc2cccc3c2B4c2cccc4c5c6c(ccc5n-3c24)C(c2ccccc2)(c2ccccc2)c2ccccc2-6)cc1]

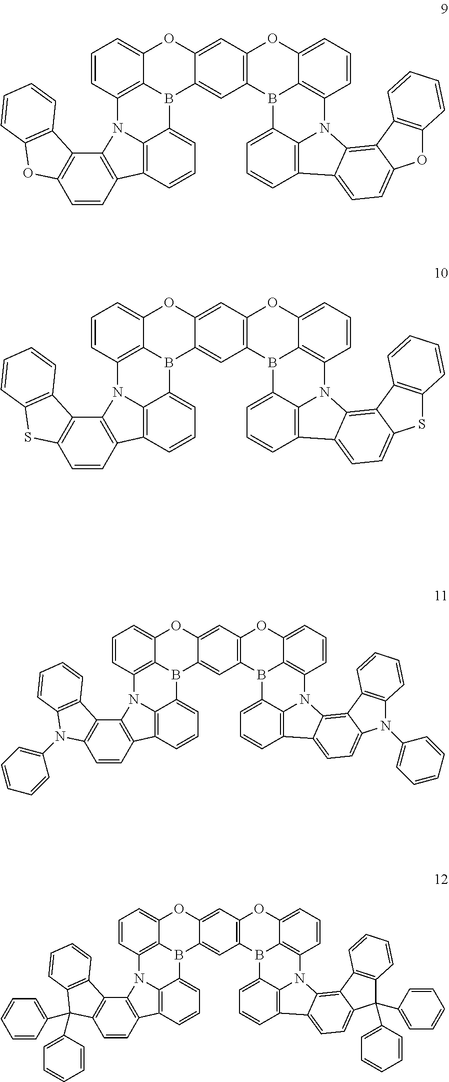 [SMILES: c1cc2c3c(c1)-n1c4c(cccc4c4ccc5oc6ccccc6c5c41)B3c1cc3c(cc1O2)Oc1cccc2c1B3c1cccc3c4ccc5oc6ccccc6c5c4n-2c13 ; c1cc2c3c(c1)-n1c4c(cccc4c4ccc5sc6ccccc6c5c41)B3c1cc3c(cc1O2)Oc1cccc2c1B3c1cccc3c4ccc5sc6ccccc6c5c4n-2c13 ; c1ccc(-n2c3ccccc3c3c2ccc2c4cccc5c4n(c23)-c2cccc3c2B5c2cc4c(cc2O3)Oc2cccc3c2B4c2cccc4c5ccc6c(c7ccccc7n6-c6ccccc6)c5n-3c24)cc1 ; c1ccc(C2(c3ccccc3)c3ccccc3-c3c2ccc2c4cccc5c4n(c32)-c2cccc3c2B5c2cc4c(cc2O3)Oc2cccc3c2B4c2cccc4c5ccc6c(c5n-3c24)-c2ccccc2C6(c2ccccc2)c2ccccc2)cc1]

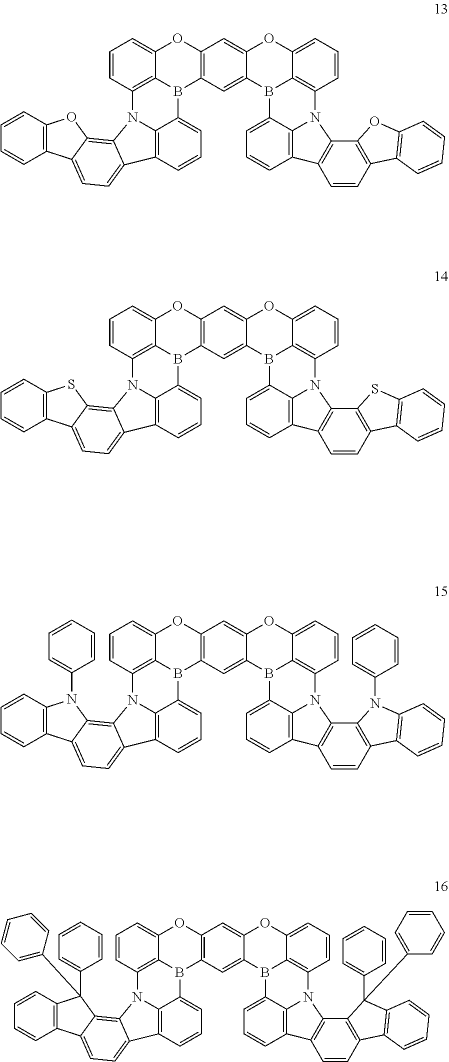 [SMILES: c1cc2c3c(c1)-n1c4c(cccc4c4ccc5c6ccccc6oc5c41)B3c1cc3c(cc1O2)Oc1cccc2c1B3c1cccc3c4ccc5c6ccccc6oc5c4n-2c13 ; c1cc2c3c(c1)-n1c4c(cccc4c4ccc5c6ccccc6sc5c41)B3c1cc3c(cc1O2)Oc1cccc2c1B3c1cccc3c4ccc5c6ccccc6sc5c4n-2c13 ; c1ccc(-n2c3ccccc3c3ccc4c5cccc6c5n(c4c32)-c2cccc3c2B6c2cc4c(cc2O3)Oc2cccc3c2B4c2cccc4c5ccc6c7ccccc7n(-c7ccccc7)c6c5n-3c24)cc1 ; c1ccc(C2(c3ccccc3)c3ccccc3-c3ccc4c5cccc6c5n(c4c32)-c2cccc3c2B6c2cc4c(cc2O3)Oc2cccc3c2B4c2cccc4c5ccc6c(c5n-3c24)C(c2ccccc2)(c2ccccc2)c2ccccc2-6)cc1]

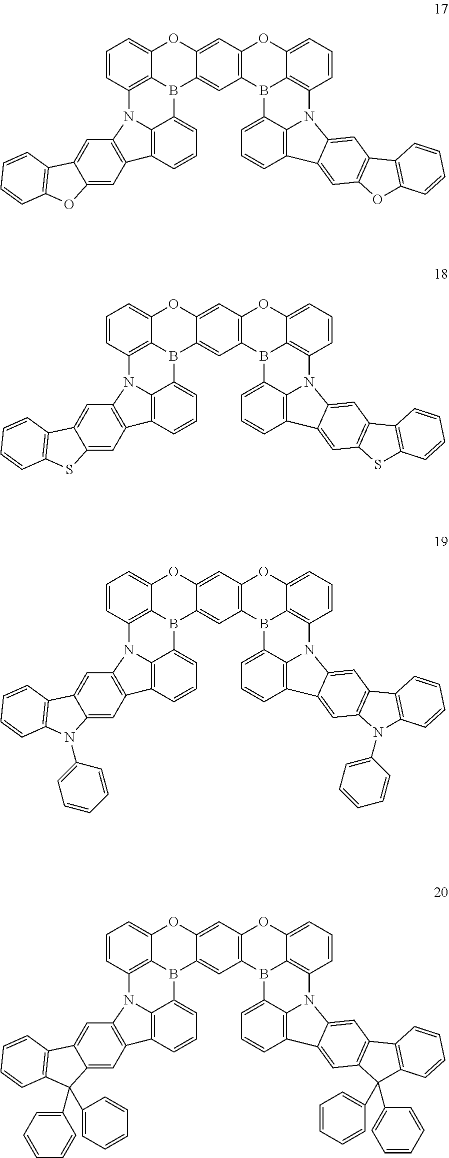 [SMILES: c1cc2c3c(c1)-n1c4cc5c(cc4c4cccc(c41)B3c1cc3c(cc1O2)Oc1cccc2c1B3c1cccc3c4cc6oc7ccccc7c6cc4n-2c13)oc1ccccc15 ; c1cc2c3c(c1)-n1c4cc5c(cc4c4cccc(c41)B3c1cc3c(cc1O2)Oc1cccc2c1B3c1cccc3c4cc6sc7ccccc7c6cc4n-2c13)sc1ccccc15 ; c1ccc(-n2c3ccccc3c3cc4c(cc32)c2cccc3c2n4-c2cccc4c2B3c2cc3c(cc2O4)Oc2cccc4c2B3c2cccc3c5cc6c(cc5n-4c23)c2ccccc2n6-c2ccccc2)cc1 ; c1ccc(C2(c3ccccc3)c3ccccc3-c3cc4c(cc32)c2cccc3c2n4-c2cccc4c2B3c2cc3c(cc2O4)Oc2cccc4c2B3c2cccc3c5cc6c(cc5n-4c23)-c2ccccc2C6(c2ccccc2)c2ccccc2)cc1]

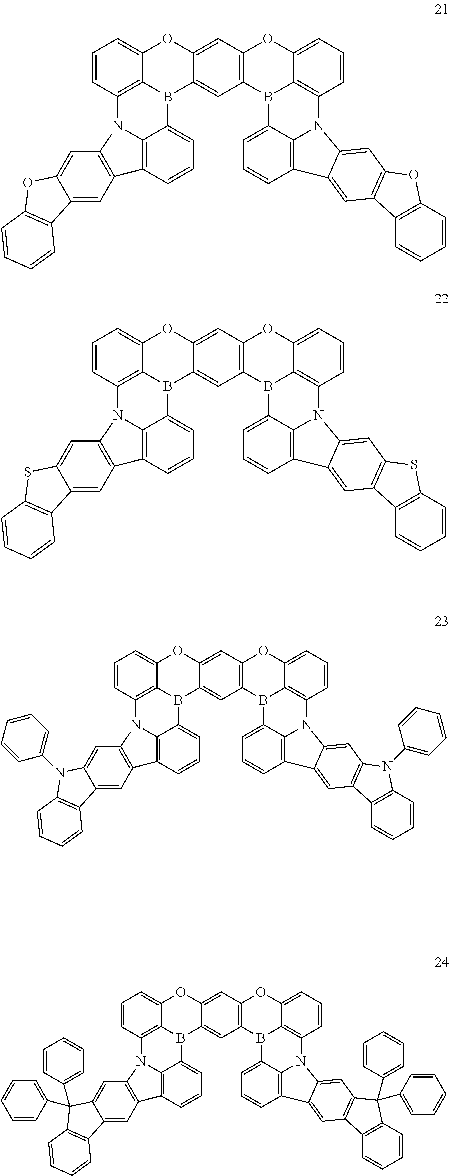 [SMILES: c1cc2c3c(c1)-n1c4cc5oc6ccccc6c5cc4c4cccc(c41)B3c1cc3c(cc1O2)Oc1cccc2c1B3c1cccc3c4cc5c(cc4n-2c13)oc1ccccc15 ; c1cc2c3c(c1)-n1c4cc5sc6ccccc6c5cc4c4cccc(c41)B3c1cc3c(cc1O2)Oc1cccc2c1B3c1cccc3c4cc5c(cc4n-2c13)sc1ccccc15 ; c1ccc(-n2c3ccccc3c3cc4c5cccc6c5n(c4cc32)-c2cccc3c2B6c2cc4c(cc2O3)Oc2cccc3c2B4c2cccc4c5cc6c7ccccc7n(-c7ccccc7)c6cc5n-3c24)cc1 ; c1ccc(C2(c3ccccc3)c3ccccc3-c3cc4c5cccc6c5n(c4cc32)-c2cccc3c2B6c2cc4c(cc2O3)Oc2cccc3c2B4c2cccc4c5cc6c(cc5n-3c24)C(c2ccccc2)(c2ccccc2)c2ccccc2-6)cc1]

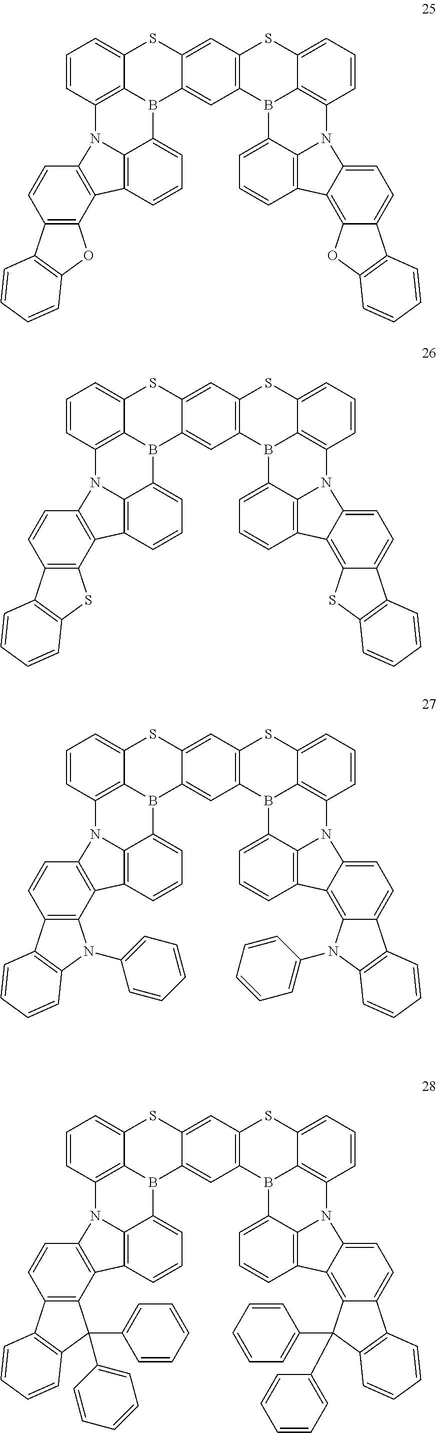 [SMILES: c1cc2c3c(c1)-n1c4ccc5c6ccccc6oc5c4c4cccc(c41)B3c1cc3c(cc1S2)Sc1cccc2c1B3c1cccc3c4c5oc6ccccc6c5ccc4n-2c13 ; c1cc2c3c(c1)-n1c4ccc5c6ccccc6sc5c4c4cccc(c41)B3c1cc3c(cc1S2)Sc1cccc2c1B3c1cccc3c4c5sc6ccccc6c5ccc4n-2c13 ; Cc1c(N2c3ccccc3B3c4cc5c(cc4Sc4cccc2c43)Sc2cccc3c2B5c2cccc4c5c(ccc6c7ccccc7n(-c7ccccc7)c65)n-3c24)ccc2c3ccccc3n(-c3ccccc3)c12 ; Cc1c(N2c3ccccc3B3c4cc5c(cc4Sc4cccc2c43)Sc2cccc3c2B5c2cccc4c5c6c(ccc5n-3c24)-c2ccccc2C6(c2ccccc2)c2ccccc2)ccc2c1C(c1ccccc1)(c1ccccc1)c1ccccc1-2]

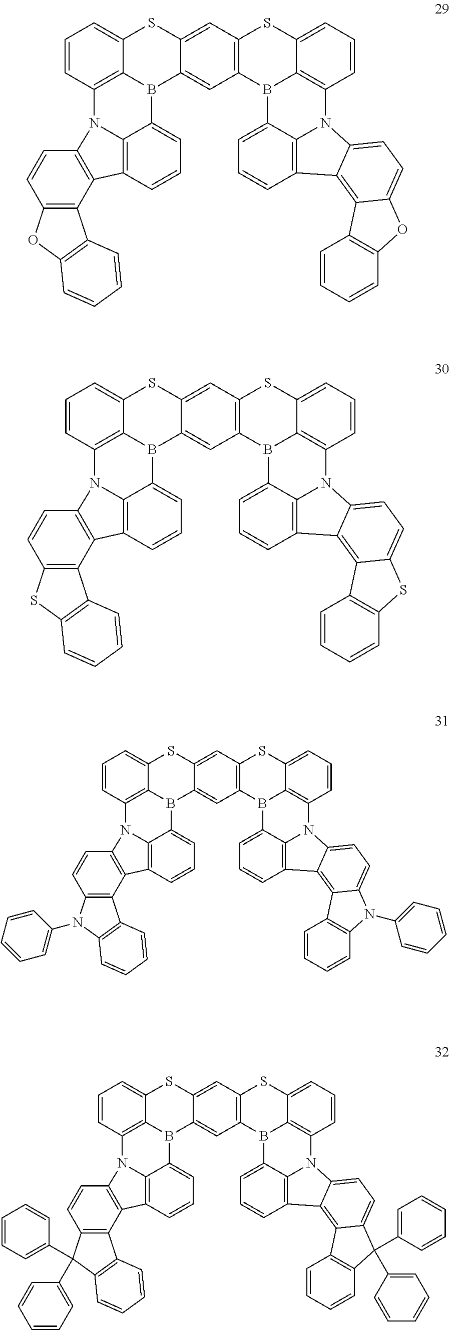 [SMILES: c1cc2c3c(c1)-n1c4ccc5oc6ccccc6c5c4c4cccc(c41)B3c1cc3c(cc1S2)Sc1cccc2c1B3c1cccc3c4c5c(ccc4n-2c13)oc1ccccc15 ; c1cc2c3c(c1)-n1c4ccc5sc6ccccc6c5c4c4cccc(c41)B3c1cc3c(cc1S2)Sc1cccc2c1B3c1cccc3c4c5c(ccc4n-2c13)sc1ccccc15 ; c1ccc(-n2c3ccccc3c3c4c5cccc6c5n(c4ccc32)-c2cccc3c2B6c2cc4c(cc2S3)Sc2cccc3c2B4c2cccc4c5c6c7ccccc7n(-c7ccccc7)c6ccc5n-3c24)cc1 ; c1ccc(C2(c3ccccc3)c3ccccc3-c3c2ccc2c3c3cccc4c3n2-c2cccc3c2B4c2cc4c(cc2S3)Sc2cccc3c2B4c2cccc4c5c6c(ccc5n-3c24)C(c2ccccc2)(c2ccccc2)c2ccccc2-6)cc1]

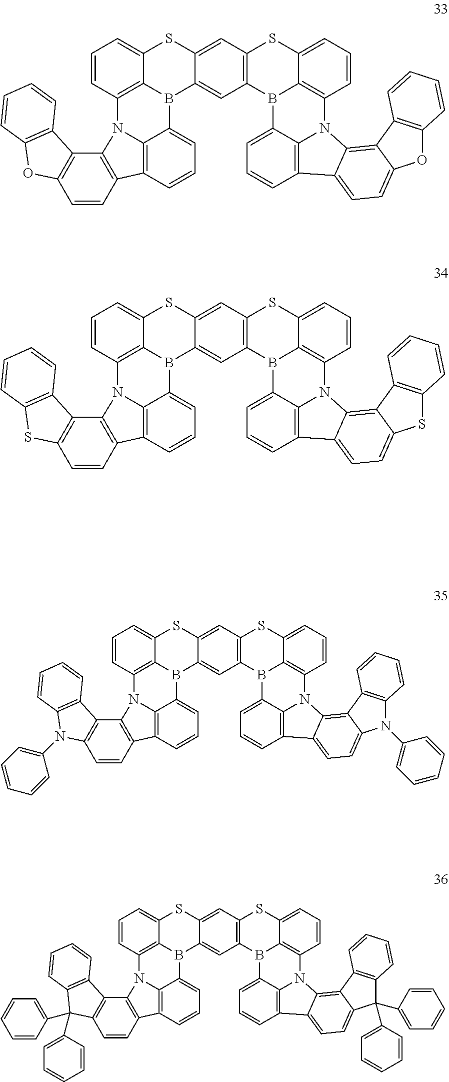 [SMILES: c1cc2c3c(c1)-n1c4c(cccc4c4ccc5oc6ccccc6c5c41)B3c1cc3c(cc1S2)Sc1cccc2c1B3c1cccc3c4ccc5oc6ccccc6c5c4n-2c13 ; c1cc2c3c(c1)-n1c4c(cccc4c4ccc5sc6ccccc6c5c41)B3c1cc3c(cc1S2)Sc1cccc2c1B3c1cccc3c4ccc5sc6ccccc6c5c4n-2c13 ; c1ccc(-n2c3ccccc3c3c2ccc2c4cccc5c4n(c23)-c2cccc3c2B5c2cc4c(cc2S3)Sc2cccc3c2B4c2cccc4c5ccc6c(c7ccccc7n6-c6ccccc6)c5n-3c24)cc1 ; c1ccc(C2(c3ccccc3)c3ccccc3-c3c2ccc2c4cccc5c4n(c32)-c2cccc3c2B5c2cc4c(cc2S3)Sc2cccc3c2B4c2cccc4c5ccc6c(c5n-3c24)-c2ccccc2C6(c2ccccc2)c2ccccc2)cc1]

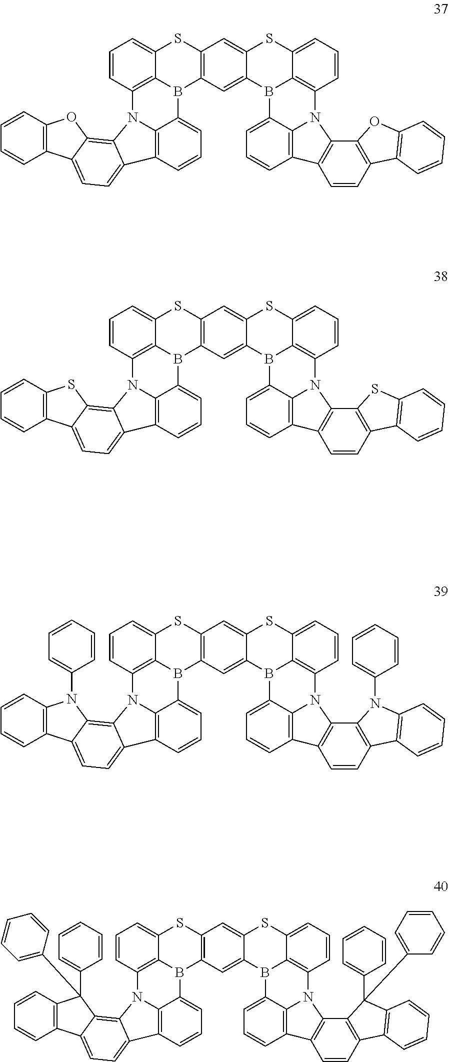 [SMILES: c1cc2c3c(c1)-n1c4c(cccc4c4ccc5c6ccccc6oc5c41)B3c1cc3c(cc1S2)Sc1cccc2c1B3c1cccc3c4ccc5c6ccccc6oc5c4n-2c13 ; c1cc2c3c(c1)-n1c4c(cccc4c4ccc5c6ccccc6sc5c41)B3c1cc3c(cc1S2)Sc1cccc2c1B3c1cccc3c4ccc5c6ccccc6sc5c4n-2c13 ; c1ccc(-n2c3ccccc3c3ccc4c5cccc6c5n(c4c32)-c2cccc3c2B6c2cc4c(cc2S3)Sc2cccc3c2B4c2cccc4c5ccc6c7ccccc7n(-c7ccccc7)c6c5n-3c24)cc1 ; c1ccc(C2(c3ccccc3)c3ccccc3-c3ccc4c5cccc6c5n(c4c32)-c2cccc3c2B6c2cc4c(cc2S3)Sc2cccc3c2B4c2cccc4c5ccc6c(c5n-3c24)C(c2ccccc2)(c2ccccc2)c2ccccc2-6)cc1]

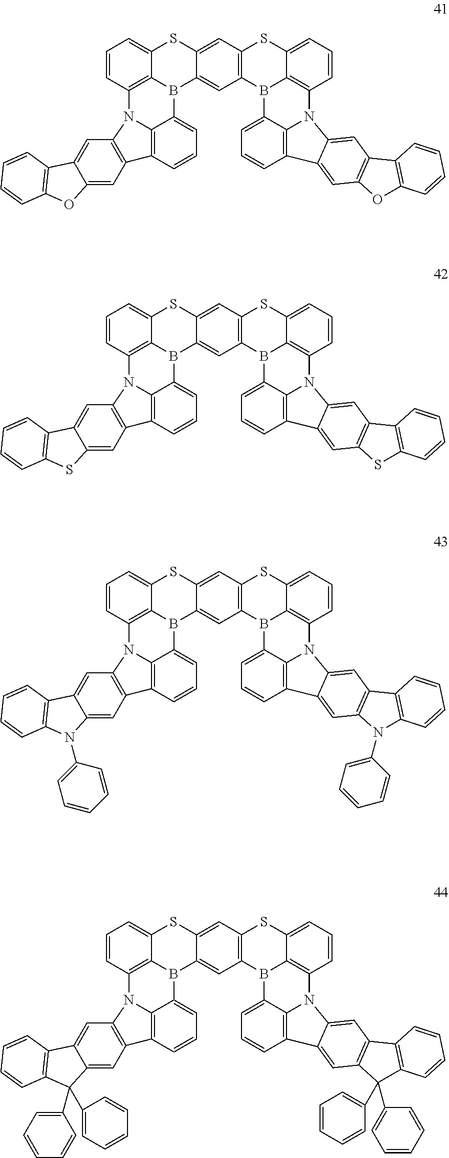 [SMILES: c1cc2c3c(c1)-n1c4cc5c(cc4c4cccc(c41)B3c1cc3c(cc1S2)Sc1cccc2c1B3c1cccc3c4cc6oc7ccccc7c6cc4n-2c13)oc1ccccc15 ; c1cc2c3c(c1)-n1c4cc5c(cc4c4cccc(c41)B3c1cc3c(cc1S2)Sc1cccc2c1B3c1cccc3c4cc6sc7ccccc7c6cc4n-2c13)sc1ccccc15 ; c1ccc(-n2c3ccccc3c3cc4c(cc32)c2cccc3c2n4-c2cccc4c2B3c2cc3c(cc2S4)Sc2cccc4c2B3c2cccc3c5cc6c(cc5n-4c23)c2ccccc2n6-c2ccccc2)cc1 ; c1ccc(C2(c3ccccc3)c3ccccc3-c3cc4c(cc32)c2cccc3c2n4-c2cccc4c2B3c2cc3c(cc2S4)Sc2cccc4c2B3c2cccc3c5cc6c(cc5n-4c23)-c2ccccc2C6(c2ccccc2)c2ccccc2)cc1]

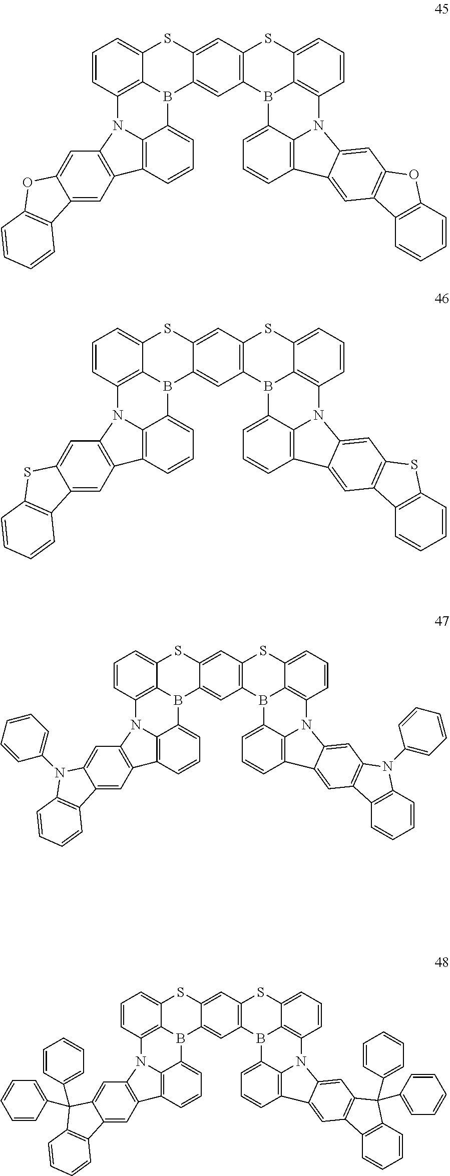 [SMILES: c1cc2c3c(c1)-n1c4cc5oc6ccccc6c5cc4c4cccc(c41)B3c1cc3c(cc1S2)Sc1cccc2c1B3c1cccc3c4cc5c(cc4n-2c13)oc1ccccc15 ; c1cc2c3c(c1)-n1c4cc5sc6ccccc6c5cc4c4cccc(c41)B3c1cc3c(cc1S2)Sc1cccc2c1B3c1cccc3c4cc5c(cc4n-2c13)sc1ccccc15 ; c1ccc(-n2c3ccccc3c3cc4c5cccc6c5n(c4cc32)-c2cccc3c2B6c2cc4c(cc2S3)Sc2cccc3c2B4c2cccc4c5cc6c7ccccc7n(-c7ccccc7)c6cc5n-3c24)cc1 ; c1ccc(C2(c3ccccc3)c3ccccc3-c3cc4c5cccc6c5n(c4cc32)-c2cccc3c2B6c2cc4c(cc2S3)Sc2cccc3c2B4c2cccc4c5cc6c(cc5n-3c24)C(c2ccccc2)(c2ccccc2)c2ccccc2-6)cc1]

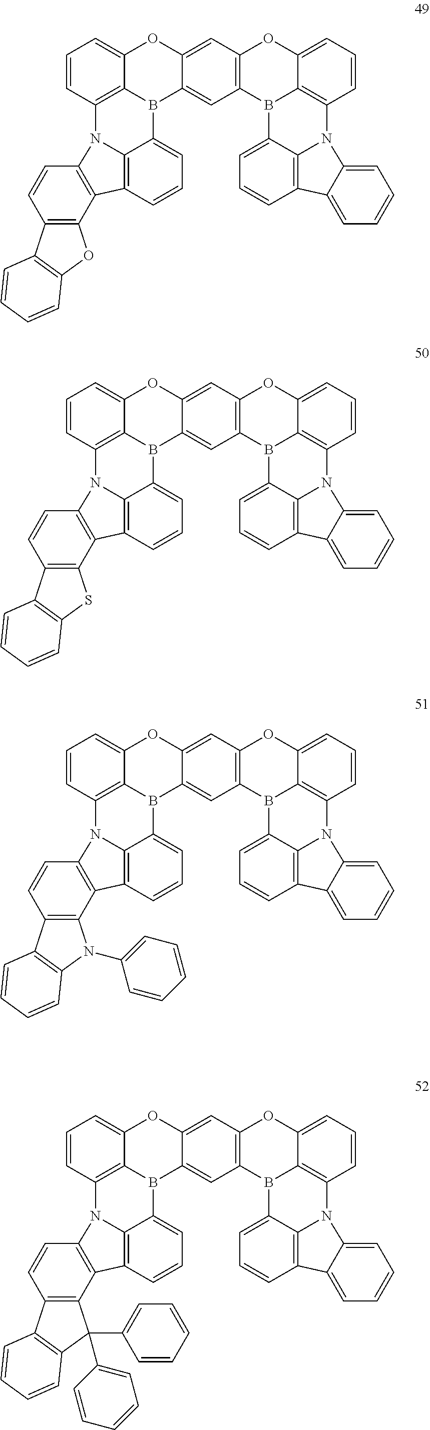 [SMILES: c1cc2c3c(c1)-n1c4ccccc4c4cccc(c41)B3c1cc3c(cc1O2)Oc1cccc2c1B3c1cccc3c4c5oc6ccccc6c5ccc4n-2c13 ; c1cc2c3c(c1)-n1c4ccccc4c4cccc(c41)B3c1cc3c(cc1O2)Oc1cccc2c1B3c1cccc3c4c5sc6ccccc6c5ccc4n-2c13 ; Cc1ccccc1N1c2ccccc2B2c3cc4c(cc3Oc3cccc1c32)Oc1cccc2c1B4c1cccc3c4c(ccc5c6ccccc6n(-c6ccccc6)c54)n-2c13 ; Cc1ccccc1N1c2ccccc2B2c3cc4c(cc3Oc3cccc1c32)Oc1cccc2c1B4c1cccc3c4c5c(ccc4n-2c13)-c1ccccc1C5(c1ccccc1)c1ccccc1]

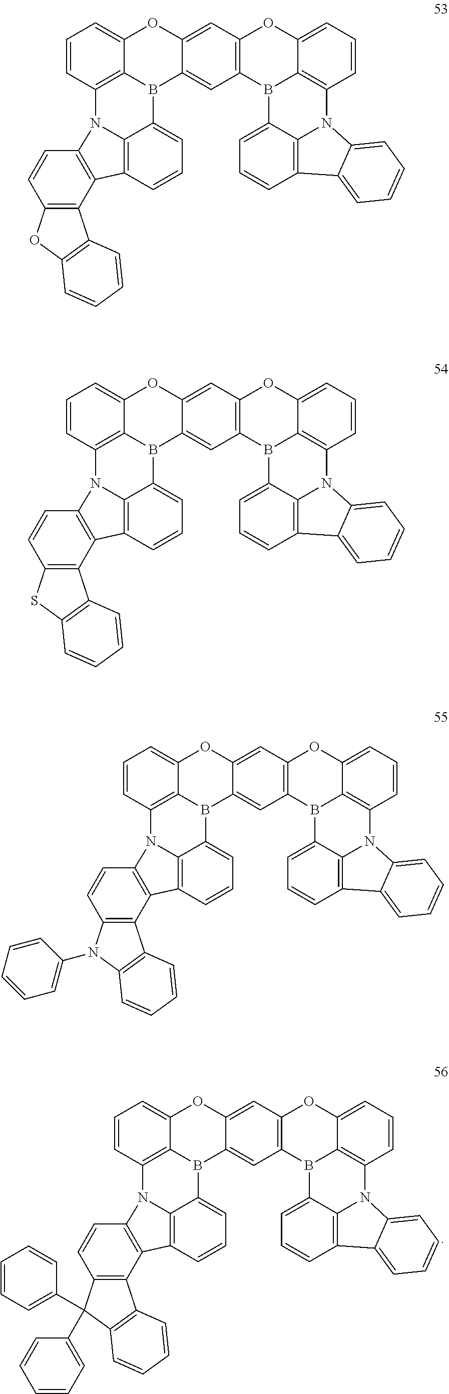 [SMILES: c1cc2c3c(c1)-n1c4ccccc4c4cccc(c41)B3c1cc3c(cc1O2)Oc1cccc2c1B3c1cccc3c4c5c(ccc4n-2c13)oc1ccccc15 ; c1cc2c3c(c1)-n1c4ccccc4c4cccc(c41)B3c1cc3c(cc1O2)Oc1cccc2c1B3c1cccc3c4c5c(ccc4n-2c13)sc1ccccc15 ; c1ccc(-n2c3ccccc3c3c4c5cccc6c5n(c4ccc32)-c2cccc3c2B6c2cc4c(cc2O3)Oc2cccc3c2B4c2cccc4c5ccccc5n-3c24)cc1 ; c1ccc(C2(c3ccccc3)c3ccccc3-c3c2ccc2c3c3cccc4c3n2-c2cccc3c2B4c2cc4c(cc2O3)Oc2cccc3c2B4c2cccc4c5ccccc5n-3c24)cc1]

14. A light-emitting device comprising:
a first electrode;
a second electrode facing the first electrode; and
an interlayer between the first electrode and the second electrode and comprising an emission layer,
wherein the emission layer comprises the condensed cyclic compound of claim 1.

15. An electronic apparatus comprising:
the light-emitting device of claim 14, and
a thin-film transistor,
wherein the thin-film transistor comprises a source electrode and a drain electrode, and
the first electrode of the light-emitting device is electrically connected to the source electrode or the drain electrode of the thin-film transistor.

16. The electronic apparatus of claim 15, wherein the electronic apparatus further comprises a color filter, a color conversion layer, a touchscreen layer, a polarization layer, or any combination thereof.
